(19) United States
(12) Patent Application Publication
(10) Pub. No.: US 2026/0261774 A1
(43) Pub. Date: Sep. 3, 2026

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventor: EIICHI OBA, KANAGAWA (JP)

(21) Appl. No.: 19/154,487

(22) PCT Filed: Feb. 22, 2024
(86) PCT No.: PCT/JP2024/006443

§ 371 Date: Aug. 7, 2025

(30) Foreign Application Priority Data
Mar. 3, 2023 (JP) 2023-033213

(51) Int. Cl. H04N 25/589; H04N 23/67; H04N 25/772

(52) U.S. Cl. CPC H04N 25/589; H04N 23/672; H04N 25/772

(57) ABSTRACT

At least one of detection of an optical flow or expansion of a dynamic range is performed without reduction of a frame rate.

A photodetection device includes: a pixel array section including a plurality of pixels arranged in a first direction and a second direction and divided into a plurality of pixel groups including some pixels different from each other on the basis of a plurality of pixel control signals; a control signal generation circuit that is arranged in a layer different from the pixel array section and generates the plurality of pixel control signals; a thinned image generation section that generates a plurality of thinned images by exposing the plurality of pixel groups within a predetermined frame period while shifting at least one of exposure start times or exposure end times from each other; and an image composition section that generates a composite image obtained by combining the plurality of thinned images.

### TECHNICAL FIELD

The present disclosure relates to a photodetection device and an electronic apparatus.

### BACKGROUND ART

Recently, drones are widely used in various fields. A technology for acquiring a motion vector, that is, an optical flow, of a drone itself is important for self-localization technology and mapping technology for the drone.

As a technology for acquiring the optical flow, a method of mounting a plurality of image sensors on the drone, a method of combining an image sensor and an acceleration sensor, and the like have been proposed. These methods have a problem of increasing the weight of the drone and shortening the flight time.

On the other hand, there is a method of calculating the optical flow from a movement distance of a feature point in two adjacent frame images continuously acquired by one image sensor (for example, see Patent Document 1). In order to calculate the optical flow by this method, it is a premise that there is a feature point in an adjacent frame image. When the frame rate is low, the feature point may deviate from the adjacent frame image, and thus, the frame rate needs to be as high as possible.

### CITATION LIST

### Patent Document

Patent Document 1: Japanese Patent Application Laid-Open No. 2006-86741

### SUMMARY OF THE INVENTION

### Problems to be Solved by the Invention

However, the frame rate changes depending on the length of the exposure time. In a case where the surroundings are dark and the exposure time has to be lengthened, the frame rate inevitably becomes long, and there is a possibility that the feature point disappears from the adjacent frame image.

Furthermore, recently, a camera has been widely used that has a high dynamic range (HDR) function of generating an image with an expanded dynamic range. In the camera having the HDR function, it is common to expand a dynamic range by combining a plurality of images captured with changed exposure times. Since it is necessary to perform a plurality of times of imaging, it takes time to obtain a final image.

Thus, the present disclosure provides a photodetection device and an electronic apparatus capable of performing at least one of detection of an optical flow or expansion of a dynamic range without lowering a frame rate.

### Solutions to Problems

In order to solve the problems described above, according to the present disclosure, there is provided a photodetection device including:
a pixel array section including a plurality of pixels arranged in a first direction and a second direction and divided into a plurality of pixel groups including some pixels different from each other on the basis of a plurality of pixel control signals;
a control signal generation circuit that is arranged in a layer different from the pixel array section and generates the plurality of pixel control signals;
a thinned image generation section that generates a plurality of thinned images by exposing the plurality of pixel groups within a predetermined frame period while shifting at least one of exposure start times or exposure end times from each other; and
an image composition section that generates a composite image obtained by combining the plurality of thinned images.

There may be included:
a first substrate on which the pixel array section is arranged;
a second substrate on which at least a part of a pixel circuit that generates a pixel signal according to charges photoelectrically converted by the plurality of pixels and the control signal generation circuit are arranged and that is stacked on the first substrate; and
a third substrate on which the thinned image generation section and the image composition section are arranged and that is stacked on the first substrate and the second substrate.

The image composition section may generate the plurality of thinned images at a frame rate identical to a frame rate in a case where image data based on all of the plurality of pixels is generated.

Each of the plurality of pixel groups may include two or more pixels that are not adjacent to each other in the first direction and the second direction.

Each of the plurality of pixels may include:
a photoelectric conversion element that accumulates a charge according to an amount of incident light;
a charge holding portion that holds the charge accumulated in the photoelectric conversion element ;
a charge-voltage conversion portion that converts the charge held in the charge holding portion into a voltage signal; and
a transfer transistor that transfers the charge held in the charge holding portion to the charge-voltage conversion portion, and
the charge holding portion may hold the charge photoelectrically converted in each of the plurality of pixel groups at an aligned timing for each pixel group.

The plurality of thinned images may be generated on the basis of the charge photoelectrically converted by the plurality of pixel groups for which at least one of the exposure start times or the exposure end times are different from each other and exposure times are identical to each other.

Each of the plurality of pixel groups may start exposure of a next frame after reading out the charge from the charge holding portion while another pixel group performs exposure.

There is provided a motion vector detection section that detects a motion vector on the basis of the composite image, and
the plurality of thinned images may be generated on the basis of the charge photoelectrically converted by the plurality of pixel groups for which at least one of the exposure start times or the exposure end times are different from each other and exposure times are different from each other.

The plurality of pixel groups may read out the charge from the charge holding portion at an identical timing, and then starts exposure of a next frame at a timing shifted for each pixel group.

The image composition section may generate the composite image having a wider dynamic range than a dynamic range of each of the plurality of thinned images.

The plurality of thinned images may include two or more thinned image groups,
each of the two or more thinned image groups may include two or more thinned images for which exposure times are different from each other, and
the image composition section may generate, for each of the two or more thinned image groups, the composite image obtained by combining the two or more thinned images included in a corresponding one of the thinned image groups.

The plurality of pixel groups may include two or more pixel group units for which at least one of the exposure start times or the exposure end times are different from each other,
each of the two or more pixel group units may include two or more pixel groups for which at least one of the exposure start times or the exposure end times are different from each other and exposure times are different from each other within the predetermined frame period, and
the two or more pixel group units may generate the two or more thinned image groups.

The two or more pixel groups included in each of the two or more pixel group units may end exposure at an identical timing, and
an exposure end timing may be different for each of the two or more pixel group units.

There may be included a motion vector detection section that detects a motion vector on the basis of the composite image, and the image composition section may generate the composite image having a wider dynamic range than a dynamic range of each of the plurality of thinned images.

According to the present disclosure, there is provided a photodetection device including: a pixel array section including a plurality of pixels arranged in a first direction and a second direction and divided into a plurality of macropixels each including two or more of the pixels adjacent to each other in at least one of the first direction or the second direction on the basis of a plurality of pixel control signals;
a control signal generation circuit that is arranged in a layer different from the pixel array section and generates the plurality of pixel control signals; and
an image generation section that generates a phase difference detection image on the basis of pixel signals generated by the plurality of macropixels in a state where charge reading from some pixels is stopped, the some pixels being included in each of the plurality of macropixels and arranged in the first direction or the second direction.

In two of the macropixels adjacent to each other in the first direction or the second direction, pixels for which charge reading is stopped may be arranged symmetrically with each other.

According to the present disclosure, there is provided an electronic apparatus including: a photodetection device that generates a composite image; and
a processing section that performs processing on the composite image, in which
the photodetection device includes:
a pixel array section including a plurality of pixels arranged in a first direction and a second direction and divided into a plurality of pixel groups including some pixels different from each other on the basis of a plurality of pixel control signals;
a control signal generation circuit that is arranged in a layer different from the pixel array section and generates the plurality of pixel control signals;
a thinned image generation section that generates a plurality of thinned images by performing exposure while shifting at least one of exposure start times or exposure end times from each other within a predetermined frame period in the plurality of pixel groups; and
an image composition section that generates the composite image obtained by combining the plurality of thinned images.

### BRIEF DESCRIPTION OF DRAWINGS

FIG. 1 is a block diagram of an electronic apparatus in a first embodiment of the present disclosure.

FIG. 2A is a block diagram of a photodetection device of a column AD method in the first embodiment of the present disclosure.

FIG. 2B is a block diagram of a photodetection device of a pixel parallel AD method in the first embodiment of the present disclosure.

FIG. 3 is a circuit diagram illustrating an example of a circuit configuration of a pixel 10 and a pixel circuit.

FIG. 4 is a perspective view schematically illustrating a chip configuration of the photodetection device according to the present disclosure.

FIG. 5 is a diagram describing a pixel array section and a control signal generation section of the photodetection device according to the first embodiment.

FIG. 6 is a flowchart illustrating processing operation of the photodetection device according to the first embodiment.

FIG. 7 is a diagram illustrating exposure and transfer timings of charges of pixel groups A to D.

FIG. 8A is a diagram schematically illustrating a thinned image A corresponding to the pixel group A.

FIG. 8B is a diagram schematically illustrating a thinned image B corresponding to the pixel group B.

FIG. 8C is a diagram schematically illustrating a thinned image C corresponding to the pixel group C.

FIG. 8D is a diagram schematically illustrating a thinned image D corresponding to the pixel group D.

FIG. 9 is a diagram describing a method of generating an optical flow.

FIG. 10 is a diagram describing a method of generating an optical flow according to a comparative example.

FIG. 11 is a flowchart illustrating processing operation of the photodetection device according to a second embodiment.

FIG. 12 is a diagram illustrating exposure and transfer timings of the charges of the pixel groups.

FIG. 13 is a diagram in which thinned images are arranged in order of luminance.

FIG. 14 is a diagram schematically illustrating a dynamic range of a composite image.

FIG. 15 is a flowchart illustrating processing operation of the photodetection device according to a third embodiment.

FIG. 16 is a diagram illustrating exposure and transfer timings of the charges of the pixel groups.

FIG. 17A is a diagram schematically illustrating the thinned image A.

FIG. 17B is a diagram schematically illustrating the thinned image B.

FIG. 17C is a diagram schematically illustrating the thinned image C.

FIG. 17D is a diagram schematically illustrating the thinned image D.

FIG. 18 is a diagram schematically illustrating composite images generated in step S24.

FIG. 19 is a diagram describing processing of detecting an optical flow in step S25.

FIG. 20 is a diagram describing the pixel array section and the control signal generation section of the photodetection device according to a fourth embodiment.

FIG. 21 is a flowchart illustrating processing operation of the photodetection device according to the fourth embodiment.

FIG. 22 is a diagram illustrating an example in which some pixels in each of macropixels are brought into a pseudo light shielding state.

FIG. 23 is a block diagram illustrating an example of a functional configuration of an imaging device according to a first application example of the present disclosure.

FIG. 24 is a schematic plan view illustrating a schematic configuration of the imaging device illustrated in FIG. 23.

FIG. 25 is a schematic diagram illustrating a cross-sectional configuration taken along line III-III′ illustrated in FIG. 24.

FIG. 26 is an equivalent circuit diagram of a pixel sharing unit illustrated in FIG. 23.

FIG. 27 is a diagram illustrating an example of a connection mode between a plurality of pixel sharing units and a plurality of vertical signal lines.

FIG. 28 is a schematic cross-sectional view illustrating an example of a specific configuration of the imaging device illustrated in FIG. 25.

FIG. 29A is a schematic diagram illustrating an example of a planar configuration of a main part of a first substrate illustrated in FIG. 28.

FIG. 29B is a schematic diagram illustrating a planar configuration of pad portions together with the main part of the first substrate illustrated in FIG. 29A.

FIG. 30 is a schematic diagram illustrating an example of a planar configuration of a second substrate (semiconductor layer) illustrated in FIG. 28.

FIG. 31 is a schematic diagram illustrating an example of a planar configuration of main parts of the pixel circuit and the first substrate together with a first wiring layer illustrated in FIG. 28.

FIG. 32 is a schematic diagram illustrating an example of a planar configuration of the first wiring layer and a second wiring layer illustrated in FIG. 28.

FIG. 33 is a schematic diagram illustrating an example of a planar configuration of the second wiring layer and a third wiring layer illustrated in FIG. 28.

FIG. 34 is a schematic diagram illustrating an example of a planar configuration of the third wiring layer and a fourth wiring layer illustrated in FIG. 28.

FIG. 35 is a schematic diagram for explaining a path of an input signal to the imaging device illustrated in FIG. 25.

FIG. 36 is a schematic diagram for explaining a signal path of a pixel signal of the imaging device illustrated in FIG. 25.

FIG. 37 is a schematic diagram illustrating a modification of the planar configuration of the second substrate (semiconductor layer) illustrated in FIG. 30.

FIG. 38 is a schematic diagram illustrating a planar configuration of main parts of the first wiring layer and the first substrate together with the pixel circuit illustrated in FIG. 37.

FIG. 39 is a schematic diagram illustrating an example of the planar configuration of the second wiring layer together with the first wiring layer illustrated in FIG. 38.

FIG. 40 is a schematic diagram illustrating an example of a planar configuration of the third wiring layer together with the second wiring layer illustrated in FIG. 39.

FIG. 41 is a schematic diagram illustrating an example of a planar configuration of the fourth wiring layer together with the third wiring layer illustrated in FIG. 40.

FIG. 42 is a schematic diagram illustrating a modification of the planar configuration of the first substrate illustrated in FIG. 29A.

FIG. 43 is a schematic diagram illustrating an example of the planar configuration of the second substrate (semiconductor layer) stacked on the first substrate illustrated in FIG. 42.

FIG. 44 is a schematic diagram illustrating an example of the planar configuration of the first wiring layer together with the pixel circuit illustrated in FIG. 43.

FIG. 45 is a schematic diagram illustrating an example of the planar configuration of the second wiring layer together with the first wiring layer illustrated in FIG. 44.

FIG. 46 is a schematic diagram illustrating an example of the planar configuration of the third wiring layer together with the second wiring layer illustrated in FIG. 45.

FIG. 47 is a schematic diagram illustrating an example of the planar configuration of the fourth wiring layer together with the third wiring layer illustrated in FIG. 46.

FIG. 48 is a schematic diagram illustrating another example of the planar configuration of the first substrate illustrated in FIG. 42.

FIG. 49 is a schematic diagram illustrating an example of the planar configuration of the second substrate (semiconductor layer) stacked on the first substrate illustrated in FIG. 48.

FIG. 50 is a schematic diagram illustrating an example of the planar configuration of the first wiring layer together with the pixel circuit illustrated in FIG. 49.

FIG. 51 is a schematic diagram illustrating an example of the planar configuration of the second wiring layer together with the first wiring layer illustrated in FIG. 50.

FIG. 52 is a schematic diagram illustrating an example of the planar configuration of the third wiring layer together with the second wiring layer illustrated in FIG. 51.

FIG. 53 is a schematic diagram illustrating an example of the planar configuration of the fourth wiring layer together with the third wiring layer illustrated in FIG. 52.

FIG. 54 is a schematic cross-sectional view illustrating another example of the imaging device illustrated in FIG. 25.

FIG. 55 is a schematic diagram for explaining a path of an input signal to the imaging device illustrated in FIG. 54.

FIG. 56 is a schematic diagram for explaining a signal path of a pixel signal of the imaging device illustrated in FIG. 54.

FIG. 57 is a schematic cross-sectional view illustrating another example of the imaging device illustrated in FIG. 28.

FIG. 58 is a diagram illustrating another example of the equivalent circuit illustrated in FIG. 26.

FIG. 59 is a schematic plan view illustrating another example of a pixel isolation portion illustrated in FIG. 29A and the like.

FIG. 60 is a diagram illustrating an example of a schematic configuration of an imaging system including the imaging device according to the above embodiments and modifications thereof.

FIG. 61 is a diagram illustrating an example of an imaging procedure in the imaging system illustrated in FIG. 60.

FIG. 62 is a block diagram illustrating an example of a schematic configuration of a vehicle control system.

FIG. 63 is an explanatory diagram illustrating an example of installation positions of an outside-vehicle information detecting section and an imaging section.

FIG. 64 is a diagram illustrating an example of a schematic configuration of an endoscopic surgery system.

FIG. 65 is a block diagram illustrating an example of a functional configuration of a camera head and a CCU.

### MODE FOR CARRYING OUT THE INVENTION

Embodiments of a photodetection device and an electronic apparatus will be described hereinafter with reference to the drawings. Hereinafter, main components of the photodetection device and the electronic apparatus will be mainly described, but the photodetection device and the electronic apparatus may have components and functions that are not illustrated or described. The following description is not intended to exclude components and functions that are not illustrated or described.

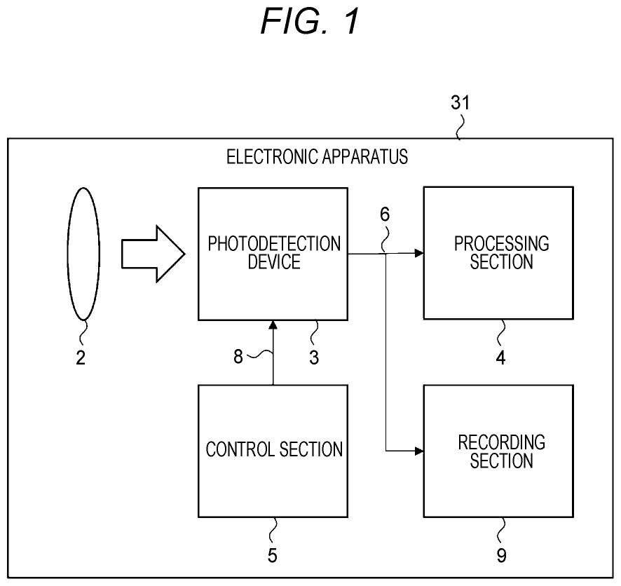

FIG. 1 is a block diagram of an electronic apparatus 31 in a first embodiment of the present disclosure. The electronic apparatus 31 captures image data, and includes an imaging lens 2, a photodetection device 3, a processing section 4, and a control section 5. As the electronic apparatus 31, for example, a camera mounted on an industrial robot, a camera mounted on a drone, a medical apparatus, an in-vehicle camera, or the like is assumed, but a specific application and configuration of the electronic apparatus 31 are arbitrary.

The imaging lens 2 condenses incident light and guides the light to the photodetection device 3. The photodetection device 3 is, for example, a complementary metal-oxide-semiconductor (CMOS) image sensor, and photoelectrically converts incident light to capture image data. The image data output from the photodetection device 3 is input to the processing section 4 via a transmission line 6. The processing section 4 performs predetermined image processing on the image data output from the photodetection device 3.

The electronic apparatus 31 may include a recording section 9. The recording section 9 records the image data from the photodetection device 3. The recording section 9 may be arranged in a server or the like connected via a network.

The control section 5 controls an imaging timing in the photodetection device 3 and the like via a control line 8. For example, the control section 5 controls start and end of imaging in the photodetection device 3 in accordance with operation of a shutter operation member (not illustrated).

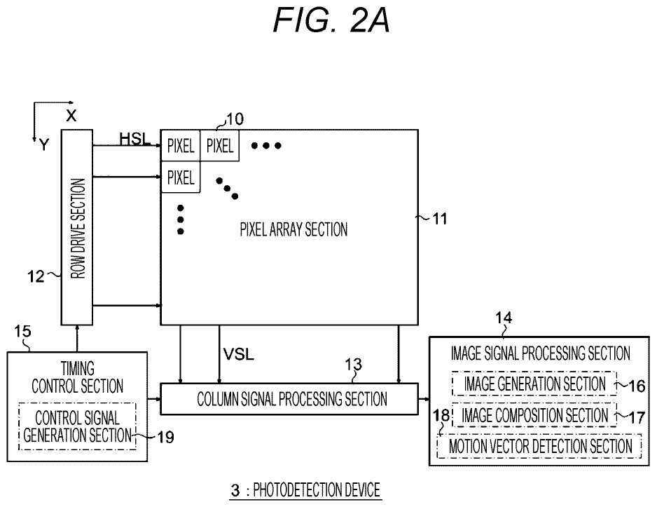

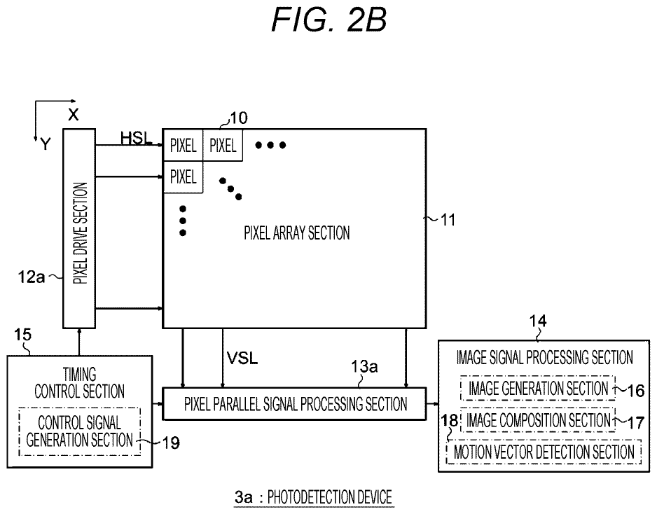

FIGS. 2A and 2B are block diagrams of the photodetection device 3 in the first embodiment of the present disclosure. The photodetection device 3 of FIG. 2A illustrates a block configuration in a case where a so-called column AD method is adopted, and includes a pixel array section 11, a row drive section 12, a column signal processing section 13, an image signal processing section 14, and a timing control section 15.

The pixel array section 11 of FIG. 2A includes a plurality of pixels 10 arranged in a first direction X and a second direction Y. In the present specification, the left-right (horizontal) direction in FIG. 2 is referred to as the first direction X, and the top-down (vertical) direction in FIG. 2 is referred to as the second direction Y. Furthermore, a plurality of groups of pixels 10 arranged along the first direction X is each referred to as a pixel row, and a plurality of groups of pixels 10 arranged along the second direction Y is each referred to as a pixel column. The pixel array section 11 includes a plurality of row selection lines HSL arranged along the first direction X and a plurality of vertical signal lines VSL arranged along the second direction Y. The pixel array section 11 is divided into a plurality of pixel groups including some pixels 10 different from each other on the basis of a plurality of pixel control signals.

Each pixel 10 includes a photoelectric conversion element that generates a charge according to an amount of incident light. The pixel 10 is connected to a pixel circuit (not illustrated in FIG. 2). As described later, the pixel circuit includes a pixel transistor, and generates a pixel signal corresponding to the charge generated by the photoelectric conversion element. At least a part of the pixel circuit may be arranged on the same surface on which the pixel 10 is arranged. Alternatively, at least a part of the pixel circuit may be arranged on a surface different from the surface on which the pixel 10 is arranged.

The row drive section 12 of FIG. 2A includes a shift register, an address decoder, and the like. The row drive section 12 sequentially drives the plurality of row selection lines HSL. Each row selection line HSL is connected to a pixel row including a plurality of pixels 10, and the pixels 10 are driven in units of pixel rows.

The column signal processing section 13 includes an analog-digital (AD) converter that converts the pixel signal transmitted from each pixel 10 to the vertical signal line VSL into a digital pixel signal. Furthermore, the column signal processing section 13 may perform correlated double sampling (CDS) processing for detecting a difference between the digital pixel signal at a pixel signal level and the digital pixel signal at a reset level.

The image signal processing section 14 generates image data in units of frames on the basis of the digital pixel signal output from the column signal processing section 13. As described later, the image signal processing section 14 is provided with an image generation section 16, an image composition section 17, a motion vector detection section 18, or the like as necessary.

The image generation section 16 generates a plurality of thinned images by exposing the plurality of pixel groups within a predetermined frame period while shifting at least one of exposure start times or exposure end times from each other. The image composition section 17 generates a plurality of thinned images at a frame rate identical to a frame rate in a case where image data based on all of the plurality of pixels is generated. The image composition section 17 generates a composite image obtained by combining the plurality of thinned images. The motion vector detection section 18 detects a motion vector of a feature point included in the composite image on the basis of the composite image.

The timing control section 15 controls operation timings of the row drive section 12 and the column signal processing section 13. The timing control section 15 includes a control signal generation section 19 as described later. The control signal generation section 19 generates a plurality of pixel control signals.

A photodetection device 3a of FIG. 2B illustrates a block configuration in a case where a so-called pixel parallel AD method is adopted, and includes a pixel drive section 12a instead of the row drive section 12 of FIG. 2A, and includes a pixel parallel signal processing section 13a instead of the column signal processing section 13 of FIG. 2A. The pixel drive section 12a of FIG. 2B can drive any pixel row in the pixel array section 11, and can also drive row selection lines of any plurality of rows in parallel. Furthermore, the pixel parallel signal processing section 13a of FIG. 2B can perform AD conversion on the pixel signals output from the pixels 10 in any pixel column in the pixel array section 11, and can also perform AD conversion on the pixel signals output from the plurality of pixels 10 in any plurality of pixel columns in parallel.

Note that, in each embodiment described below, the description will be given on the basis of the block configuration of the photodetection device 3 of FIG. 2A, but each embodiment is also applicable to the block configuration of FIG. 2B.

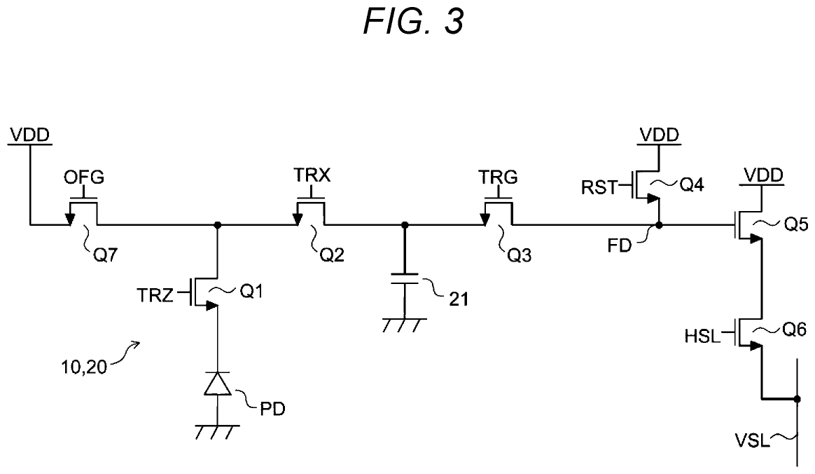

FIG. 3 is a circuit diagram illustrating an example of a circuit configuration of the pixel 10 and a pixel circuit 20. The pixel 10 and the pixel circuit 20 of FIG. 3 include a photodiode PD, a first transfer transistor Q1, a second transfer transistor Q2, a third transfer transistor Q3, a reset transistor Q4, an amplification transistor Q5, a selection transistor Q6, an overflow transistor Q7, and a floating diffusion (floating diffusion region) FD.

The photodiode PD and the first to third transfer transistors Q1 to Q3 of FIG. 3 are included in the pixel 10, and the others are included in the pixel circuit 20. Note that a boundary between the pixel 10 and the pixel circuit 20 is arbitrary, and for example, the first to third transfer transistors Q1 to Q3 may be interpreted as being included in the pixel circuit 20. FIG. 3 illustrates an example in which the pixel 10 and the pixel circuit 20 correspond to each other on a one-to-one basis, but there may be a configuration in which a plurality of pixels 10 shares at least a part of the circuit of the pixel circuit 20.

Note that, in the following, a description will be given of an example in which all the transistors in the pixel circuit 20 are NMOS transistors.

The photodiode PD is a photoelectric conversion element, and the anode is grounded and the cathode is connected to the source of the first transfer transistor Q1. The drain of the first transfer transistor Q1 is connected to the source of the second transfer transistor Q2 and the drain of the overflow transistor Q7. A global shutter (GS) memory (charge holding portion) 21 is arranged between a ground node and a connection node connecting together the drain of the second transfer transistor Q2 and the source of the third transfer transistor Q3. The GS memory 21 is provided for each pixel 10. In the GS memory 21, for each pixel group to be described later, all the pixels 10 in the pixel group simultaneously hold accumulated charges of the photodiodes PD. Furthermore, the charges held in the GS memory 21 are collectively read for each pixel group, for example. As described above, since the pixel circuit 20 of FIG. 3 includes the GS memory 21, global shutter operation is possible.

The drain of the third transfer transistor Q3, the source of the reset transistor Q4, and the gate of the amplification transistor Q5 are connected to the floating diffusion FD. The source of the amplification transistor Q5 is connected to the drain of the selection transistor Q6. The row selection line HSL is connected to the gate of the selection transistor Q6. The source of the selection transistor Q6 is connected to the vertical signal line VSL. The source of the overflow transistor Q7 is connected to a power-supply voltage node.

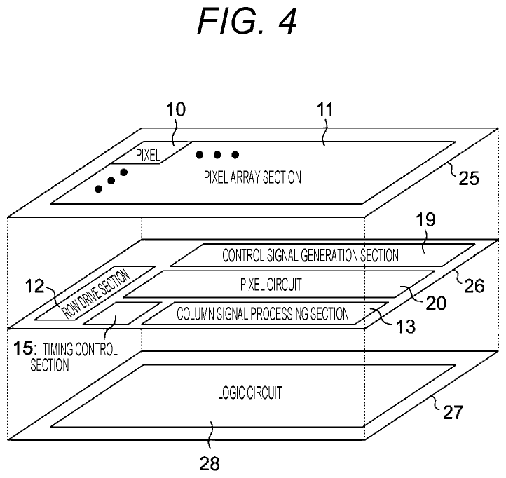

The photodetection device 3 according to the present disclosure can be formed into a chip by using a semiconductor process. FIG. 4 is a perspective view schematically illustrating a chip configuration of the photodetection device 3 according to the present disclosure. The photodetection device 3 of FIG. 4 has a structure in which a first substrate (first chip) 25, a second substrate 26 (second chip), and a third substrate 27 (third chip) are stacked. The plurality of pixels 10 in the pixel array section 11 is arranged on the first substrate 25. At least a part of a plurality of the pixel circuits 20 in the pixel array section 11 and at least a part of the row drive section 12, the column signal processing section 13, and the timing control section 15 are arranged on the second substrate 26. The control signal generation section 19 described above is also arranged on the second substrate 26. On the third substrate 27, a logic circuit 28 including an image signal processing section 14 and the like is arranged. The logic circuit 28 may include at least a part of the row drive section 12 and the column signal processing section 13.

Components arranged on the first substrate 25, the second substrate 26, and the third substrate 27 are arbitrary, and are not necessarily limited to those illustrated in FIG. 4.

Hereinafter, descriptions will be sequentially given of a characteristic configuration and operation of the photodetection device 3 according to the present disclosure.

### FIRST EMBODIMENT

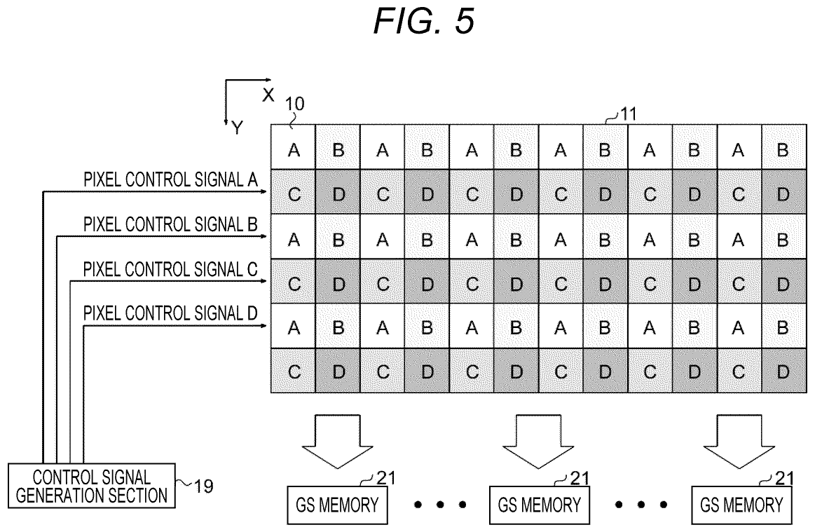

FIG. 5 is a diagram describing the pixel array section 11 and the control signal generation section 19 of the photodetection device 3 according to the first embodiment. The number of pixels 10 of the pixel array section 11 is arbitrary. The pixel array section 11 of FIG. 5 illustrates an example in which the plurality of pixels 10 arranged in the first direction X and the second direction Y is divided into four pixel groups A to D. Note that the number of divided pixel groups is not necessarily limited to four. Each pixel group is arranged, for example, every other pixel in each of the first direction X and the second direction Y. Thus, each of the pixel groups A, B, C, and D is used to generate four thinned images obtained by thinning out of all the pixels 10 in the pixel array section 11 to ¼. As described above, each of the plurality of pixel groups includes two or more pixels 10 that are not adjacent to each other in the first direction X and the second direction Y.

In order to divide the plurality of pixels 10 of the pixel array section 11 into the plurality of pixel groups A to D, a plurality of pixel control signals generated by the control signal generation section 19 is used. When the control signal generation section 19 is arranged on the same substrate on which the pixel array section 11 is arranged, an area of the pixel array section 11 is compressed, which hinders high resolution. Thus, in the present embodiment, it is assumed that the photodetection device 3 has a three-layer structure of the first to third substrates 25 to 27 as illustrated in FIG. 4, the plurality of pixels 10 of the pixel array section 11 is arranged on the first substrate 25, and the control signal generation section 19 is arranged on the second substrate 26. Transmission and reception of various signals between the first substrate 25 and the second substrate 26 are performed through, for example, a via, a bump, Cu—Cu bonding, or the like. In addition to the control signal generation section 19, the row drive section 12, the column signal processing section 13, the timing control section 15, and the like are arranged on the second substrate 26, but there is more empty space than in the first substrate 25 on which the plurality of pixels 10 is arranged. Thus, by providing the control signal generation section 19 on the second substrate 26 and transmitting the plurality of pixel control signals to the first substrate 25 through, for example, a via, a contact, or the like, it is possible to divide the plurality of pixels 10 of the pixel array section 11 into a plurality of pixel groups without affecting the area of the pixel array section 11 of the first substrate 25. Note that the pixel array section 11 includes the plurality of pixels 10 and the plurality of pixel circuits 20, but at least a part of the plurality of pixel circuits 20 may be arranged on the second substrate 26.

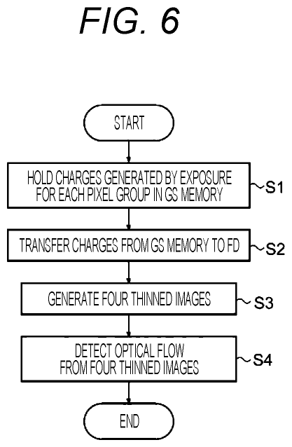

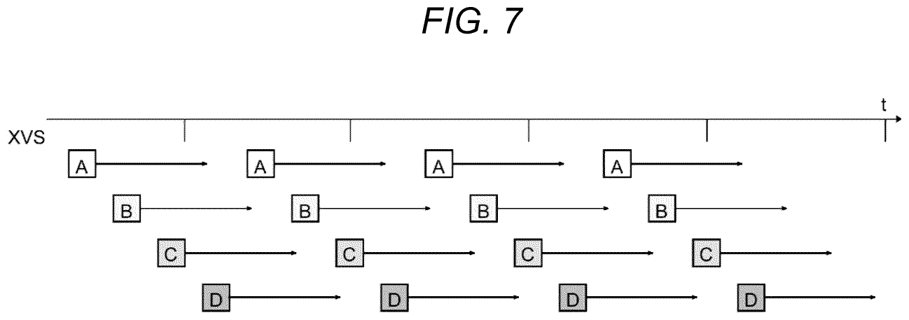

FIG. 6 is a flowchart illustrating processing operation of the photodetection device 3 according to the first embodiment, and FIG. 7 is a diagram illustrating exposure and transfer timings of the charges of the pixel groups A to D. The photodetection device 3 according to the first embodiment performs the processing of the flowchart of FIG. 6 when starting imaging processing. XVS in FIG. 7 is a frame synchronization signal. First, as illustrated in FIG. 7, for each of the four pixel groups A to D, exposure is performed while the exposure start time is shifted within one frame period, and charges photoelectrically converted by the photodiode PD from the start of exposure until an exposure time common in the four pixel groups A to D elapses are held in the GS memory 21 via the first and second transfer transistors Q1 and Q2 (step S1).

As described above, in the first embodiment, the pixel groups A to D respectively start exposure at different timings, but the exposure times of the pixel groups A to D are the same as each other. Since the exposure start time is different for each of the pixel groups A to D, a timing at which the charges are held in the GS memory 21 is also different for each of the pixel groups A to D. The GS memory 21 holds the charges photoelectrically converted in each of the plurality of pixel groups at an aligned timing for each pixel group.

Control of the exposure start times and the exposure times of the pixel groups A to D in FIG. 7 is performed according to the pixel control signals generated by the control signal generation section 19. The control signal generation section 19 is provided in, for example, the timing control section 15, and the pixel control signals generated by the control signal generation section 19 are supplied to the row drive section 12 and the column signal processing section 13.

Next, the charges held in the GS memory 21 are transferred to the floating diffusion FD via the third transfer transistor Q3 at a timing determined for each pixel group after the exposure of the pixel groups A to D ends (step S2). The charges transferred to the floating diffusion FD are converted into a voltage signal, a pixel signal is generated by the amplification transistor Q5, and is transmitted to the vertical signal line VSL via the selection transistor Q6. The column signal processing section 13 performs AD conversion on the pixel signal transmitted through the vertical signal line VSL to generate a digital pixel signal.

Next, the image signal processing section 14 performs remosaic and demosaic processing on the digital pixel signals of the respective pixel groups to generate four thinned images corresponding to the four pixel groups A to D (step S3). The plurality of thinned images is generated on the basis of charges photoelectrically converted by a plurality of pixel groups for which at least the exposure start times or exposure end times are different from each other and the exposure times are the same as each other.

As illustrated in FIG. 7, after the charges are transferred from the GS memory 21 to the floating diffusion FD, the pixel groups A to D can start exposure of the next frame. For example, when the exposure time of the pixel group A ends, the pixel groups B to D are still being exposed. However, the pixel group A can start exposure of the next frame without waiting for the end of exposure of the pixel groups B to D. As a result, the pixel groups A to D can continue exposure while the exposure start times are shifted a little from each other within one frame period, and a feature point used for detection of an optical flow can be included in all of the pixel groups A to D. As described above, each of the plurality of pixel groups starts exposure of the next frame after reading the charges from the GS memory 21 while another pixel group is performing exposure.

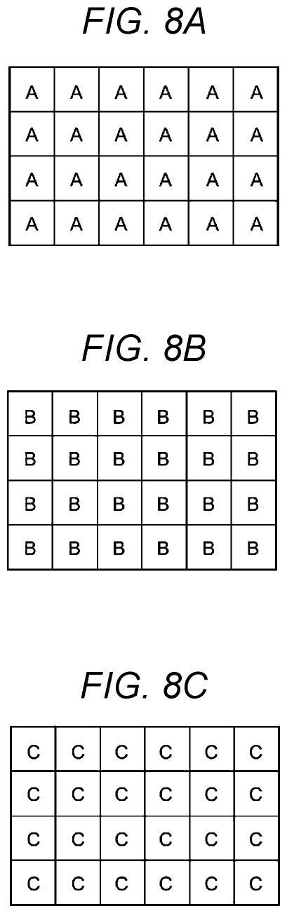

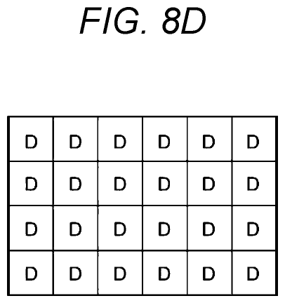

FIG. 8A is a diagram schematically illustrating a thinned image A corresponding to the pixel group A, FIG. 8B is a diagram schematically illustrating a thinned image B corresponding to the pixel group B, FIG. 8C is a diagram schematically illustrating a thinned image C corresponding to the pixel group C, and FIG. 8D is a diagram schematically illustrating a thinned image D corresponding to the pixel group D. Since exposure and charge reading are performed in the order of the pixel groups A, B, C, and D, the thinned images A, B, C, and D are generated in this order.

Next, the four thinned images A to D are arranged in chronological order in the generated order, and the optical flow is detected from an amount of movement of the feature point included in each image (step S4).

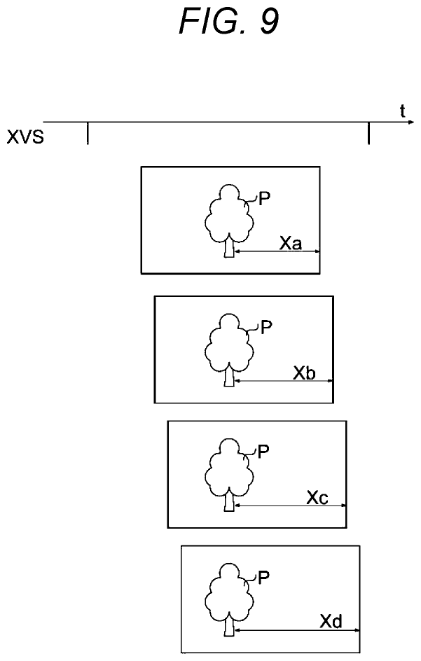

FIG. 9 is a diagram describing a method of generating an optical flow. Since the thinned images A to D are generated with the times shifted a little from each other within one frame period, there is a high possibility that the feature point (for example, a specific object) P is included in all of the thinned images A to D, and it is possible to detect the optical flow easily and accurately by detecting amounts of movement Xa, Xb, Xc, and Xd of the feature point P in the respective thinned images A to D.

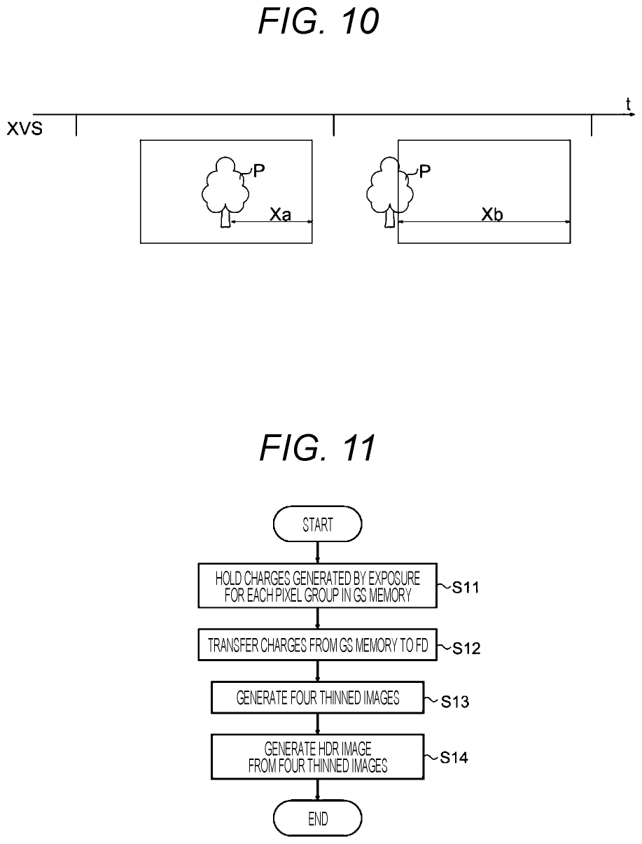

FIG. 10 is a diagram describing a method of generating an optical flow according to a comparative example. In one comparative example, a frame image is generated in units of frames by use of all the pixels 10 of the pixel array section 11, and an optical flow is detected on the basis of the amounts of movement Xa and Xb of the feature point P included in two adjacent frame images. Since the frame images are generated at a period (hereinafter, a frame period) according to the frame rate, a time interval at which the frame images are generated is much longer than a time interval at which the thinned images are generated in the first embodiment. Thus, there is a low possibility that the feature point P is included in both of the two adjacent frame images, and detection accuracy of the optical flow decreases.

As described above, in the first embodiment, since the plurality of thinned images is generated with the exposure start times shifted from each other within one frame period and the exposure times equal to each other, there is a high possibility that the feature point P is included in the plurality of thinned images, and the optical flow can be accurately detected on the basis of the amounts of movement of the feature point P.

Furthermore, since the control signal generation section 19 that generates the plurality of pixel control signals used to divide the plurality of pixels 10 of the pixel array section 11 into the plurality of pixel groups is arranged on the second substrate 26 different from the first substrate 25 on which the pixel array section 11 is arranged, there is no possibility that the area of the pixel array section 11 is compressed by provision of the control signal generation section 19, and high resolution can be achieved.

### SECOND EMBODIMENT

A second embodiment is characterized in that an HDR image with an expanded dynamic range is generated.

The photodetection device 3 according to the second embodiment has a block configuration similar to that of FIG. 2, and is the same in that the pixel array section 11 is divided into a plurality of pixel groups as in FIG. 5. Hereinafter, differences from the first embodiment will be mainly described.

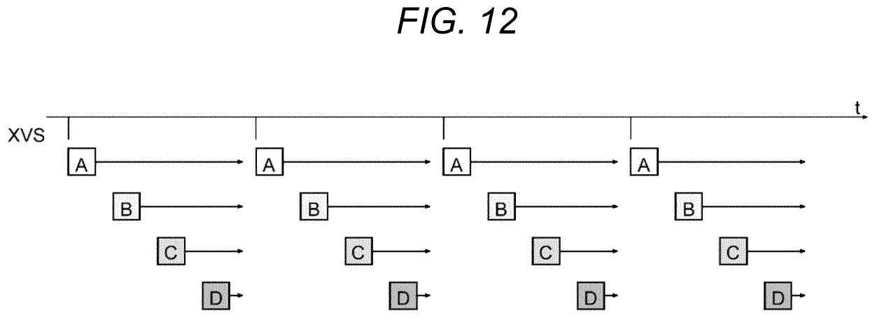

FIG. 11 is a flowchart illustrating processing operation of the photodetection device 3 according to the second embodiment, and FIG. 12 is a diagram illustrating exposure and transfer timings of the charges of the pixel groups A to D. The photodetection device 3 according to the second embodiment performs the processing of the flowchart of FIG. 11 when starting imaging processing. First, as illustrated in FIG. 12, for each of the four pixel groups A to D, exposure is performed while at least one of the exposure start time or the exposure end time is shifted within one frame period, and charges photoelectrically converted by the photodiode PD until an exposure time different for each of the four pixel groups A to D elapses are held in the GS memory 21 via the first and second transfer transistors Q1 and Q2 (step S11).

As illustrated in FIG. 12, in the second embodiment, the exposure time is different for each of the pixel groups A to D, and the exposure time is shorter in the order of the pixel groups A, B, C, and D. Furthermore, in the second embodiment, the exposure end times of the pixel groups A to D are substantially the same as each other. Also in the second embodiment, control of at least one of the exposure start times or the exposure end times and the exposure time of the pixel groups A to D is performed according to a plurality of pixel control signals generated by the control signal generation section 19.

The charges photoelectrically converted in each of the pixel groups A to D and held in the GS memory 21 are transferred to the floating diffusion FD via the third transfer transistor Q3 all at once in all the pixels 10 to be converted into a voltage signal, and a pixel signal is generated in the amplification transistor Q5 (step S12). The pixel signal of each pixel 10 is transmitted to the column signal processing section 13 via the vertical signal line VSL, and a digital pixel signal is generated.

Next, the image signal processing section 14 performs remosaic and demosaic processing on the digital pixel signals of the respective pixel groups to generate four thinned images corresponding to the four pixel groups A to D (step S13). Note that, also in the second embodiment, the number of thinned images is not necessarily limited to four. The plurality of thinned images is generated on the basis of charges photoelectrically converted by a plurality of pixel groups for which at least one of the exposure start times or the exposure end times are different from each other and the exposure times are different from each other.

As illustrated in FIG. 12, in the pixel groups A to D, exposure end times are substantially the same as each other, so that the exposure is started in the order of the pixel groups A, B, C, and D also for the next frame. Furthermore, in the pixel group A for which exposure is started the earliest, exposure of the next frame is started after the exposure of the other pixel groups B to D ends. As described above, in the plurality of pixel groups, the charges from the GS memory 21 are read at the same timing, and then exposure of the next frame is started at a timing shifted for each pixel group.

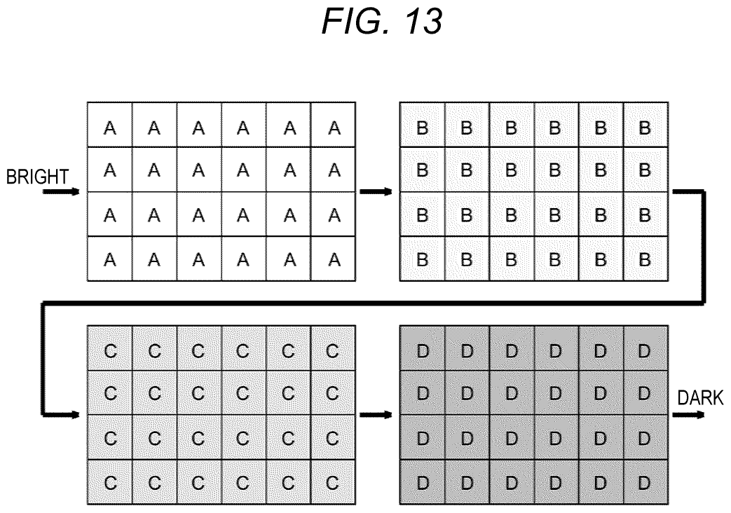

FIG. 13 is a diagram in which the thinned images A to D are arranged in order of luminance. Since the exposure time is shorter in the order of the thinned images A, B, C, and D, the luminance is darker in the order of the thinned images A, B, C, and D. Thus, although the thinned image A is more excellent in imaging in a dark place, blown out highlights are most likely to occur. Furthermore, the thinned image D can be imaged without blown out highlights of a subject with high luminance, but blocked up shadows are likely to occur.

Next, the image composition section 17 in the image signal processing section 14 combines the four thinned images A to D to generate one composite image with less blown out highlights and blocked up shadows (step S14). The composite image has a larger dynamic range than dynamic ranges of the thinned images A to D, and is also called an HDR image.

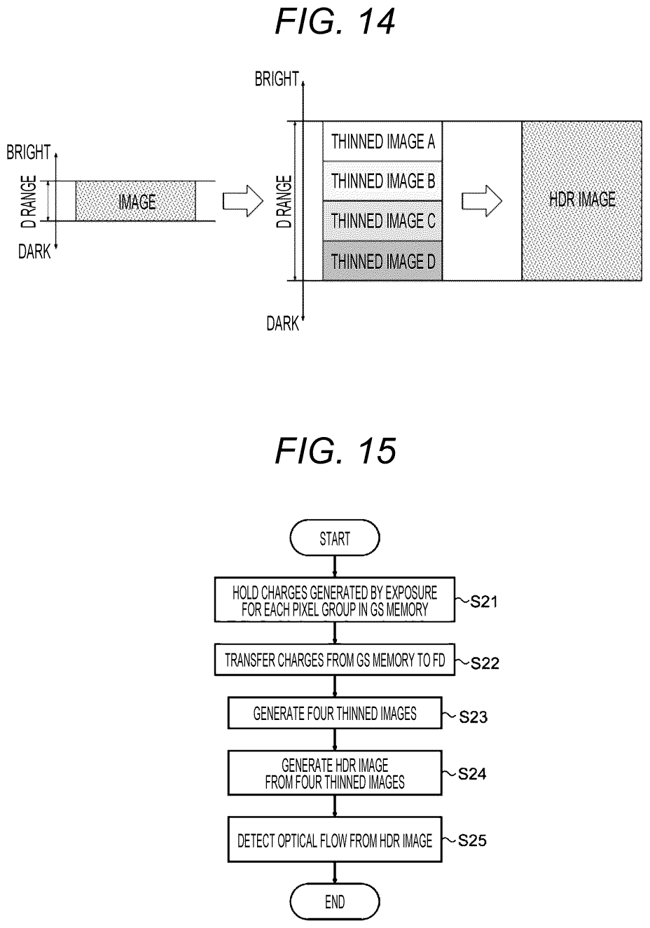

FIG. 14 is a diagram schematically illustrating the dynamic range of the composite image. In FIG. 14, the vertical axis represents luminance. By combining the thinned images A to D, it is possible to obtain a composite image in which blown out highlights and blocked up shadows hardly occur from a bright side to a dark side in luminance. The left side of FIG. 14 illustrates a dynamic range of an image generated with the exposure times of all the pixels 10 of the pixel array section 11 set to the same. The composite image (HDR image) generated by the second embodiment can expand the dynamic range much more than the dynamic range of the image on the left side.

As described above, in the second embodiment, since at least one of the exposure start times or the exposure end times and the exposure times of the pixel groups A to D are made different from each other by the plurality of pixel control signals, it is possible to generate a composite image (HDR image) with an expanded dynamic range by combining the plurality of thinned images A to D generated by the charges photoelectrically converted in these pixel groups.

### THIRD EMBODIMENT

A third embodiment is a combination of the first and second embodiments, and is characterized in that an HDR image is generated and an optical flow is detected on the basis of the HDR image.

The photodetection device 3 according to the third embodiment has a block configuration similar to that of FIG. 2, and is the same in that the pixel array section 11 is divided into a plurality of pixel groups as in FIG. 5. Hereinafter, differences from the first embodiment will be mainly described.

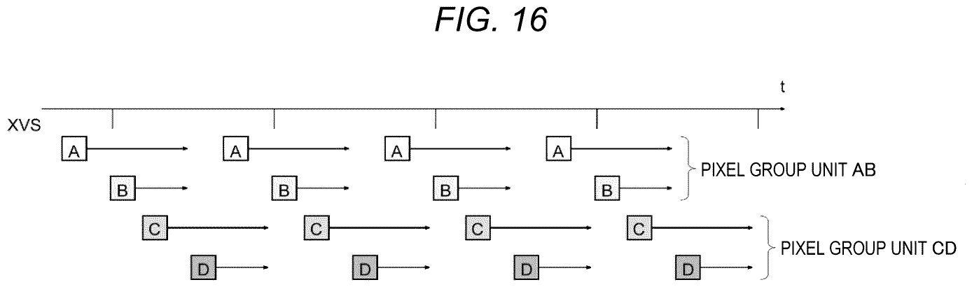

FIG. 15 is a flowchart illustrating processing operation of the photodetection device 3 according to the third embodiment, and FIG. 16 is a diagram illustrating exposure and transfer timings of the charges of the pixel groups A to D. The photodetection device 3 according to the third embodiment performs the processing of the flowchart of FIG. 15 when starting imaging processing.

In the third embodiment, a plurality of pixel groups is classified into two or more pixel group units. Each of the two or more pixel group units includes two or more pixel groups for which exposure times are different from each other. In the example in FIG. 16, four pixel groups A to D are classified into two pixel group units AB and CD. Note that the number of pixel group units is arbitrary, and the number of pixel groups included in each pixel group unit is also arbitrary.

The exposure start time of the pixel group unit AB is earlier than the exposure start time of the pixel group unit CD. The pixel group unit AB includes the pixel group A for which the exposure time is long and the pixel group B for which the exposure time is short. The pixel group unit CD includes the pixel group C for which the exposure time is long and the pixel group D for which the exposure time is short. The exposure start time of the pixel group A is earlier than the exposure start time of the pixel group B. The exposure end times of the pixel groups A and B are substantially the same as each other. The exposure start time of the pixel group C is earlier than the exposure start time of the pixel group D. The exposure end times of the pixel groups C and D are substantially the same as each other. The exposure times of the pixel groups A and C are substantially the same as each other, and the exposure times of the pixel groups B and D are substantially the same as each other. As described above, each of the two or more pixel group units includes two or more pixel groups for which at least one of the exposure start times or the exposure end times are different from each other and the exposure times are different from each other within a predetermined frame period. The two or more pixel group units generate two or more thinned image groups. The two or more pixel groups included in each of the two or more pixel group units end the exposure at the same timing, and an exposure end timing is different for each of the two or more pixel group units.

The pixel group unit AB generates a thinned image group AB. The thinned image group AB includes, for example, two thinned images A and B. Furthermore, the pixel group unit CD generates a thinned image group CD. The thinned image group CD includes, for example, two thinned images C and D.

Hereinafter, the processing operation of the photodetection device 3 according to the third embodiment will be described with reference to the flowchart of FIG. 15. First, as illustrated in FIG. 16, the exposure is started in the order of the pixel groups A, B, C, and D, and the charges photoelectrically converted by the photodiode PD until each of exposure times respectively determined elapses are held in the GS memory 21 via the first and second transfer transistors Q1 and Q2 (step S21).

Next, after the lapse of the exposure time, pixel 10 readout operation is performed in which the charges held in the GS memory 21 are transferred to the floating diffusion FD collectively for each pixel group and converted into a voltage signal, and a pixel signal is generated in the amplification transistor Q5 and transmitted to the vertical signal line VSL (step S22). The pixel signal on the vertical signal line VSL is converted into a digital pixel signal by the column signal processing section 13.

Next, the image signal processing section 14 performs remosaic and demosaic processing on the digital pixel signals of the respective pixel groups to generate four thinned images A to D corresponding to the four pixel groups A to D (step S23).

As described above, the thinned images A and B constitute the thinned image group AB, and the thinned images C and D constitute the thinned image group CD. Among the four thinned images A to D, for the thinned images A and C, exposure times are longer than for the thinned images B and D. Furthermore, the exposure timing is in the order of the thinned images A, B, C, and D.

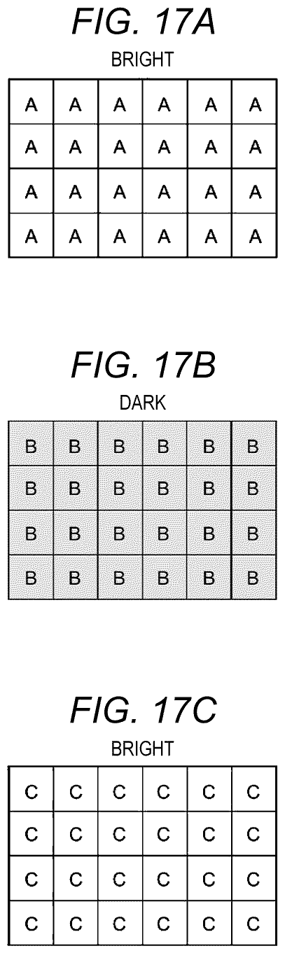

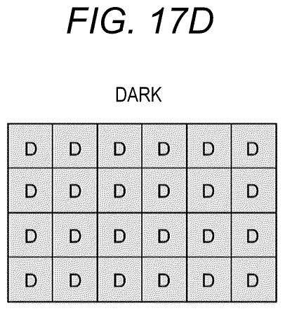

FIG. 17A is a diagram schematically illustrating the thinned image A, FIG. 17B is a diagram schematically illustrating the thinned image B, FIG. 17C is a diagram schematically illustrating the image C, and FIG. 17D is a diagram schematically illustrating the thinned image D. In each of the thinned images A to D, the number of pixels 10 is ¼ of the total number of pixels 10 of the pixel array section 11.

Next, the image composition section 17 generates, at timings shifted from each other, a composite image AB obtained by combining the thinned images A and B, and a composite image CD obtained by combining the thinned images C and D (step S24).

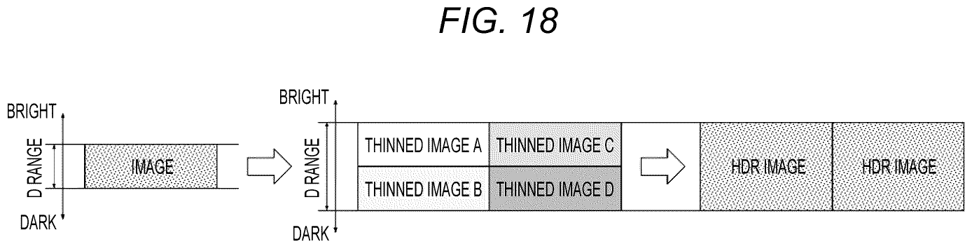

FIG. 18 is a diagram schematically illustrating the composite images generated in step S24. In FIG. 18, the vertical axis represents the dynamic range. The left side of FIG. 18 illustrates a dynamic range of an image generated by exposure of all the pixels 10 of the pixel array section 11 in the same exposure time. As illustrated in FIG. 18, the dynamic range can be expanded by combination of the thinned image A or C for which the exposure time is long and the thinned image B or D for which the exposure time is short, as compared with the image on the left side.

Next, an optical flow is detected on the basis of the amounts of movement of the feature point P imaged in the two composite images generated in step S24 (step S25).

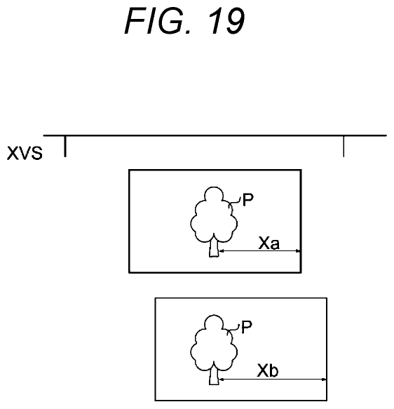

FIG. 19 is a diagram describing processing of detecting the optical flow in step S25. Since the composite image AB and the composite image CD are generated at slightly shifted times within the same frame period, there is a high possibility that the feature point P is included in both the composite images AB and CD. Thus, the detection accuracy of the optical flow can be improved.

As described above, in the third embodiment, the plurality of pixel groups A to D is classified into two or more pixel group units AB and CD, and two or more pixel groups for which the exposure times are different from each other are provided for each of the pixel group units AB and CD. Then, at least one of the exposure start times and the exposure end times of the two or more pixel group units AB and CD are shifted from each other. As a result, two or more composite images can be generated at times shifted from each other within one frame period, and the dynamic range of each composite image can be expanded. In addition, since two or more composite images are generated within one frame period, there is a high possibility that the feature point P is included in each composite image, and the optical flow can be accurately detected.

### FOURTH EMBODIMENT

A fourth embodiment is characterized in that phase difference detection is performed.

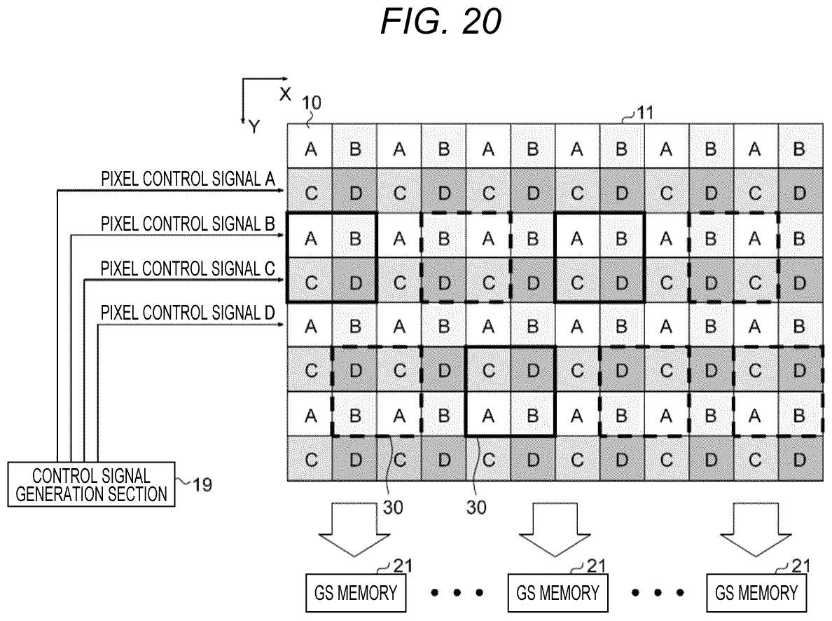

FIG. 20 is a diagram describing the pixel array section 11 and the control signal generation section 19 of the photodetection device 3 according to the fourth embodiment. The pixel array section 11 in FIG. 20 includes the plurality of pixels 10 arranged in the first direction X and the second direction Y. The plurality of pixels 10 of the pixel array section 11 is divided into a plurality of macropixels 30 each including two or more pixels 10 adjacent to each other in at least one of the first direction X or the second direction Y on the basis of a plurality of pixel control signals.

FIG. 20 illustrates an example in which each macropixel 30 is generated by a total of four pixels 10 of two pixels 10 adjacent to each other in each of the first direction X and the second direction Y, but the size of the macropixel 30 and the arrangement of the pixels 10 are arbitrary. In FIG. 20, the macropixel 30 is indicated by a solid line frame or a broken line frame. The macropixels 30 in the solid line frames and the macropixels 30 in the broken line frames are alternately arranged in the first direction X and the second direction Y, and a gap of one pixel 10 is provided between the macropixels 30 adjacent to each other in the first direction X or the second direction Y. Note that the gap is not limited to one pixel, and is only required to be any gap of an odd number of pixels.

Control for dividing the plurality of pixels 10 of the pixel array section 11 into the plurality of macropixels 30 is performed according to a plurality of pixel control signals generated by the control signal generation section 19. The control signal generation section 19 is provided in, for example, the timing control section 15 in FIG. 1, and the pixel control signals generated by the control signal generation section 19 are input to the row drive section 12 and the column signal processing section 13.

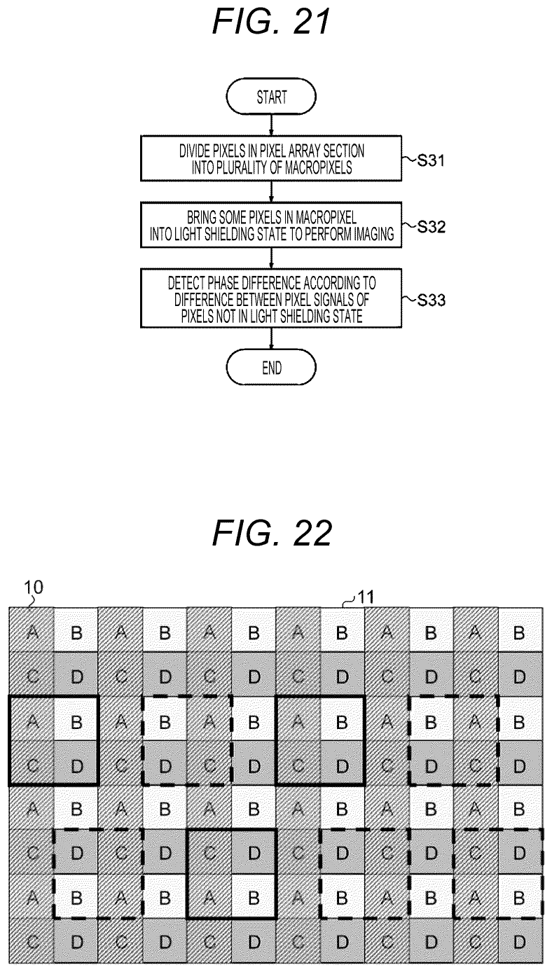

FIG. 21 is a flowchart illustrating processing operation of the photodetection device 3 according to the fourth embodiment. The photodetection device 3 according to the fourth embodiment performs the processing of the flowchart of FIG. 6 when starting imaging processing. First, on the basis of a plurality of pixel control signals, the plurality of pixels 10 of the pixel array section 11 is divided into the plurality of macropixels 30 (step S31).

Next, reading out pixel signals from some pixels 10 included in each of the plurality of macropixels 30 is stopped, whereby the some pixels 10 are brought into a pseudo light shielding state (step S32).

FIG. 22 is a diagram illustrating an example in which some pixels 10 in each macropixel 30 are brought into the pseudo light shielding state. It is illustrated that the gray pixels 10 in FIG. 22 are in the pseudo light shielding state. In the example in FIG. 22, a pixel column of A and C arranged in the second direction Y is brought into the pseudo light shielding state. This is an example, and a pixel column of B and D may be brought into the pseudo light shielding state.

Some pixel columns are brought into the light shielding state, whereby, for example, in one of two macropixels 30 adjacent to each other in the first direction X, two pixels 10 arranged vertically on the right side are brought into the light shielding state, and in the other, two pixels 10 arranged vertically on the left side is brought into the light shielding state.

As described above, by symmetrically arranging the pixels 10 that are in the light shielding state in the two adjacent pixels 10, it is possible to detect a phase difference according to a difference between pixel signals of the pixels 10 that are not in the light shielding state in these two pixels 10 (step S33). The detected phase difference can be used, for example, for auto focus (AF) control.

FIG. 22 illustrates an example in which the pixel column of A and C arranged in the second direction Y is brought into the pseudo light shielding state, but a pixel row of A and B, or C and D arranged in the first direction X may be brought into the pseudo light shielding state. In this case, in one of two macropixels 30 adjacent to each other in the second direction Y, two pixels 10 arranged horizontally on the upper side are brought into the light shielding state, and in the other, two pixels 10 arranged horizontally on the lower side is brought into the light shielding state, and the phase difference can be similarly detected.

As described above, in the fourth embodiment, the plurality of pixels 10 of the pixel array section 11 can be divided into the plurality of macropixels 30 according to the plurality of pixel control signals. Furthermore, some pixels 10 in each of the macropixels 30 are not read intentionally, whereby some pixels 10 in two macropixels 30 adjacent to each other in the first direction X or the second direction Y can be brought into the light shielding state, and the phase difference can be detected according to the pixel signals of the two adjacent macropixels 30 and utilized for auto focus.

### FIRST APPLICATION EXAMPLE

The photodetection device 3 according to the first to fourth embodiments described above can include, for example, a stacked chip in which first to third substrates 25 to 27 are stacked as illustrated in FIG. 4. Hereinafter, an example of a specific form of this type of stacked chip will be described. Note that a configuration of the photodetection device 3 of the rolling shutter type will be described below, but by adding the GS memory 21, it is also applicable to the photodetection devices 3 of the global shutter type according to the first to fourth embodiments. Furthermore, a specific configuration of an imaging device 1 of the column AD method will be described below, but it is also applicable to the imaging device 1 of the pixel parallel AD method.

### Configuration of Imaging Device 1

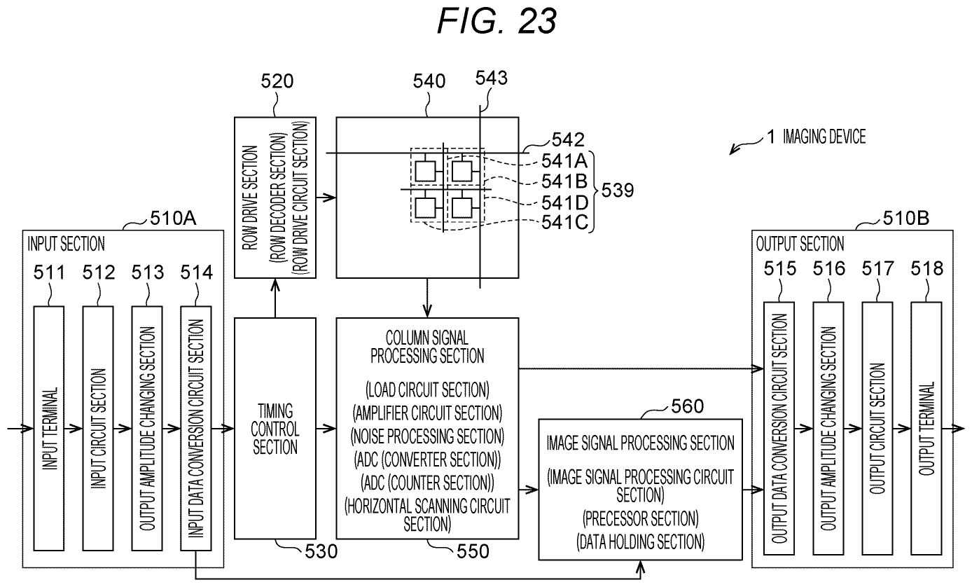

FIG. 23 is a block diagram illustrating an example of a functional configuration of the imaging device 1 according to a first application example of the present disclosure.

The imaging device 1 of FIG. 23 includes, for example, an input section 510A, a row drive section 520, a timing control section 530, a pixel array section 540, a column signal processing section 550, an image signal processing section 560, and an output section 510B.

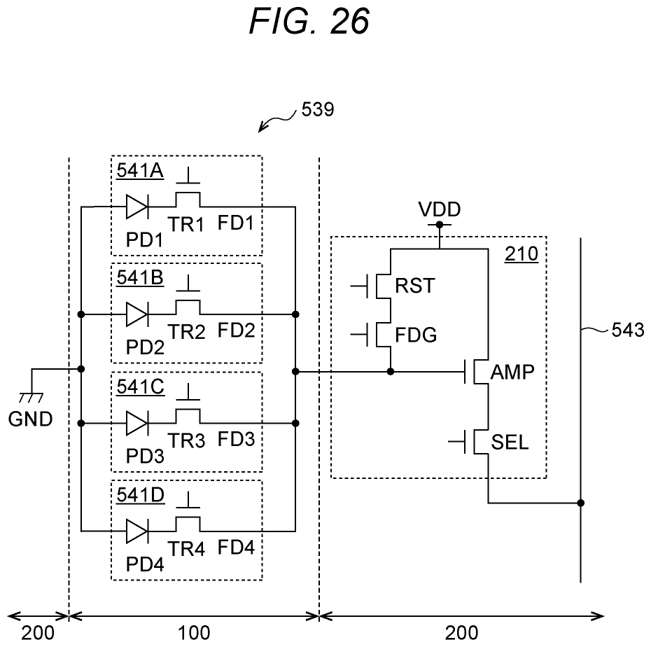

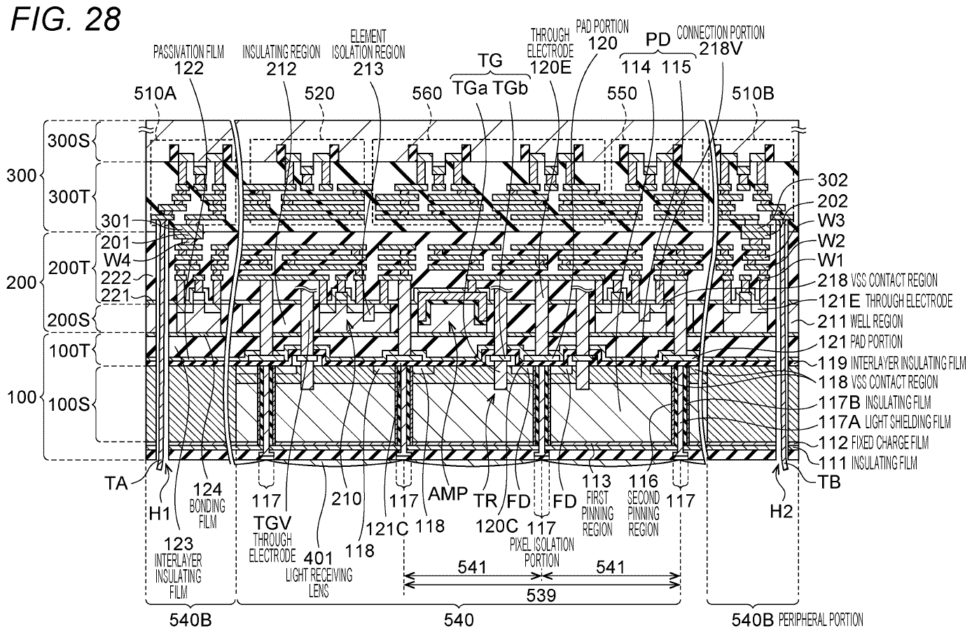

In the pixel array section 540, pixels 541 are repeatedly arranged in an array. More specifically, a pixel sharing unit 539 including a plurality of pixels is a unit of repetition, and is repeatedly arranged in an array in a row direction and a column direction. Note that, in the present specification, the row direction will also be referred to as an H direction, and the column direction perpendicular to the row direction will also be referred to as a V direction for convenience. In the example in FIG. 23, one pixel sharing unit 539 includes four pixels (pixels 541A, 541B, 541C, and 541D). Each of the pixels 541A, 541B, 541C, and 541D includes the photodiode PD (illustrated in FIG. 28 and the like described later). The pixel sharing unit 539 is a unit in which one pixel circuit (a pixel circuit 210 in FIG. 25 described later) is shared. In other words, one pixel circuit (the pixel circuit 210 described later) is included for every four pixels (pixels 541A, 541B, 541C, and 541D). The pixel circuit is operated in a time division manner, whereby pixel signals of the pixels 541A, 541B, 541C, and 541D are sequentially read. The pixels 541A, 541B, 541C, and 541D are arranged in, for example, two rows×two columns. In the pixel array section 540, a plurality of row drive signal lines 542 and a plurality of vertical signal lines (column readout lines) 543 are provided together with the pixels 541A, 541B, 541C, and 541D. The row drive signal lines 542 drive the pixels 541 included in each of a plurality of the pixel sharing units 539 arranged in the pixel array section 540 side by side in the row direction. In the pixel sharing unit 539, each of the pixels arranged side by side in the row direction is driven. As will be described in detail later with reference to FIG. 26, the pixel sharing unit 539 is provided with a plurality of transistors. In order to respectively drive the plurality of transistors, a plurality of row drive signal lines 542 is connected to one pixel sharing unit 539. The pixel sharing unit 539 is connected to one of the vertical signal lines (column readout lines) 543. The pixel signal is read from each of the pixels 541A, 541B, 541C, and 541D included in the pixel sharing unit 539 via the vertical signal line (column readout line) 543.

The row drive section 520 includes, for example, a row address control section that determines a position of a row for driving pixels, in other words, a row decoder section, and a row drive circuit section that generates a signal for driving the pixels 541A, 541B, 541C, and 541D.

The column signal processing section 550 includes, for example, a load circuit section that is connected to the vertical signal line 543 and forms a source follower circuit with the pixels 541A, 541B, 541C, and 541D (pixel sharing unit 539). The column signal processing section 550 may include an amplifier circuit section that amplifies a signal read from the pixel sharing unit 539 via the vertical signal line 543. The column signal processing section 550 may include a noise processing section. In the noise processing section, for example, a noise level of a system is removed from the signal read from the pixel sharing unit 539 as a result of photoelectric conversion.

The column signal processing section 550 includes, for example, an analog-to-digital converter (ADC). In the analog-to-digital converter, the signal read from the pixel sharing unit 539 or an analog signal subjected to the noise processing described above is converted into a digital signal. The ADC includes, for example, a comparator section and a counter section. The comparator section compares an analog signal to be converted with a reference signal to be compared. In the counter section, a time until a comparison result in the comparator section is inverted is measured. The column signal processing section 550 may include a horizontal scanning circuit section that performs control for scanning a column to be read.

The timing control section 530 supplies a signal for controlling timing to the row drive section 520 and the column signal processing section 550 on the basis of a reference clock signal and a timing control signal input to the device.

The image signal processing section 560 is a circuit that performs various types of signal processing on data obtained as a result of photoelectric conversion, in other words, data obtained as a result of imaging operation in the imaging device 1. The image signal processing section 560 includes, for example, an image signal processing circuit section and a data holding section. The image signal processing section 560 may include a processor section.

An example of the signal processing executed by the image signal processing section 560 is tone curve correction processing for providing a large number of gradations in a case where imaging data subjected to AD conversion is data obtained by imaging of a dark subject and reducing the number of gradations in a case where imaging data subjected to AD conversion is data obtained by imaging of a bright subject. In this case, it is desirable to store characteristic data regarding a tone curve in the data holding section of the image signal processing section 560 in advance to determine how the tone curve corrects gradation of imaging data.

The input section 510A is, for example, for inputting the above-described reference clock signal, timing control signal, characteristic data, and the like from the outside of the device to the imaging device 1. The timing control signal is, for example, a vertical synchronization signal, a horizontal synchronization signal, or the like. The characteristic data is, for example, to be stored in the data holding section of the image signal processing section 560. The input section 510A includes, for example, an input terminal 511, an input circuit section 512, an input amplitude changing section 513, an input data conversion circuit section 514, and a power supply section (not illustrated).

The input terminal 511 is an external terminal for receiving data as an input. The input circuit section 512 is for taking a signal input to the input terminal 511 into the imaging device 1. In the input amplitude changing section 513, an amplitude of the signal taken by the input circuit section 512 is changed to an amplitude that can be easily used inside the imaging device 1. In the input data conversion circuit section 514, arrangement of data strings of input data is changed. The input data conversion circuit section 514 includes, for example, a serial-to-parallel conversion circuit. In the serial-to-parallel conversion circuit, a serial signal received as input data is converted into a parallel signal. Note that, in the input section 510A, the input amplitude changing section 513 and the input data conversion circuit section 514 may be omitted. The power supply section supplies power set to various voltages required inside the imaging device 1 on the basis of power supplied from the outside to the imaging device 1.

When the imaging device 1 is connected to an external memory device, the input section 510A may be provided with a memory interface circuit that receives data from the external memory device. The external memory device is, for example, a flash memory, an SRAM, a DRAM, or the like.

The output section 510B outputs image data to the outside of the device. The image data is, for example, image data captured by the imaging device 1, image data subjected to signal processing by the image signal processing section 560, and the like. The output section 510B includes, for example, an output data conversion circuit section 515, an output amplitude changing section 516, an output circuit section 517, and an output terminal 518.

The output data conversion circuit section 515 includes, for example, a parallel-to-serial conversion circuit, and in the output data conversion circuit section 515, a parallel signal used inside the imaging device 1 is converted into a serial signal. The output amplitude changing section 516 changes the amplitude of a signal used inside the imaging device 1. The signal having the changed amplitude is easily used in an external device externally connected to the imaging device 1. The output circuit section 517 is a circuit that outputs data from the inside of the imaging device 1 to the outside of the device, and wiring outside the imaging device 1 connected to the output terminal 518 is driven by the output circuit section 517. At the output terminal 518, data is output from the imaging device 1 to the outside of the device. In the output section 510B, the output data conversion circuit section 515 and the output amplitude changing section 516 may be omitted.

When the imaging device 1 is connected to an external memory device, the output section 510B may be provided with a memory interface circuit that outputs data to the external memory device. The external memory device is, for example, a flash memory, an SRAM, a DRAM, or the like.

### Schematic Configuration of Imaging Device 1

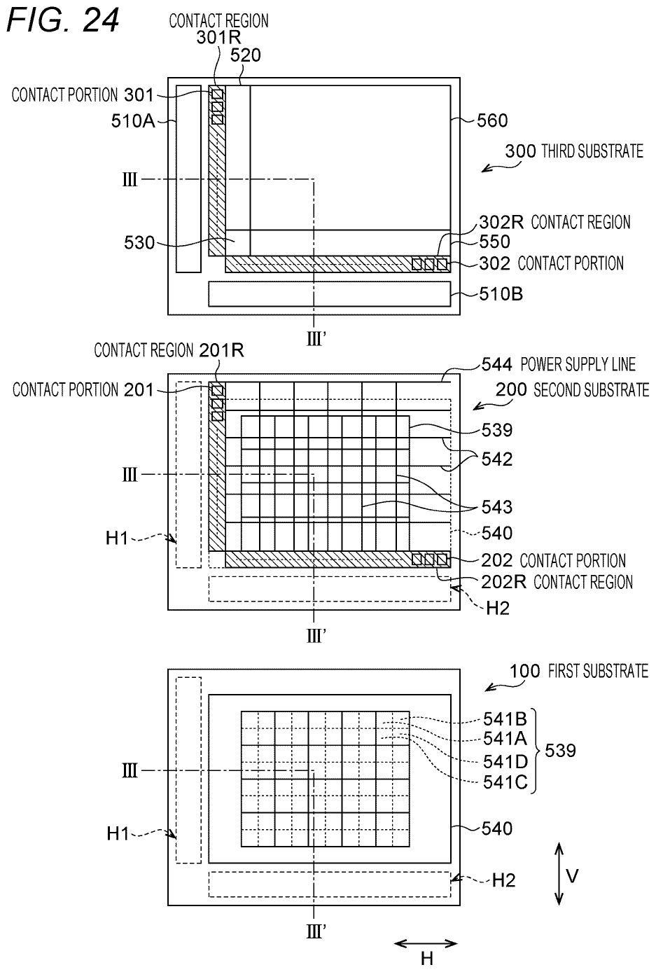

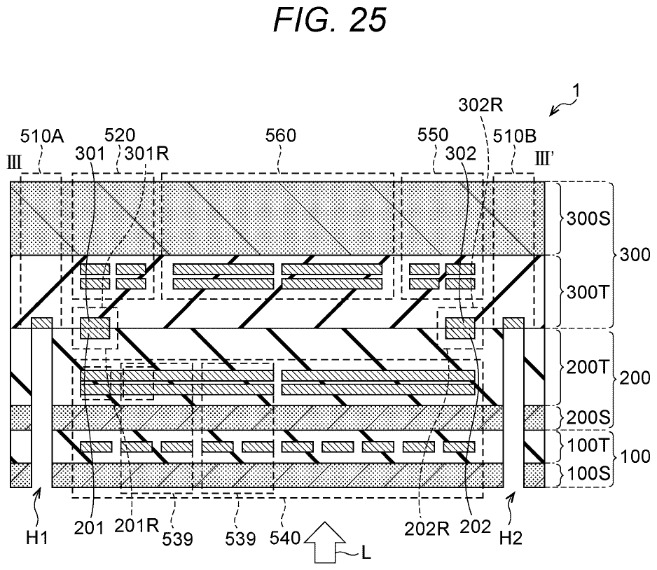

FIGS. 24 and 25 are diagrams illustrating an example of a schematic configuration of the imaging device 1. The imaging device 1 includes three substrates (first substrate 100, second substrate 200, and third substrate 300). FIG. 24 schematically illustrates planar configurations of the first substrate 100, the second substrate 200, and the third substrate 300, and FIG. 25 schematically illustrates a cross-sectional configuration of the first substrate 100, the second substrate 200, and the third substrate 300 stacked on each other. FIG. 25 corresponds to a cross-sectional configuration taken along line III-III′ illustrated in FIG. 24. The imaging device 1 is an imaging device having a three-dimensional structure formed by bonding three substrates (first substrate 100, second substrate 200, and third substrate 300). The first substrate 100 includes a semiconductor layer 100S and a wiring layer 100T. The second substrate 200 includes a semiconductor layer 200S and a wiring layer 200T. The third substrate 300 includes a semiconductor layer 300S and a wiring layer 300T. Here, a combination of wiring lines included in each of the first substrate 100, the second substrate 200, and the third substrate 300 and an interlayer insulating film around the wiring lines will be referred to as a wiring layer (100T, 200T, or 300T) provided in each of the substrates (the first substrate 100, the second substrate 200, and the third substrate 300) for convenience. The first substrate 100, the second substrate 200, and the third substrate 300 are stacked on each other in this order, and the semiconductor layer 100S, the wiring layer 100T, the semiconductor layer 200S, the wiring layer 200T, the wiring layer 300T, and the semiconductor layer 300S are arranged in this order along a stacking direction. Specific configurations of the first substrate 100, the second substrate 200, and the third substrate 300 will be described later. An arrow illustrated in FIG. 25 indicates an incident direction of light L on the imaging device 1. In the present specification, for convenience, in the following cross-sectional views, a light incident side in the imaging device 1 may be referred to as “lower”, “lower side”, and “lower direction”, and a side opposite to the light incident side may be referred to as “upper”, “upper side”, and “upper direction”. Furthermore, in the present specification, with respect to a substrate including a semiconductor layer and a wiring layer, a wiring layer's side may be referred to as a front surface, and a semiconductor layer's side may be referred to as a back surface, for convenience. Note that description of the specification is not limited to the above terms. The imaging device 1 is, for example, a back-illuminated imaging device in which light enters from the back surface side of the first substrate 100 including a photodiode.

Both the pixel array section 540 and the pixel sharing unit 539 included in the pixel array section 540 include both the first substrate 100 and the second substrate 200. The first substrate 100 is provided with the plurality of pixels 541A, 541B, 541C, and 541D included in the pixel sharing unit 539. Each of these pixels 541 includes a photodiode (the photodiode PD described later) and a transfer transistor (a transfer transistor TR described later). The second substrate 200 is provided with the pixel circuit (the pixel circuit 210 described later) included in the pixel sharing unit 539. The pixel circuit reads the pixel signal transferred from the photodiode of each of the pixels 541A, 541B, 541C, and 541D via the transfer transistor, or resets the photodiode. In addition to such a pixel circuit, the second substrate 200 includes the plurality of row drive signal lines 542 extending in the row direction and the plurality of vertical signal lines 543 extending in the column direction. The second substrate 200 further includes a power supply line 544 extending in the row direction. The third substrate 300 includes, for example, the input section 510A, the row drive section 520, the timing control section 530, the column signal processing section 550, the image signal processing section 560, and the output section 510B. The row drive section 520 is provided, for example, in a region partially overlapping the pixel array section 540 in the stacking direction (hereinafter simply referred to as a stacking direction) of the first substrate 100, the second substrate 200, and the third substrate 300. More specifically, the row drive section 520 is provided in a region overlapping the vicinity of an end portion of the pixel array section 540 in the H direction, in the stacking direction (FIG. 24). The column signal processing section 550 is provided, for example, in a region partially overlapping the pixel array section 540, in the stacking direction. More specifically, the column signal processing section 550 is provided in a region overlapping the vicinity of an end portion of the pixel array section 540 in the V direction, in the stacking direction (FIG. 24). Although not illustrated, the input section 510A and the output section 510B may be arranged in a portion other than the third substrate 300, and, for example, may be arranged on the second substrate 200. Alternatively, the input section 510A and the output section 510B may be provided on the back surface (light incident surface) side of the first substrate 100. Note that the pixel circuit provided in the second substrate 200 described above may be referred to as a pixel transistor circuit, a pixel transistor group, a pixel transistor, a pixel readout circuit, or a readout circuit as another name. In the present specification, the term “pixel circuit” is used.

The first substrate 100 and the second substrate 200 are electrically connected to each other by, for example, through electrodes (through electrodes 120E and 121E in FIG. 28 described later). The second substrate 200 and the third substrate 300 are electrically connected to each other via, for example, contact portions 201, 202, 301, and 302. The contact portions 201 and 202 are provided on the second substrate 200, and the contact portions 301 and 302 are provided on the third substrate 300. The contact portion 201 of the second substrate 200 is in contact with the contact portion 301 of the third substrate 300, and the contact portion 202 of the second substrate 200 is in contact with the contact portion 302 of the third substrate 300. The second substrate 200 includes a contact region 201R in which a plurality of the contact portions 201 is provided and a contact region 202R in which a plurality of the contact portions 202 is provided. The third substrate 300 includes a contact region 301R in which a plurality of the contact portions 301 is provided and a contact region 302R in which a plurality of the contact portions 302 is provided. The contact regions 201R and 301R are provided between the pixel array section 540 and the row drive section 520, in the stacking direction (FIG. 25). In other words, the contact regions 201R and 301R are provided, for example, in a region where the row drive section 520 (third substrate 300) and the pixel array section 540 (second substrate 200) overlap in the stacking direction or in a region in the vicinity thereof. The contact regions 201R and 301R are arranged, for example, at an end portion in the H direction in such a region (FIG. 24). In the third substrate 300, the contact region 301R is provided, for example, at a position overlapping a part of the row drive section 520, specifically, an end portion of the row drive section 520 in the H direction (FIGS. 24 and 25). The contact portions 201 and 301 connect, for example, the row drive section 520 provided in the third substrate 300 and the row drive lines 542 provided in the second substrate 200 to each other. For example, the contact portions 201 and 301 may connect the input section 510A provided in the third substrate 300, the power supply line 544, and a reference potential line (reference potential line VSS described later) to each other. The contact regions 202R and 302R are provided between the pixel array section 540 and the column signal processing section 550, in the stacking direction (FIG. 25). In other words, the contact regions 202R and 302R are provided, for example, in a region where the column signal processing section 550 (third substrate 300) and the pixel array section 540 (second substrate 200) overlap in the stacking direction or in a region in the vicinity thereof. The contact regions 202R and 302R are arranged, for example, at an end portion in the V direction in such a region (FIG. 24). In the third substrate 300, the contact region 301R is provided, for example, at a position overlapping a part of the column signal processing section 550, specifically, an end portion of the column signal processing section 550 in the V direction (FIGS. 24 and 25). The contact portions 202 and 302 are, for example, for connecting the pixel signal (the signal corresponding to an amount of charge generated as a result of photoelectric conversion in the photodiode) output from each of the plurality of pixel sharing units 539 included in the pixel array section 540 to the column signal processing section 550 provided in the third substrate 300. The pixel signal is transmitted from the second substrate 200 to the third substrate 300.

FIG. 25 is an example of a cross-sectional view of the imaging device 1 as described above. The first substrate 100, the second substrate 200, and the third substrate 300 are electrically connected to each other via the wiring layers 100T, 200T, and 300T. For example, the imaging device 1 includes an electrical connection portion that electrically connects the second substrate 200 and the third substrate 300 to each other. Specifically, the contact portions 201, 202, 301, and 302 include an electrode including a conductive material. The conductive material includes, for example, a metal material such as copper (Cu), aluminum (Al), or gold (Au). The contact regions 201R, 202R, 301R, and 302R electrically connect the second substrate and the third substrate by directly bonding wiring lines formed as electrodes, for example, and enable signal input and/or output between the second substrate 200 and the third substrate 300.

The electrical connection portion that electrically connects the second substrate 200 and the third substrate 300 to each other can be provided at a desired location. For example, as described as the contact regions 201R, 202R, 301R, and 302R in FIG. 25, the electrical connection portion may be provided in a region overlapping the pixel array section 540 in the stacking direction. Furthermore, the electrical connection portion may be provided in a region not overlapping the pixel array section 540 in the stacking direction. Specifically, the electrical connection portion may be provided in a region overlapping a peripheral portion arranged outside the pixel array section 540 in the stacking direction.

The first substrate 100 and the second substrate 200 are provided with, for example, connection holes H1 and H2. The connection holes H1 and H2 penetrate the first substrate 100 and the second substrate 200 (FIG. 25). The connection holes H1 and H2 are provided outside the pixel array section 540 (or a portion overlapping the pixel array section 540) (FIG. 24). For example, the connection hole H1 is arranged outside the pixel array section 540 in the H direction, and the connection hole H2 is arranged outside the pixel array section 540 in the V direction. For example, the connection hole H1 reaches the input section 510A provided in the third substrate 300, and the connection hole H2 reaches the output section 510B provided in the third substrate 300. The connection holes H1 and H2 may be hollow, and at least a part thereof may contain a conductive material. For example, there is a configuration in which a bonding wire is connected to an electrode formed as the input section 510A and/or the output section 510B. Alternatively, there is a configuration in which the electrode formed as the input section 510A and/or the output section 510B and the conductive material provided in the connection holes H1 and H2 are connected to each other. The conductive material provided in the connection holes H1 and H2 may be embedded in a part or all of the connection holes H1 and H2, and the conductive material may be formed on side walls of the connection holes H1 and H2.

Note that, FIG. 25 illustrates a structure in which the input section 510A and the output section 510B are provided in the third substrate 300, but the structure is not limited to this. For example, by sending a signal of the third substrate 300 to the second substrate 200 via the wiring layers 200T and 300T, it is also possible to provide the input section 510A and/or the output section 510B in the second substrate 200. Similarly, by sending a signal of the second substrate 200 to the first substrate 1000 via the wiring layers 100T and 200T, it is also possible to provide the input section 510A and/or the output section 510B in the first substrate 100.

FIG. 26 is an equivalent circuit diagram illustrating an example of the configuration of the pixel sharing unit 539. The pixel sharing unit 539 includes a plurality of pixels 541 (FIG. 26 illustrates four pixels 541 of the pixels 541A, 541B, 541C, and 541D), one pixel circuit 210 connected to the plurality of pixels 541, and the vertical signal line 5433 connected to the pixel circuit 210. The pixel circuit 210 includes, for example, four transistors, specifically, an amplification transistor AMP, a selection transistor SEL, a reset transistor RST, and an FD conversion gain switching transistor FD. As described above, the pixel sharing unit 539 sequentially outputs the pixel signals of the four pixels 541 (pixels 541A, 541B, 541C, and 541D) included in the pixel sharing unit 539 to the vertical signal line 543 by operating one pixel circuit 210 in a time division manner. One pixel circuit 210 is connected to the plurality of pixels 541, and a mode in which the pixel signals of the plurality of pixels 541 are output by one pixel circuit 210 in a time division manner will be referred to as “the plurality of pixels 541 shares one pixel circuit 210”.

The pixels 541A, 541B, 541C, and 541D include common components. Hereinafter, in order to distinguish the components of the pixels 541A, 541B, 541C, and 541D from each other, an identification number 1 is assigned to the end of the reference sign of the component of the pixel 541A, an identification number 2 is assigned to the end of the reference sign of the component of the pixel 541B, an identification number 3 is assigned to the end of the reference sign of the component of the pixel 541C, and an identification number 4 is assigned to the end of the reference sign of the component of the pixel 541D. In a case where it is not necessary to distinguish the components of the pixels 541A, 541B, 541C, and 541D from each other, the identification numbers at the ends of the reference signs of the components of the pixels 541A, 541B, 541C, and 541D are omitted.

The pixels 541A, 541B, 541C, and 541D each include, for example, the photodiode PD, the transfer transistor TR electrically connected to the photodiode PD, and the floating diffusion FD electrically connected to the transfer transistor TR. In the photodiode PD (PD1, PD2, PD3, or PD4), the cathode is electrically connected to the source of the transfer transistor TR, and the anode is electrically connected to the reference potential line (for example, ground). The photodiode PD performs photoelectric conversion on incident light to generate a charge corresponding to an amount of the light received. The transfer transistor TR (transfer transistor TR1, TR2, TR3, or TR4) is, for example, an n-type complementary metal oxide semiconductor (CMOS) transistor. In the transfer transistor TR, the drain is electrically connected to the floating diffusion FD, and the gate is electrically connected to a drive signal line. The drive signal line is a part of the plurality of row drive signal lines 542 (see FIG. 23) connected to one pixel sharing unit 539. The transfer transistor TR transfers the charge generated in the photodiode PD to the floating diffusion FD. The floating diffusion FD (floating diffusion FD1, FD2, FD3, or FD4) is an n-type diffusion layer region formed in a p-type semiconductor layer. The floating diffusion FD is a charge holding means for temporarily holding the charge transferred from the photodiode PD, and is a charge-to-voltage conversion means for generating a voltage corresponding to an amount of the charge.

Four floating diffusions FD (floating diffusions FD1, FD2, FD3, and FD4) included in one pixel sharing unit 539 are electrically connected to each other, and are electrically connected to the gate of the amplification transistor AMP and the source of the FD conversion gain switching transistor FDG. The drain of the FD conversion gain switching transistor FDG is connected to the source of the reset transistor RST, and the gate of the FD conversion gain switching transistor FDG is connected to a drive signal line. The drive signal line is a part of the plurality of row drive signal lines 542 connected to one pixel sharing unit 539. The drain of the reset transistor RST is connected to a power supply line VDD, and the gate of the reset transistor RST is connected to a drive signal line. The drive signal line is a part of the plurality of row drive signal lines 542 connected to one pixel sharing unit 539. The gate of the amplification transistor AMP is connected to the floating diffusion FD, the drain of the amplification transistor AMP is connected to the power supply line VDD, and the source of the amplification transistor AMP is connected to the drain of the selection transistor SEL. The source of the selection transistor SEL is connected to the vertical signal line 543, and the gate of the selection transistor SEL is connected to a drive signal line. The drive signal line is a part of the plurality of row drive signal lines 542 connected to one pixel sharing unit 539.

The transfer transistor TR transfers the charge of the photodiode PD to the floating diffusion FD when the transfer transistor TR is turned on. The gate (transfer gate TG) of the transfer transistor TR includes, for example, a so-called vertical electrode, and is provided to extend from the front surface of the semiconductor layer (the semiconductor layer 100S in FIG. 28 described later) to a depth reaching the PD as illustrated in FIG. 28 described later. The reset transistor RST resets a potential of the floating diffusion FD to a predetermined potential. When the reset transistor RST is turned on, the potential of the floating diffusion FD is reset to a potential of the power supply line VDD. The selection transistor SEL controls an output timing of the pixel signal from the pixel circuit 210. The amplification transistor AMP generates a signal of a voltage corresponding to a level of the charge held in the floating diffusion FD as the pixel signal. The amplification transistor AMP is connected to the vertical signal line 543 via the selection transistor SEL. The amplification transistor AMP constitutes a source follower together with a load circuit section (see FIG. 23) connected to the vertical signal line 543 in the column signal processing section 550. When the selection transistor SEL is turned on, the amplification transistor AMP outputs the voltage of the floating diffusions FD to the column signal processing section 550 via the vertical signal line 543. The reset transistor RST, the amplification transistor AMP, and the selection transistor SEL are, for example, n-type CMOS transistors.

The FD conversion gain switching transistor FDG is used to change gain of charge-to-voltage conversion in the floating diffusions FD. In general, the pixel signal is small at a time of imaging in a dark place. If capacitance (FD capacitance C) of the floating diffusion FD is large when charge-to-voltage conversion is performed on the basis of Q=CV, V obtained by conversion by the amplification transistor AMP into a voltage is small. On the other hand, the pixel signal is large in a bright place, so that the floating diffusion FD cannot receive the charge of the photodiode PD unless the FD capacitance C is large. Moreover, the FD capacitance C needs to be large so that V obtained by conversion by the amplification transistor AMP into a voltage is not too large (in other words, is small). On the basis of these, when the FD conversion gain switching transistor FDG is turned on, gate capacitance of the FD conversion gain switching transistor FDG increases, and the entire FD capacitance C increases. When the FD conversion gain switching transistor FDG is turned off, on the other hand, the entire FD capacitance C decreases. The FD capacitance C can thus be made variable and conversion efficiency can be switched, by turning on and off of the FD conversion gain switching transistor FDG. The FD conversion gain switching transistor FDG is, for example, an n-type CMOS transistor.

Note that a configuration is also possible in which the FD conversion gain switching transistor FDG is not provided. At this time, for example, the pixel circuit 210 includes three transistors of, for example, the amplification transistor AMP, the selection transistor SEL, and the reset transistor RST. The pixel circuit 210 includes, for example, at least one of the pixel transistors such as the amplification transistor AMP, the selection transistor SEL, the reset transistor RST, and the FD conversion gain switching transistor FDG.

The selection transistor SEL may be provided between the power supply line VDD and the amplification transistor AMP. In this case, the drain of the reset transistor RST is electrically connected to the power supply line VDD and the drain of the selection transistor SEL. The source of the selection transistor SEL is electrically connected to the drain of the amplification transistor AMP, and the gate of the selection transistor SEL is electrically connected to the row drive signal line 542 (see FIG. 23). The source of the amplification transistor AMP (an output terminal of the pixel circuit 210) is electrically connected to the vertical signal line 543, and the gate of the amplification transistor AMP is electrically connected to the source of the reset transistor RST. Note that, although not illustrated, the number of pixels 541 that share one pixel circuit 210 may be other than four. For example, two or eight pixels 541 may share one pixel circuit 210.

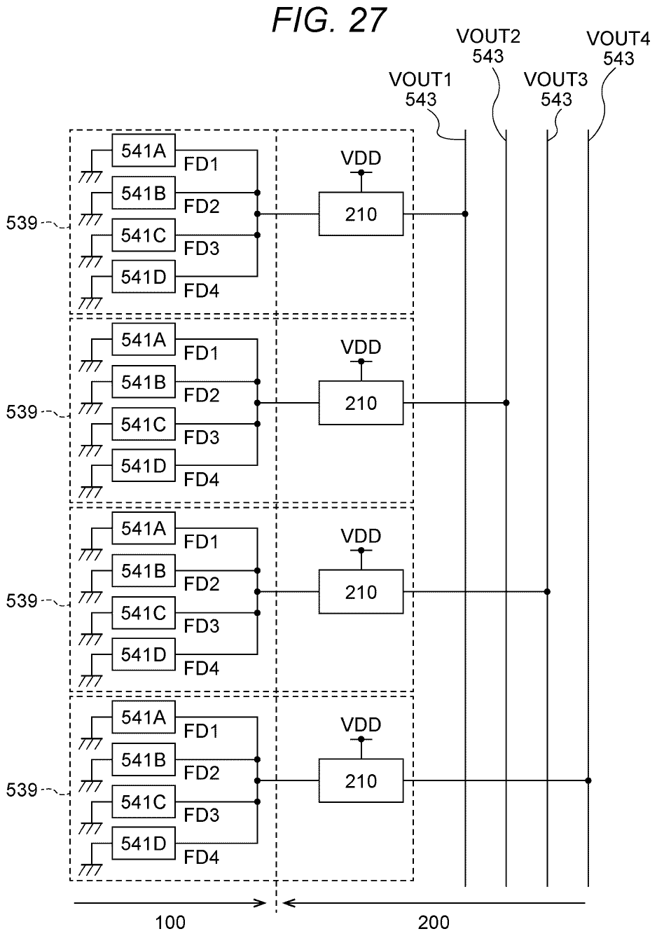

FIG. 27 illustrates an example of a connection mode between the plurality of pixel sharing units 539 and the vertical signal lines 543. For example, four pixel sharing units 539 arranged in the column direction are divided into four groups, and the vertical signal lines 543 are respectively connected to the four groups. Although FIG. 27 illustrates an example in which four groups each include one pixel sharing unit 539 in order to simplify description, the four groups may each include a plurality of pixel sharing units 539. As described above, in the imaging apparatus 1, the plurality of pixel sharing units 539 arranged in the column direction may be divided into groups including one or a plurality of pixel sharing units 539. For example, the vertical signal lines 543 and column signal processing circuits 550 are connected to respective groups, and the pixel signals can be simultaneously read from the respective groups. Alternatively, in the imaging device 1, one vertical signal line 543 may be connected to the plurality of pixel sharing units 539 arranged in the column direction. At this time, the pixel signals are sequentially read, in a time division manner, from the plurality of pixel sharing units 539 connected to one vertical signal line 543.

### Specific Configuration of Imaging Device 1

FIG. 28 illustrates an example of a cross-sectional configuration in a direction perpendicular to main surfaces of the first substrate 100, the second substrate 100, and the third substrate 300 of the imaging device 1. FIG. 28 schematically illustrates a positional relationship of the components for easy understanding, and may be different from an actual cross section. In the imaging device 1, the first substrate 100, the second substrate 200, and the third substrate 300 are stacked in this order. The imaging device 1 further includes a light receiving lens 401 on the back surface side (light incident surface side) of the first substrate 100. A color filter layer (not illustrated) may be provided between the light receiving lens 401 and the first substrate 100. The light receiving lens 401 is provided in each of the pixels 541A, 541B, 541C, and 541D, for example. The imaging device 1 is, for example, a back-illuminated imaging device. The imaging device 1 includes the pixel array section 540 arranged in a central portion and a peripheral portion 540B arranged outside the pixel array section 540.

The first substrate 100 includes an insulating film 111, a fixed charge film 112, the semiconductor layer 100S, and the wiring layer 100T in this order from the light receiving lens 401 side. The semiconductor layer 100S includes, for example, a silicon substrate. The semiconductor layer 100S includes, for example, a p-well layer 115 in a part of the front surface (surface on the wiring layer 100T side) and in the vicinity thereof, and an n-type semiconductor region 114 in another region (region deeper than the p-well layer 115). For example, the n-type semiconductor region 114 and the p-well layer 115 constitute a photodiode PD of a pn junction type. The p-well layer 115 is a p-type semiconductor region.

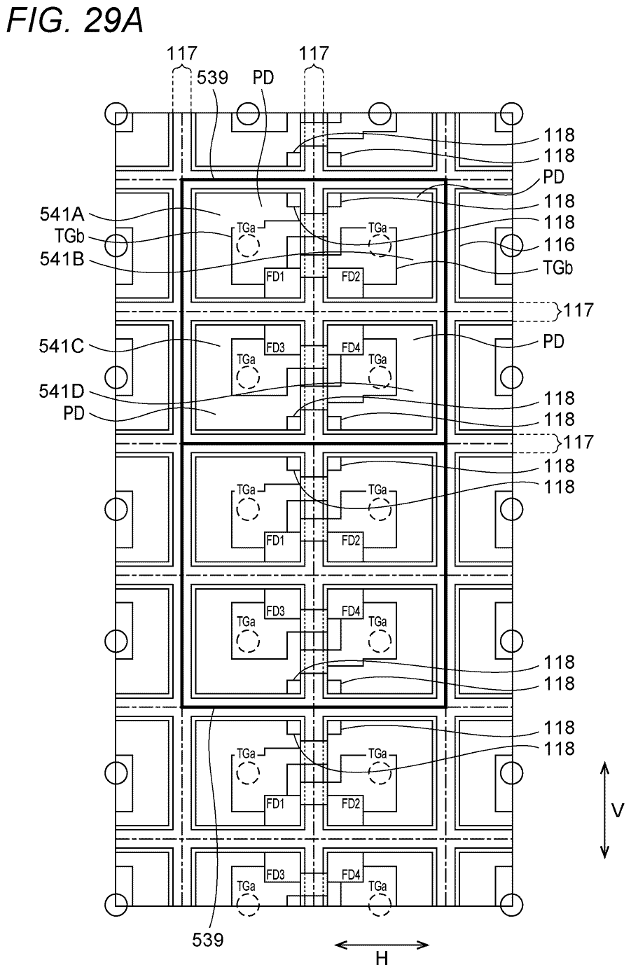

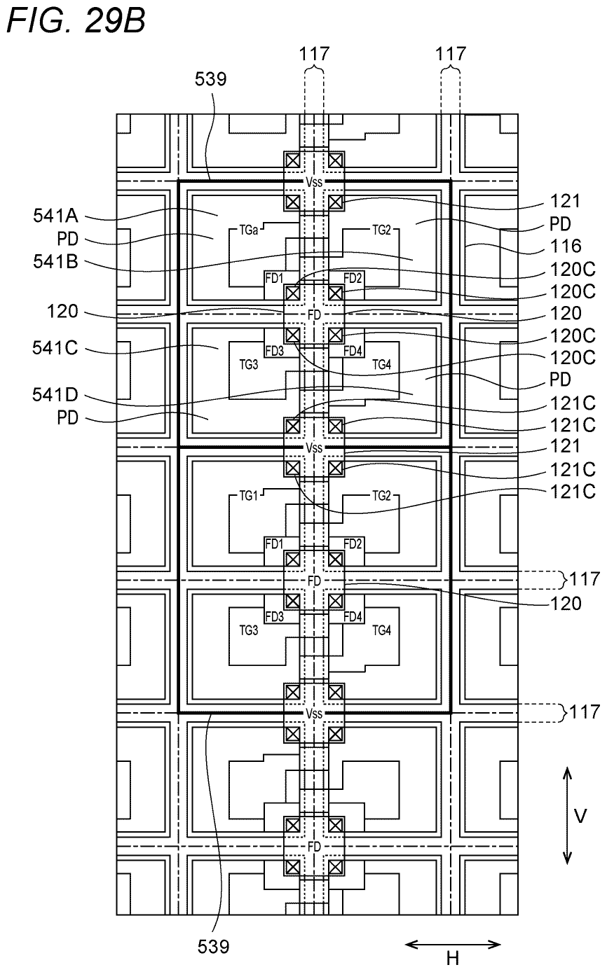

FIG. 29A illustrates an example of the planar configuration of the first substrate 100. FIG. 29A mainly illustrates a planar configuration of a pixel isolation portion 117, the photodiode PD, the floating diffusion FD, a VSS contact region 118, and the transfer transistor TR of the first substrate 100. A configuration of the first substrate 100 will be described with reference to FIG. 29A together with FIG. 28.

The floating diffusion FD and the VSS contact region 118 are provided in the vicinity of the front surface of the semiconductor layer 100S. The floating diffusion FD includes an n-type semiconductor region provided in the p-well layer 115. The floating diffusions FD (floating diffusion FD1, FD2, FD3, and FD4) of the respective pixels 541A, 541B, 541C, and 541D are provided, for example, close to each other in a central portion of the pixel sharing unit 539 (FIG. 29A). Although details will be described later, the four floating diffusions (floating diffusions FD1, FD2, FD3, and FD4) included in the sharing unit 539 are electrically connected to each other in the first substrate 100 (more specifically, in the wiring layer 100T) via an electrical connection means (pad portion 120 described later). Moreover, the floating diffusions FD are connected from the first substrate 100 to the second substrate 200 (more specifically, from the wiring layer 100T to the wiring layer 200T) via an electrical means (through electrode 120E described later). In the second substrate 200 (more specifically, inside the wiring layer 200T), the floating diffusions FD are electrically connected to the gate of the amplification transistor AMP and the source of the FD conversion gain switching transistor FDG by the electrical means.

The VSS contact region 118 is a region electrically connected to the reference potential line VSS, and arranged away from the floating diffusion FD. For example, in the pixels 541A, 541B, 541C, and 541D, the floating diffusion FD is arranged at one end in the V direction of each pixel, and the VSS contact region 118 is arranged at the other end (FIG. 29A). The VSS contact region 118 includes, for example, a p-type semiconductor region. The VSS contact region 118 is connected to, for example, a ground potential or a fixed potential. As a result, a reference potential is supplied to the semiconductor layer 100S.

The transfer transistor TR is provided in the first substrate 100 together with the photodiode PD, the floating diffusion FD, and the VSS contact region 118. The photodiode PD, the floating diffusion FD, the VSS contact region 118, and the transfer transistor TR are provided in each of the pixels 541A, 541B, 541C, and 541D. The transfer transistor TR is provided on the front surface side (an opposite side from the light incident surface side, the second substrate 200 side) of the semiconductor layer 100S. The transfer transistor TR includes the transfer gate TG. The transfer gate TG includes, for example, a horizontal portion TGb facing the front surface of the semiconductor layer 100S and a vertical portion TGa provided in the semiconductor layer 100S. The vertical portion TGa extends in a thickness direction of the semiconductor layer 100S. One end of the vertical portion TGa is in contact with the horizontal portion TGb, and the other end is provided in the n-type semiconductor region 114. The transfer transistor TR is formed as such a vertical transistor, whereby transfer failure of the pixel signal hardly occurs, and readout efficiency of the pixel signal can be improved.

The horizontal portion TGb of the transfer gate TG extends from a position facing the vertical portion TGa toward, for example, the central portion of the pixel sharing unit 539 in the H direction (FIG. 29A). As a result, a position in the H direction of a through electrode (through electrode TGV described later) reaching the transfer gate TG can be brought close to positions in the H direction of the through electrodes (through electrodes 120E and 121E described later) connected to the floating diffusion FD and the VSS contact region 118. For example, the plurality of pixel sharing units 539 provided in the first substrate 100 has the same configuration as each other (FIG. 29A).

The semiconductor layer 100S is provided with the pixel isolation portion 117 that isolates the pixels 541A, 541B, 541C, and 541D from each other. The pixel isolation portion 117 is formed to extend in a normal direction of the semiconductor layer 100S (a direction perpendicular to the front surface of the semiconductor layer 100S). The pixel isolation portion 117 is provided so as to partition the pixels 541A, 541B, 541C, and 541D from each other, and has, for example, a grid-like planar shape (FIG. 29A and FIG. 29B). For example, the pixel isolation portion 117 electrically and optically isolates the pixels 541A, 541B, 541C, and 541D from each other. The pixel isolation portion 117 includes, for example, a light shielding film 117A and an insulating film 117B. For example, tungsten (W) or the like is used for the light shielding film 117A. The insulating film 117B is provided between the light shielding film 117A and the p-well layer 115 or the n-type semiconductor region 114. The insulating film 117B includes, for example, silicon oxide (SiO). The pixel isolation portion 117 has, for example, a full trench isolation (FTI) structure and penetrates the semiconductor layer 100S. Although not illustrated, the pixel isolation portion 117 is not limited to the FTI structure penetrating the semiconductor layer 100S. For example, a deep trench isolation (DTI) structure that does not penetrate the semiconductor layer 100S may be employed. The pixel isolation portion 117 extends in the normal direction of the semiconductor layer 100S and is formed in a region of a part of the semiconductor layer 100S.

In the semiconductor layer 100S, for example, a first pinning region 113 and a second pinning region 116 are provided. The first pinning region 113 is provided in the vicinity of the back surface of the semiconductor layer 100S, and is arranged between the n-type semiconductor region 114 and the fixed charge film 112. The second pinning region 116 is provided on a side surface of the pixel isolation portion 117, specifically, between the pixel isolation portion 117 and the p-well layer 115 or the n-type semiconductor region 114. The first pinning region 113 and the second pinning region 116 include, for example, a p-type semiconductor region.

The fixed charge film 112 having a negative fixed charge is provided between the semiconductor layer 100S and the insulating film 111. The first pinning region 113 of a hole accumulation layer is formed at an interface on a light receiving surface (back surface) side of the semiconductor layer 100S by an electric field induced by the fixed charge film 112. As a result, generation of a dark current due to an interface state on the light receiving surface side of the semiconductor layer 100S is suppressed. The fixed charge film 112 includes, for example, an insulating film having a negative fixed charge. Examples of a material of the insulating film having a negative fixed charge include hafnium oxide, zircon oxide, aluminum oxide, titanium oxide, and tantalum oxide.

The light shielding film 117A is provided between the fixed charge film 112 and the insulating film 111. This light shielding film 117A may be provided continuously with the light shielding film 117A constituting the pixel isolation portion 117. The light shielding film 117A between the fixed charge film 112 and the insulating film 111 is selectively provided, for example, in the semiconductor layer 100S at a position facing the pixel isolation portion 117. The insulating film 111 is provided to cover the light shielding film 117A. The insulating film 111 includes, for example, silicon oxide.

The wiring layer 100T provided between the semiconductor layer 100S and the second substrate 200 includes an interlayer insulating film 119, pad portions 120 and 121, a passivation film 122, an interlayer insulating film 123, and a bonding film 124 in this order from the semiconductor layer 100S side. The horizontal portion TGb of the transfer gate TG is provided, for example, in the wiring layer 100T. The interlayer insulating film 119 is provided over the entire front surface of the semiconductor layer 100S and in contact with the semiconductor layer 100S. The interlayer insulating film 119 includes, for example, a silicon oxide film. Note that a configuration of the wiring layer 100T is not limited to the above, and is only required to be a configuration including wiring lines and an insulating film.

FIG. 29B illustrates a configuration of the pad portions 120 and 121 together with the planar configuration illustrated in FIG. 29A. The pad portions 120 and 121 are provided in selective regions on the interlayer insulating film 119. The pad portion 120 is for connecting the floating diffusions FD (floating diffusions FD1, FD2, FD3, and FD4) of the pixels 541A, 541B, 541C, and 541D to each other. For example, the pad portion 120 is arranged for each pixel sharing unit 539 at the central portion of the pixel sharing unit 539 in plan view (FIG. 29B). The pad portion 120 is provided so as to straddle the pixel isolation portion 117, and is arranged to overlap at least a part of each of the floating diffusions FD1, FD2, FD3, and FD4 (FIG. 28 and FIG. 29B). Specifically, the pad portion 120 is formed in a region overlapping at least a part of each of the plurality of floating diffusions FD (floating diffusions FD1, FD2, FD3, and FD4) sharing the pixel circuit 210 and at least a part of the pixel isolation portion 117 formed between the plurality of photodiodes PD (photodiodes PD1, PD2, PD3, and PD4) sharing the pixel circuit 210, in a direction perpendicular to the front surface of the semiconductor layer 100S. The interlayer insulating film 119 is provided with a connection via 120C for electrically connecting the pad portion 120 and the floating diffusions FD1, FD2, FD3, and FD4 to each other. The connection via 120C is provided in each of the pixels 541A, 541B, 541C, and 541D. For example, a part of the pad portion 120 is embedded in the connection via 120C, whereby the pad portion 120 and the floating diffusions FD1, FD2, FD3, and FD4 are electrically connected to each other.

The pad portion 121 is for connecting a plurality of the VSS contact regions 118 to each other. For example, the VSS contact regions 118 provided in the pixels 541C and 541D of one of the pixel sharing units 539 adjacent to each other in the V direction and the VSS contact regions 118 provided in the pixels 541A and 541B of the other of the pixel sharing units 539 are electrically connected to each other by the pad portion 121. The pad portion 121 is provided so as to straddle the pixel isolation portion 117, for example, and is arranged to overlap at least a part of each of these four VSS contact regions 118. Specifically, the pad portion 121 is formed in a region overlapping at least a part of each of the plurality of VSS contact regions 118 and at least a part of the pixel isolation portion 117 formed between the plurality of VSS contacts 118 in a direction perpendicular to the front surface of the semiconductor layer 100S. The interlayer insulating film 119 is provided with a connection via 121C for electrically connecting the pad portion 121 and the VSS contact region 118 to each other. The connection via 121C is provided in each of the pixels 541A, 541B, 541C, and 541D. For example, a part of the pad portion 121 is embedded in the connection via 121C, whereby the pad portion 121 and the VSS contact regions 118 are electrically connected to each other. For example, the pad portion 120 and the pad portion 121 of each of the plurality of pixel sharing units 539 arranged in the V direction are arranged at substantially the same position in the H direction (FIG. 29B).

By providing the pad portion 120, it is possible to reduce wiring lines for connecting each floating diffusion FD to the pixel circuit 210 (for example, a gate electrode of the amplification transistor AMP) in the entire chip. Similarly, by providing the pad portion 121, it is possible to reduce wiring lines for supplying a potential to each VSS contact region 118 in the entire chip. As a result, it is possible to reduce an area of the entire chip, suppress electrical interference between wiring lines in the miniaturized pixels, and/or reduce a cost by reducing the number of components.

The pad portions 120 and 121 can be provided in the first substrate 100 and the second substrate 200 at desired positions. Specifically, the pad portions 120 and 121 can be provided in either the wiring layer 100T or an insulating region 212 of the semiconductor layer 200S. In a case where the pad portions 120 and 121 are provided in the wiring layer 100T, the pad portions 120 and 121 may be brought into direct contact with the semiconductor layer 100S. Specifically, the pad portions 120 and 121 may be directly connected to at least a part of each of the floating diffusion FD and/or the VSS contact region 118. Furthermore, the connection vias 120C and 121C may be provided from the floating diffusion FD and/or the VSS contact region 118 that are to be connected to the pad portions 120 and 121, and the pad portions 120 and 121 may be provided at desired positions of the insulating region 2112 of the wiring layer 100T and the semiconductor layer 200S.

In particular, in a case where the pad portions 120 and 121 are provided in the wiring layer 100T, it is possible to reduce wiring lines connected to the floating diffusion FD and/or the VSS contact region 118 in the insulating region 212 of the semiconductor layer 200S. As a result, it is possible to reduce an area of the insulating region 212 for forming a through wiring line for connecting the floating diffusion FD to the pixel circuit 210 in the second substrate 200 in which the pixel circuit 210 is to be formed. Thus, it is possible to secure a large area of the second substrate 200 in which the pixel circuit 210 is to be formed. By securing the area of the pixel circuit 210, it is possible to form a large pixel transistor and contribute to image quality improvement through noise reduction or the like.

In particular, in a case where the FTI structure is used for the pixel isolation portion 117, it is preferable to provide the floating diffusion FD and/or the VSS contact region 118 in each pixel 541, so that it is possible to greatly reduce wiring lines connecting the first substrate 100 and the second substrate 200 to each other by using the configuration of the pad portions 120 and 121.

Furthermore, as illustrated in FIG. 29B, for example, the pad portion 120 to which the plurality of floating diffusions FD is connected and the pad portion 121 to which the plurality of VSS contacts 118 is connected are alternately arranged linearly in the V direction. Furthermore, the pad portions 120 and 121 are formed at positions surrounded by the plurality of photodiodes PD, the plurality of transfer gates TG, and the plurality of floating diffusions FD. As a result, in the first substrate 100 in which a plurality of elements is to be formed, elements other than the floating diffusion FD and the VSS contact region 118 can be freely arranged, and efficiency of a layout of the entire chip can be improved. Furthermore, symmetry in the layout of the elements formed in each pixel sharing unit 539 can be secured, and variation in characteristics of each pixel 541 can be suppressed.

The pad portions 120 and 121 include, for example, polysilicon (Poly Si), more specifically, doped polysilicon doped with impurities. The pad portions 120 and 121 preferably include a conductive material having high heat resistance, such as polysilicon, tungsten (W), titanium (Ti), or titanium nitride (TiN). As a result, the pixel circuit 210 can be formed after the semiconductor layer 200S of the second substrate 200 is bonded to the first substrate 100. A reason for this will be described hereinafter. Note that, in the following description, a method for forming the pixel circuit 210 after bonding the first substrate 100 and the semiconductor layer 200S of the second substrate 200 to each other will be referred to as a first manufacturing method.

Here, it is also conceivable to bond, after forming the pixel circuit 210 on the second substrate 200, the second substrate 200 to the first substrate 100 (hereinafter referred to as a second manufacturing method). In the second manufacturing method, an electrode for electrical connection is formed in advance on each of a surface of the first substrate 100 (surface of the wiring layer 100T) and a surface of the second substrate 200 (surface of the wiring layer 200T). When the first substrate 100 and the second substrate 200 are bonded to each other, the electrodes for electrical connection respectively formed on the surfaces of the first substrate 100 and the second substrate 200 come into contact with each other. As a result, an electrical connection is formed between wiring lines included in the first substrate 100 and wiring lines included in the second substrate 200. Thus, by employing the configuration of the imaging device 1 using the second manufacturing method, it is possible to perform manufacturing using an appropriate process according to the configuration of each of the first substrate 100 and the second substrate 200, for example, and it is possible to manufacture a high-quality and high-performance imaging device.

In such a second manufacturing method, when the first substrate 100 and the second substrate 200 are bonded to each other, an error in alignment may occur due to a manufacturing apparatus for bonding. Furthermore, the first substrate 100 and the second substrate 200 have a size of, for example, about several tens of centimeters in diameter, and when the first substrate 100 and the second substrate 200 are bonded to each other, there is a possibility that expansion and contraction of the substrates occur in microscopic regions of the respective parts of the first substrate 100 and the second substrate 200. The expansion and contraction of the substrates is caused by a slight shift in timing of contact between the substrates. Due to such expansion and contraction of the first substrate 100 and the second substrate 200, an error may occur in positions of the electrodes for electrical connection formed on the surface of the first substrate 100 and the surface of the second substrate 200. In the second manufacturing method, even if such an error occurs, it is preferable to take measures so that the electrodes of the first substrate 100 and the second substrate 200 come into contact with each other. Specifically, at least one, preferably both, of the electrodes of the first substrate 100 and the second substrate 200 is increased in consideration of the above error. For this reason, when the second manufacturing method is used, for example, a size (size in the substrate planar direction) of the electrode formed on the surface of the first substrate 100 or the second substrate 200 is larger than a size of an internal electrode extending from the inside of the first substrate 100 or the second substrate 200 to the surface in the thickness direction.

On the other hand, by including a heat-resistant conductive material in the pad portions 120 and 121, it is possible to use the above-described first manufacturing method. In the first manufacturing method, after the first substrate 100 including the photodiode PD, the transfer transistor TR, and the like is formed, the first substrate 100 and the second substrate 200 (semiconductor layer 2000S) are bonded to each other. At this time, the second substrate 200 is in a state in which a pattern of an active element, a wiring layer, and the like constituting the pixel circuit 210 are not formed. Since the second substrate 200 is in a state before the pattern is formed, even if an error occurs in a bonding position of the first substrate 100 and the second substrate 200 when they are bonded to each other, an error does not occur in alignment between the pattern of the first substrate 100 and the pattern of the second substrate 200 due to the bonding error. This is because the pattern of the second substrate 200 is formed after the first substrate 100 and the second substrate 200 are bonded to each other. Note that, when a pattern is formed on the second substrate, for example, in an exposure apparatus for pattern formation, the pattern is formed while the pattern formed on the first substrate is set as an alignment target. For the above reason, the error in the bonding position between the first substrate 100 and the second substrate 200 does not cause a problem in manufacturing the imaging device 1 in the first manufacturing method. For a similar reason, an error caused by expansion and contraction of the substrate occurring in the second manufacturing method does not cause a problem in manufacturing the imaging device 1 in the first manufacturing method.

In the first manufacturing method, after the first substrate 100 and the second substrate 200 (semiconductor layer 200S) are bonded to each other in this manner, an active element is formed on the second substrate 200. Thereafter, the through electrodes 120E and 121E and the through electrodes TGV (FIG. 28) are formed. In the formation of the through electrodes 120E, 121E, and TGV, for example, a pattern of the through electrode is formed from above the second substrate 200 by using reduced projection exposure by an exposure apparatus. Since the reduced exposure projection is used, even if an error occurs in alignment between the second substrate 200 and the exposure apparatus, a magnitude of the error is only a fraction (inverse of a reduced exposure projection magnification) of a magnitude of the error of the second manufacturing method described above, in the second substrate 200. Thus, by employing the configuration of the imaging device 1 using the first manufacturing method, it is easy to align elements respectively formed on the first substrate 100 and the second substrate 200, and it is possible to manufacture a high-quality and high-performance imaging device.

The imaging device 1 manufactured by using such a first manufacturing method has features different from those of the imaging device manufactured by the second manufacturing method. Specifically, in the imaging device 1 manufactured by the first manufacturing method, for example, the through electrodes 120E, 121E, and TGV have substantially constant thicknesses (sizes in the substrate planar direction) from the second substrate 200 to the first substrate 100. Alternatively, when the through electrodes 120E, 121E, and TGV have a tapered shape, they have a tapered shape with a constant inclination. In the imaging device 1 including such through electrodes 120E, 121E, and TGV, the pixel 541 is easily miniaturized.

Here, when the imaging device 1 is manufactured by the first manufacturing method, since the active element is formed on the second substrate 200 after the first substrate 100 and the second substrate 200 (semiconductor layer 200S) are bonded to each other, the first substrate 100 is also affected by heating treatment necessary in forming the active element. For this reason, as described above, it is preferable to use a conductive material having high heat resistance for the pad portions 120 and 121 provided on the first substrate 100. For example, the pad portions 120 and 121 preferably include a material having a higher melting point (that is, higher heat resistance) than at least a part of a wiring material included in the wiring layer 200T of the second substrate 200. For example, a conductive material having high heat resistance such as doped polysilicon, tungsten, titanium, or titanium nitride is used for the pad portions 120 and 121. As a result, the imaging device 1 can be manufactured by use of the above-described first manufacturing method.

The passivation film 122 is provided over the entire front surface of the semiconductor layer 100S so as to cover the pad portions 120 and 121, for example (FIG. 28). The passivation film 122 includes, for example, a silicon nitride (SiN) film. The interlayer insulating film 123 covers the pad portions 120 and 121 with the passivation film 122 interposed therebetween. The interlayer insulating film 123 is provided, for example, over the entire front surface of the semiconductor layer 100S. The interlayer insulating film 123 includes, for example, a silicon oxide (SiO) film. The bonding film 124 is provided on a bonding surface between the first substrate 100 (specifically, the wiring layer 100T) and the second substrate 200. That is, the bonding film 124 is in contact with the second substrate 200. The bonding film 124 is provided over the entire main surface of the first substrate 100. The bonding film 124 includes, for example, a silicon nitride film.

The light receiving lens 401 faces the semiconductor layer 100S with the fixed charge film 112 and the insulating film 111 interposed therebetween, for example (FIG. 28). The light receiving lens 401 is provided, for example, at a position facing the photodiode PD of each of the pixels 541A, 541B, 541C, and 541D.

The second substrate 200 includes the semiconductor layer 200S and the wiring layer 200T in this order from the first substrate 100 side. The semiconductor layer 200S includes a silicon substrate. In the semiconductor layer 200S, a well region 211 is provided over the thickness direction. The well region 211 is, for example, a p-type semiconductor region. The second substrate 200 is provided with the pixel circuit 210 arranged for each pixel sharing unit 539. The pixel circuit 210 is provided, for example, on the front surface side (wiring layer 200T side) of the semiconductor layer 200S. In the imaging device 1, the second substrate 200 is bonded to the first substrate 100 such that the back surface side (semiconductor layer 200S side) of the second substrate 200 faces the front surface side (wiring layer 100T side) of the first substrate 100. That is, the second substrate 200 is bonded to the first substrate 100 in a face-to-back manner.

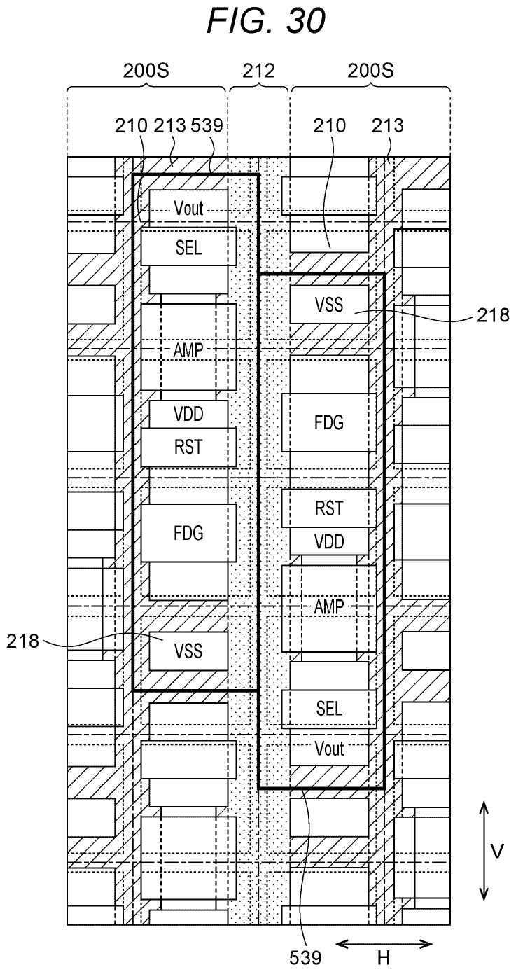

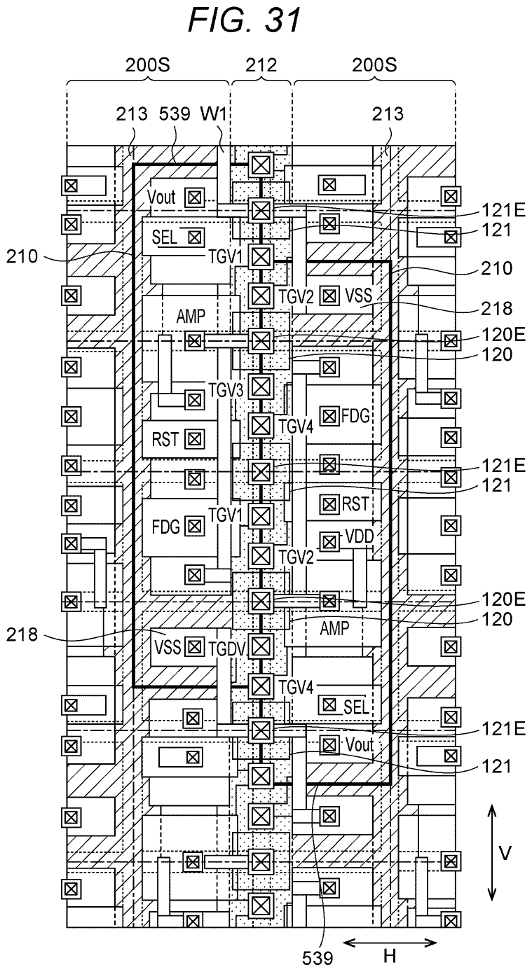

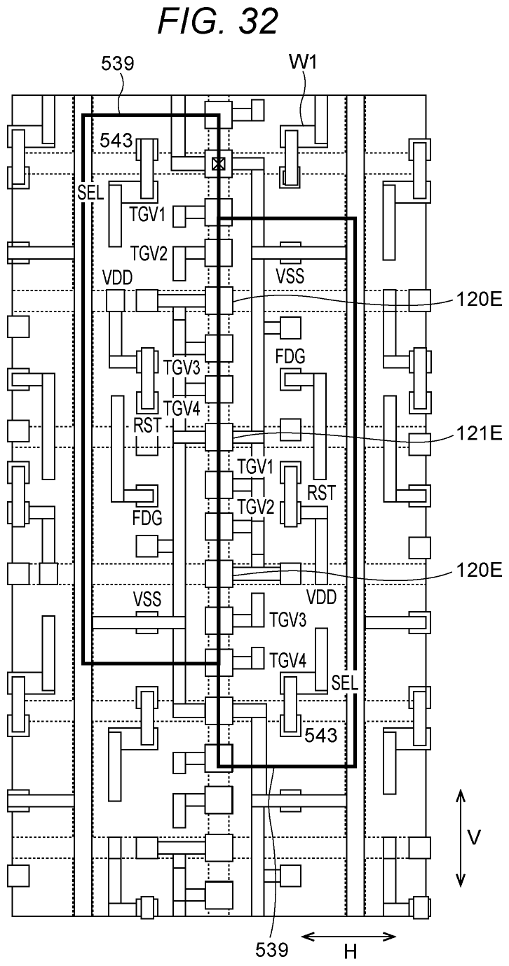

FIGS. 30 to 34 schematically illustrate an example of the planar configuration of the second substrate 200. FIG. 30 illustrates a configuration of the pixel circuit 210 provided in the vicinity of the front surface of the semiconductor layer 200S. FIG. 31 schematically illustrates a configuration of each part of the wiring layer 200T (specifically, a first wiring layer W1 described later), the semiconductor layer 200S connected to the wiring layer 200T, and the first substrate 100. FIGS. 32 to 34 illustrate an example of a planar configuration of the wiring layer 200T. The configuration of the second substrate 200 will be described hereinafter with reference to FIGS. 30 to 34 together with FIG. 28. In FIGS. 30 and 31, an outer shape of the photodiode PD (a boundary between the pixel isolation portion 117 and the photodiode PD) is indicated by a broken line, and a boundary between the semiconductor layer 200S and an element isolation region 213 or an insulating region 214 in a portion overlapping a gate electrode of each transistor constituting the pixel circuit 210 is indicated by a dotted line. In a portion overlapping the gate electrode of the amplification transistor AMP, a boundary between the semiconductor layer 200S and the element isolation region 213 and a boundary between the element isolation region 213 and an insulating region 213 are provided on one side in a channel width direction.

The second substrate 200 is provided with the insulating region 212 that divides the semiconductor layer 200S and the element isolation region 213 provided in a part of the semiconductor layer 200S in the thickness direction (FIG. 28). For example, in the insulating region 212 provided between two pixel circuits 210 adjacent to each other in the H direction, the through electrodes 120E and 121E and the through electrodes TGV (through electrodes TGV1, TGV2, TGV3, and TGV4) of two pixel sharing units 539 connected to the two pixel circuits 210 are arranged (FIG. 31).

The insulating region 212 has a thickness substantially the same as a thickness of the semiconductor layer 200S (FIG. 28). The semiconductor layer 200S is divided by the insulating region 212. The through electrodes 120E and 121E and the through electrodes TGV are arranged in the insulating region 212. The insulating region 212 includes, for example, silicon oxide.

The through electrodes 120E and 121E are provided to penetrate the insulating region 212 in the thickness direction. The upper ends of the through electrodes 120E and 121E are connected to wiring lines (first wiring W1, second wiring W2, third wiring W3, and fourth wiring W4 described later) of the wiring layer 200T. The through electrodes 120E and 121E are provided to penetrate the insulating region 212, the bonding film 124, the interlayer insulating film 123, and the passivation film 122, and the lower ends thereof are connected to the pad portions 120 and 121 (FIG. 28). The through electrode 120E is for electrically connecting the pad portion 120 and the pixel circuit 210 to each other. That is, the floating diffusion FD of the first substrate 100 is electrically connected to the pixel circuit 210 of the second substrate 200 by the through electrode 120E. The through electrode 121E is for electrically connecting the pad portion 121 and the reference potential line VSS of the wiring layer 200T to each other. That is, the VSS contact region 118 of the first substrate 100 is electrically connected to the reference potential line VSS of the second substrate 200 by the through electrode 121E.

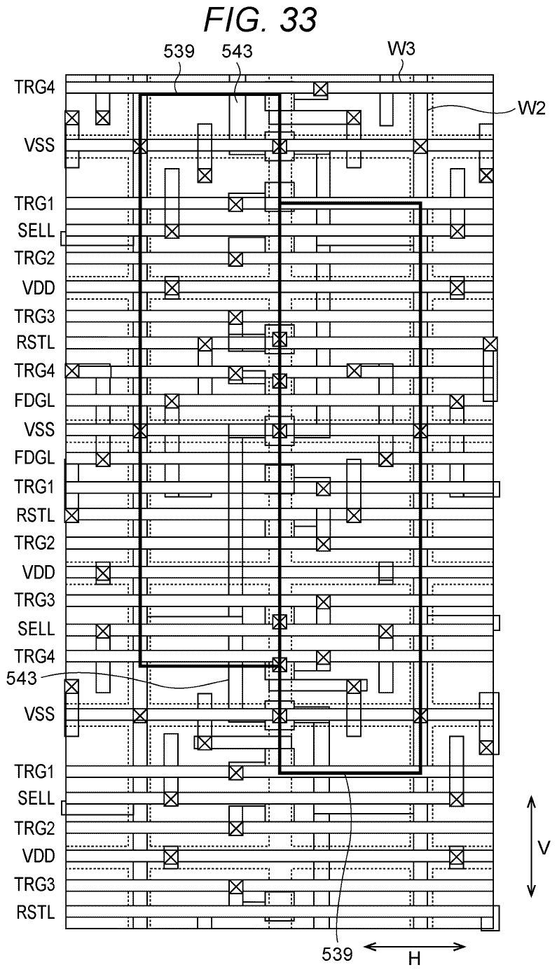

The through electrode TGV is provided to penetrate the insulating region 212 in the thickness direction. The upper end of the through electrode TGV is connected to the wiring lines of the wiring 200T. The through electrode TGV is provided to penetrate the insulating region 212, the bonding film 124, the interlayer insulating film 123, the passivation film 122, and the interlayer insulating film 119, and the lower end thereof is connected to the transfer gate TG (FIG. 28). Such a through electrode TGV is for electrically connecting the transfer gate TG (transfer gate TG1, TG2, TG3, or TG4) of each of the pixels 541A, 541B, 541C, and 541D and a wiring line (a part of the row drive signal lines 542, specifically, a wiring line TRG1, TRG2, TRG3, or TRG4 in FIG. 33 described later) of the wiring layer 200T to each other. That is, the transfer gate TG of the first substrate 100 is electrically connected to wiring lines TRG of the second substrate 200 by the through electrode TGV, and a drive signal is sent to each of the transfer transistors TR (transfer transistors TR1, TR2, TR3, and TR4).

The insulating region 212 is a region for providing the through electrodes 120E and 121E and the through electrodes TGV for electrically connecting the first substrate 100 and the second substrate 200 to each other, the through electrodes being insulated from the semiconductor layer 200S. For example, in the insulating region 212 provided between two pixel circuits 210 (sharing unit 539) adjacent to each other in the H direction, the through electrodes 120E and 121E and the through electrodes TGV (through electrodes TGV1, TGV2, TGV3, and TGV4) connected to the two pixel circuits 210 are arranged. The insulating region 212 is provided, for example, to extend in the V direction (FIG. 30 and FIG. 31). Here, by devising of arrangement of the horizontal portion TGb of the transfer gate TG, the through electrode TGV is arranged such that a position of the through electrode TGV in the H direction is closer to positions of the through electrodes 120E and 121E in the H direction as compared with a position of the vertical portion TGa (FIG. 29A, FIG. 31). For example, the through electrode TGV is arranged at substantially the same position as the through electrodes 120E and 120E in the H direction. As a result, the through electrodes 120E and 121E and the through electrodes TGV can be collectively provided in the insulating region 212 extending in the V direction. As another arrangement example, it is also conceivable to provide the horizontal portion TGb only in a region overlapping the vertical portion TGa. In this case, the through electrode TGV is formed substantially immediately above the vertical portion TGa, and for example, the through electrode TGV is arranged substantially at the central portion in the H direction and the V direction of each pixel 541. At this time, the position of the through electrode TGV in the H direction greatly deviates from the positions of the through electrodes 120E and 121E in the H direction. For example, the insulating region 212 is provided around the through electrode TGV and the through electrodes 120E and 121E in order to electrically insulate the through electrodes from the semiconductor layer 200S close to them. In a case where the position of the through electrode TGV in the H direction and the positions of the through electrodes 120E and 121E in the H direction are greatly separated from each other, it is necessary to provide the insulating region 212 independently around each of the through electrodes 120E, 121E, and TGV. As a result, the semiconductor layer 200S is finely divided. In comparison, a layout in which the through electrodes 120E and 121E and the through electrodes TGV are collectively arranged in the insulating region 212 extending in the V direction can increase a size of the semiconductor layer 200S in the H direction. Thus, it is possible to secure a large area of a semiconductor element formation region in the semiconductor layer 200S. As a result, for example, it is possible to increase a size of the amplification transistor AMP, and suppress noise.

As described with reference to FIG. 26, the pixel sharing unit 539 has a structure in which the floating diffusions FD provided in the respective plurality of pixels 541 are electrically connected to each other, and the plurality of pixels 541 shares one pixel circuit 210. Then, the floating diffusions FD are electrically connected to each other by the pad portion 120 provided on the first substrate 100 (FIG. 28 and FIG. 29B). An electrical connection portion (pad portion 120) provided on the first substrate 100 and the pixel circuit 210 provided on the second substrate 200 are electrically connected to each other via one through electrode 120E. As another structural example, it is also conceivable to provide an electrical connection portion between the floating diffusions FD on the second substrate 200. In this case, the pixel sharing unit 539 is provided with four through electrodes connected to the floating diffusions FD1, FD2, FD3, and FD4, respectively. Thus, in the second substrate 200, the number of through electrodes penetrating the semiconductor layer 200S increases, and the insulating region 212 that insulates the periphery of these through electrodes becomes large. In comparison, in a structure in which the pad portion 120 is provided on the first substrate 100 (FIG. 28 and FIG. 29B), the number of through electrodes can be reduced, and the insulating region 212 can be made small. Thus, it is possible to secure a large area of the semiconductor element formation region in the semiconductor layer 200S. As a result, for example, it is possible to increase the size of the amplification transistor AMP, and suppress the noise.

The element isolation region 213 is provided on the front surface side of the semiconductor layer 200S. The element isolation region 213 has a shallow trench isolation (STI) structure. In the element isolation region 213, the semiconductor layer 200S is dug in the thickness direction (direction perpendicular to the main surface of the second substrate 200), and an insulating film is embedded in the dug portion. The insulating film includes, for example, silicon oxide. The element isolation region 213 isolates the plurality of transistors constituting the pixel circuit 210 from each other in accordance with a layout of the pixel circuit 210. The semiconductor layer 200S (specifically, the well region 211) extends below the element isolation region 213 (deep portion of the semiconductor layer 200S).

Here, with reference to FIGS. 29A, 29B, and 30, a description will be given of a difference between an outer shape (outer shape in the substrate planar direction) of the pixel sharing unit 539 on the first substrate 100 and an outer shape of the pixel sharing unit 539 on the second substrate 200.

In the imaging device 1, the pixel sharing unit 539 is provided over both the first substrate 100 and the second substrate 200. For example, the outer shape of the pixel sharing unit 539 provided in the first substrate 100 is different from the outer shape of the pixel sharing unit 539 provided in the second substrate 200.

In FIGS. 29A and 29B, an outline of each of the pixels 541A, 541B, 541C, and 541D is indicated by a one-dot chain line, and the outer shape of the pixel sharing unit 539 is indicated by a thick line. For example, the pixel sharing unit 539 of the first substrate 100 includes two pixels 541 (pixels 541A and 541B) arranged adjacent to each other in the H direction, and two pixels 541 (pixels 541C and 541D) arranged adjacent to the pixels 541A and 541B in the V direction. That is, the pixel sharing unit 539 of the first substrate 100 includes four pixels 541 of two rows×two columns adjacent to each other, and the pixel sharing unit 539 of the first substrate 100 has a substantially square outer shape. In the pixel array section 540, such pixel sharing units 539 are arranged adjacent to each other at a two-pixel pitch (a pitch corresponding to two pixels 541) in the H direction and a two-pixel pitch (a pitch corresponding to two pixels 541) in the V direction.

In FIGS. 30 and 31, the outline of each of the pixels 541A, 541B, 541C, and 541D is indicated by a one-dot chain line, and the outer shape of the pixel sharing unit 539 is indicated by a thick line. For example, the outer shape of the pixel sharing unit 539 of the second substrate 200 is smaller than the pixel sharing unit 539 of the first substrate 100 in the H direction and larger than the pixel sharing unit 539 of the first substrate 100 in the V direction. For example, the pixel sharing unit 539 of the second substrate 200 is formed in a size (region) corresponding to one pixel in the H direction, and is formed in a size corresponding to four pixels in the V direction. That is, the pixel sharing unit 539 of the second substrate 200 is formed in a size corresponding to the pixels adjacent to each other arranged in one row×four columns, and the pixel sharing unit 539 of the second substrate 200 has a substantially rectangular outer shape.

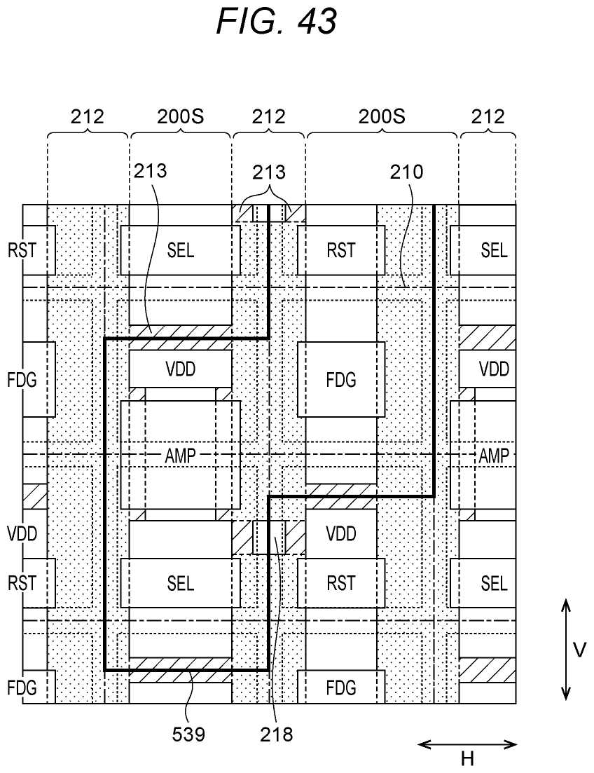

For example, in each pixel circuit 210, the selection transistor SEL, the amplification transistor AMP, the reset transistor RST, and the FD conversion gain switching transistor FDG are arranged side by side in this order in the V direction (FIG. 30). By providing an outer shape of each pixel circuit 210 in a substantially rectangular shape as described above, it is possible to arrange four transistors (selection transistor SEL, amplification transistor AMP, reset transistor RST, and FD conversion gain switching transistor FDG) side by side in one direction (V direction in FIG. 30). As a result, the drain of the amplification transistor AMP and the drain of the reset transistor RST can be shared by one diffusion region (diffusion region connected to the power supply line VDD). For example, a formation region for each pixel circuit 210 can be provided in a substantially square shape (see FIG. 43 described later). In this case, two transistors are arranged along one direction, and it is difficult to share the drain of the amplification transistor AMP and the drain of the reset transistor RST in one diffusion region. Thus, by providing the formation region for the pixel circuit 210 in a substantially rectangular shape, the four transistors can be easily arranged close to each other, and the formation region for the pixel circuit 210 can be reduced. That is, the pixels can be miniaturized. Furthermore, when it is unnecessary to reduce the formation region for the pixel circuit 210, a formation region for the amplification transistor AMP can be enlarged to suppress noise.

For example, in the vicinity of the front surface of the semiconductor layer 200S, a VSS contact region 218 connected to the reference potential line VSS is provided in addition to the selection transistor SEL, the amplification transistor AMP, the reset transistor RST, and the FD conversion gain switching transistor FDG. The VSS contact region 218 includes, for example, a p-type semiconductor region. The VSS contact region 218 is electrically connected to the VSS contact region 118 of the first substrate 100 (semiconductor layer 100S) via the wiring lines of the wiring layer 200T and the through electrode 121E. The VSS contact region 218 is provided, for example, at a position adjacent to the source of the FD conversion gain switching transistor FDG with the element isolation region 213 interposed therebetween (FIG. 30).

Next, with reference to FIGS. 29B and 30, a description will be given of a positional relationship between the pixel sharing unit 539 provided in the first substrate 100 and the pixel sharing unit 539 provided in the second substrate 200. For example, one pixel sharing unit 539 (for example, the upper side of FIG. 29B) of two pixel sharing units 539 arranged in the V direction of the first substrate 100 is connected to one pixel sharing unit 539 (for example, the left side of FIG. 30) of two pixel sharing units 539 arranged in the H direction of the second substrate 200. For example, the other pixel sharing unit 539 (for example, the lower side of FIG. 29B) of the two pixel sharing units 539 arranged in the V direction of the first substrate 100 is connected to the other pixel sharing unit 539 (for example, the right side of FIG. 30) of the two pixel sharing units 539 arranged in the H direction of the second substrate 200.

For example, in the two pixel sharing units 539 arranged in the H direction of the second substrate 200, an internal layout (arrangement of transistors and the like) of one pixel sharing unit 539 is substantially equal to a layout obtained by inversion of an internal layout of the other pixel sharing unit 539 in the V direction and the H direction. Hereinafter, effects obtained by this layout will be described.

In the two pixel sharing units 539 arranged in the V direction of the first substrate 100, each pad portion 120 is arranged at the central portion of the outer shape of the pixel sharing unit 539, that is, at the central portion in the V direction and the H direction of the pixel sharing unit 539 (FIG. 29B). On the other hand, since the pixel sharing unit 539 of the second substrate 200 has a substantially rectangular outer shape long in the V direction as described above, for example, the amplification transistor AMP connected to the pad portion 120 is arranged at a position shifted upward in the figure from the center of the pixel sharing unit 539 in the V direction. For example, when the internal layouts of the two pixel sharing units 539 arranged in the H direction of the second substrate 200 are the same as each other, a distance between the amplification transistor AMP of one pixel sharing unit 539 and the pad portion 120 (for example, the pad portion 120 of the pixel sharing unit 539 on the upper side of FIG. 29) is relatively short. However, a distance between the amplification transistor AMP of the other pixel sharing unit 539 and the pad portion 120 (for example, the pad portion 120 of the pixel sharing unit 539 on the lower side of FIG. 29) is long. For this reason, an area of wiring lines required for connection between the amplification transistor AMP and the pad portion 120 increases, and a wiring layout of the pixel sharing unit 539 may be complicated. This may affect miniaturization of the imaging device 1.

On the other hand, by inverting the internal layouts of the two pixel sharing units 539 arranged in the H direction of the second substrate 200 at least in the V direction, it is possible to shorten the distance between the amplification transistor AMP and the pad portion 120 of both of the two pixel sharing units 539. Thus, it is easy to miniaturize the imaging device 1 as compared with a configuration in which the internal layouts of the two pixel sharing units 539 arranged in the H direction of the second substrate 200 are the same as each other. Note that a planar layout of each of the plurality of pixel sharing units 539 of the second substrate 200 is bilaterally symmetrical in a range illustrated in FIG. 30, but is bilaterally asymmetrical when including a layout of the first wiring layer W1 described later in FIG. 31.

Furthermore, it is preferable that the internal layouts of the two pixel sharing units 539 arranged in the H direction of the second substrate 200 are also inverted to each other in the H direction. A reason for this will be described hereinafter. As illustrated in FIG. 31, each of the two pixel sharing units 539 arranged in the H direction of the second substrate 200 is connected to the pad portions 120 and 121 of the first substrate 100. For example, the pad portions 120 and 121 are arranged at the central portion in the H direction of the two pixel sharing units 539 arranged in the H direction (between the two pixel sharing units 539 arranged in the H direction) of the second substrate 200. Thus, it is possible to reduce the distance between each of the plurality of pixel sharing units 539 of the second substrate 200 and the pad portions 120 and 121 by inverting the internal layouts of the two pixel sharing units 539 arranged in the H direction of the second substrate 200 to each other also in the H direction. That is, it is easier to miniaturize the imaging device 1.

Furthermore, a position of an outline of the pixel sharing unit 539 of the second substrate 200 may not be aligned with a position of any outline of the pixel sharing unit 539 of the first substrate 100. For example, in one pixel sharing unit 539 (for example, the left side of FIG. 31) of the two pixel sharing units 539 arranged in the H direction of the second substrate 200, one outline (for example, the upper side of FIG. 31) in the V direction is arranged outside one outline in the V direction of the pixel sharing unit 539 (for example, the upper side of FIG. 29B) of the corresponding first substrate 100. Furthermore, in the other pixel sharing unit 539 (for example, the right side of FIG. 31) of the two pixel sharing units 539 arranged in the H direction of the second substrate 200, the other outline (for example, the lower side of FIG. 31) in the V direction is arranged outside the other outline in the V direction of the pixel sharing unit 539 (for example, the lower side of FIG. 29B) of the corresponding first substrate 100. As described above, by arranging the pixel sharing unit 539 of the second substrate 200 and the pixel sharing unit 539 of the first substrate 100 mutually, it is possible to shorten the distance between the amplification transistor AMP and the pad portion 120. Thus, it is easy to miniaturize the imaging device 1.

Furthermore, the positions of the outlines of the plurality of pixel sharing units 539 of the second substrate 200 may not be mutually aligned. For example, the two pixel sharing units 539 arranged in the H direction of the second substrate 200 are arranged such that the positions of the outlines in the V direction are shifted from each other. As a result, the distance between the amplification transistor AMP and the pad portion 120 can be shortened. Thus, it is easy to miniaturize the imaging device 1.

Repetitive arrangement of the pixel sharing units 539 in the pixel array section 540 will be described with reference to FIGS. 29B and 31. The pixel sharing unit 539 of the first substrate 100 has a size of two pixels 541 in the H direction and a size of two pixels 541 in the V direction (FIG. 29B). For example, in the pixel array section 540 of the first substrate 100, the pixel sharing units 539 each having a size corresponding to the four pixels 541 are repeatedly arranged adjacent to each other at a two-pixel pitch (a pitch corresponding to two pixels 541) in the H direction and at a two-pixel pitch (a pitch corresponding to two pixels 541) in the V direction. Alternatively, the pixel array section 540 of the first substrate 100 may be provided with a pair of pixel sharing units 539 in which two pixel sharing units 539 are arranged adjacent to each other in the V direction. In the pixel array section 540 of the first substrate 100, for example, the pair of pixel sharing units 539 is repeatedly arranged adjacent to each other at a two-pixel pitch (a pitch corresponding to two pixels 541) in the H direction and at a 4-pixel pitch (a pitch corresponding to four pixels 541) in the V direction. The pixel sharing unit 539 of the second substrate 200 has a size of one pixel 541 in the H direction and a size of four pixels 541 in the V direction (FIG. 31). For example, the pixel array section 540 of the second substrate 200 is provided with a pair of pixel sharing units 539 including two pixel sharing units 539 each having a size corresponding to the four pixels 541. The pixel sharing units 539 are arranged adjacent to each other in the H direction and are arranged to be shifted from each other in the V direction. In the pixel array section 540 of the second substrate 200, for example, the pair of pixel sharing units 539 is repeatedly arranged adjacent to each other without a gap at a two-pixel pitch (a pitch corresponding to two pixels 541) in the H direction and at a 4-pixel pitch (a pitch corresponding to four pixels 541) in the V direction. Such repetitive arrangement of the pixel sharing units 539 enables the pixel sharing units 539 to be arranged without any gap. Thus, it is easy to miniaturize the imaging device 1.

The amplification transistor AMP preferably has, for example, a three-dimensional structure such as a Fin type (FIG. 28). As a result, it is possible to increase a size of an effective gate width, and suppress noise. The selection transistor SEL, the reset transistor RST, and the FD conversion gain switching transistor FDG have, for example, a planar structure. The amplification transistor AMP may have a planar structure. Alternatively, the selection transistor SEL, the reset transistor RST, or the FD conversion gain switching transistor FDG may have a three-dimensional structure.

The wiring layer 200T includes, for example, a passivation film 221, an interlayer insulating film 222, and a plurality of wiring lines (first wiring layer W1, second wiring layer W2, third wiring layer W3, and fourth wiring layer W4). The passivation film 221 is, for example, in contact with the front surface of the semiconductor layer 200S and covers the entire front surface of the semiconductor layer 200S. The passivation film 221 covers the gate electrodes of the selection transistor SEL, the amplification transistor AMP, the reset transistor RST, and the FD conversion gain switching transistor FDG. The interlayer insulating film 222 is provided between the passivation film 221 and the third substrate 300. The plurality of wiring lines (first wiring layer W1, second wiring layer W2, third wiring layer W3, and fourth wiring layer W4) is separated from each other by the interlayer insulating film 222. The interlayer insulating film 222 includes, for example, silicon oxide.

In the wiring layer 200T, for example, the first wiring layer W1, the second wiring layer W2, the third wiring layer W3, the fourth wiring layer W4, and the contact portions 201 and 202 are provided in this order from the semiconductor layer 200S side, and these layers are insulated from each other by the interlayer insulating film 222. The interlayer insulating film 222 is provided with a plurality of connection portions that connect the first wiring layer W1, the second wiring layer W2, the third wiring layer W3 or the fourth wiring layer W4 and a lower layer thereof to each other. Each connection portion is a portion in which a conductive material is embedded in a connection hole provided in the interlayer insulating film 222. For example, the interlayer insulating film 222 is provided with a connection portion 218V that connects the first wiring layer W1 and the VSS contact region 218 of the semiconductor layer 200S to each other. For example, a hole diameter of such a connection portion connecting the elements of the second substrate 200 to each other is different from hole diameters of the through electrodes 120E and 121E and the through electrodes TGV. Specifically, the hole diameter of the connection hole connecting the elements of the second substrate 200 to each other is preferably smaller than the hole diameters of the through electrodes 120E and 121E and the through electrodes TGV. A reason for this will be described hereinafter. A depth of the connection portion (the connection portion 218V or the like) provided in the wiring layer 200T is smaller than depths of the through electrodes 120E and 121E and the through electrodes TGV. For this reason, in the connection portion, the conductive material can be more easily embedded in the connection hole as compared with the through electrodes 120E and 121E and the through electrodes TGV. By making the hole diameter of the connection portion smaller than the hole diameters of the through electrodes 120E and 121E and the through electrodes TGV, it is easy to miniaturize the imaging device 1.

For example, the first wiring layer W1 connects the through electrode 120E, the gate of the amplification transistor AMP, and the source of the FD conversion gain switching transistor FDG (specifically, a connection hole reaching the source of the FD conversion gain switching transistor FDG) to each other. The first wiring layer W1 connects, for example, the through electrode 121E and the connection portion 218V to each other, whereby the VSS contact region 218 of the semiconductor layer 200S and the VSS contact region 118 of the semiconductor layer 100S are electrically connected to each other.

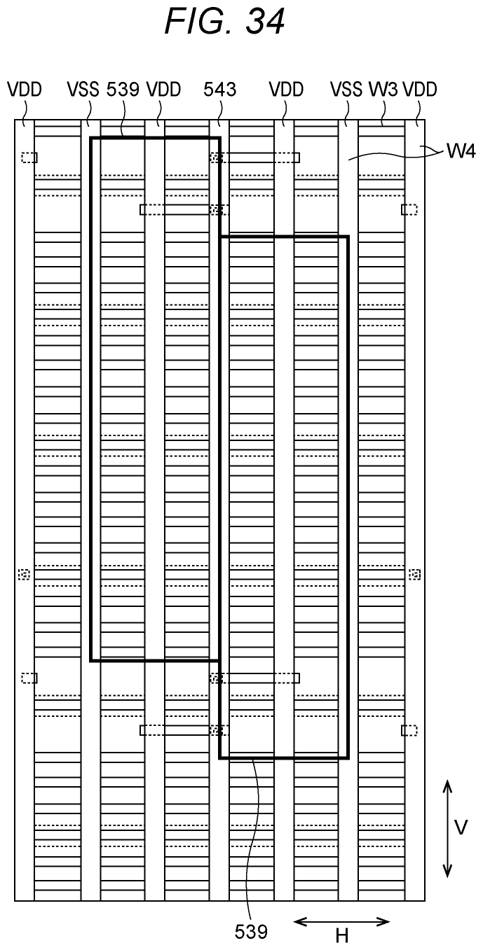

Next, a planar configuration of the wiring layer 200T will be described with reference to FIGS. 32 to 34. FIG. 32 illustrates an example of a planar configuration of the first wiring layer W1 and the second wiring layer W2. FIG. 33 illustrates an example of a planar configuration of the second wiring layer W2 and the third wiring layer W3. FIG. 34 illustrates an example of a planar configuration of the third wiring layer W3 and the fourth wiring layer W4.

For example, the third wiring layer W3 includes wiring lines TRG1, TRG2, TRG3, TRG4, SELL, RSTL, and FDGL extending in the H direction (row direction) (FIG. 33). These wiring lines correspond to the plurality of row drive signal lines 542 described with reference to FIG. 26. The wiring lines TRG1, TRG2, TRG3, and TRG4 are for sending drive signals respectively to the transfer gates TG1, TG2, TG3, and TG4. The wiring lines TRG1, TRG2, TRG3, and TRG4 are connected respectively to the transfer gates TG1, TG2, TG3, and TG4 via the second wiring layer W2, the first wiring layer W1, and the through electrode 120E. The wiring line SELL is for sending a drive signal to the gate of the selection transistor SEL, the wiring line RSTL is for sending a drive signal to the gate of the reset transistor RST, and the wiring line FDGL is for sending a drive signal to the gate of the FD conversion gain switching transistor FDG. The wiring lines SELL, RSTL, and FDGL are connected respectively to the gates of the selection transistor SEL, the reset transistor RST, and the FD conversion gain switching transistor FDG via the second wiring layer W2, the first wiring layer W1, and the connection portion.

For example, the fourth wiring layer W4 includes the power supply line VDD, the reference potential line VSS, and the vertical signal line 543 extending in the V direction (column direction) (FIG. 34). The power supply line VDD is connected to the drain of the amplification transistor AMP and the drain of the reset transistor RST via the third wiring layer W3, the second wiring layer W2, the first wiring layer W1, and the connection portion. The reference potential line VSS is connected to the VSS contact region 218 via the third wiring layer W3, the second wiring layer W2, the first wiring layer W1, and the connection portion 218V. Furthermore, the reference potential line VSS is connected to the VSS contact region 118 of the first substrate 100 via the third wiring layer W3, the second wiring layer W2, the first wiring layer W1, the through electrode 121E, and the pad portion 121. The vertical signal line 543 is connected to the source (Vout) of the selection transistor SEL via the third wiring layer W3, the second wiring layer W2, the first wiring layer W1, and the connection portion.

The contact portions 201 and 202 may be provided at positions overlapping the pixel array section 540 in plan view (for example, FIG. 25), or may be provided in the peripheral portion 540B outside the pixel array section 540 (for example, FIG. 28). The contact portions 201 and 202 are provided on the front surface (surface on the wiring layer 200T side) of the second substrate 200. The contact portions 201 and 202 include metal such as copper (Cu) and aluminum (Al), for example. The contact portions 201 and 202 are exposed on the front surface (surface on the third substrate 300 side) of the wiring layer 200T. The contact portions 201 and 202 are used for electrical connection between the second substrate 200 and the third substrate 300 and bonding between the second substrate 200 and the third substrate 300.

FIG. 28 illustrates an example in which a peripheral circuit is provided in the peripheral portion 540B of the second substrate 200. The peripheral circuit may include a part of the row drive section 520, a part of the column signal processing section 550, or the like. Furthermore, as illustrated in FIG. 25, the peripheral circuit may not be arranged in the peripheral portion 540B of the second substrate 200, and the connection holes H1 and H2 may be arranged in the vicinity of the pixel array section 540.

The third substrate 300 includes, for example, the wiring layer 300T and the semiconductor layer 300S in this order from the second substrate 200 side. For example, the front surface of the semiconductor layer 300S is provided on the second substrate 200 side. The semiconductor layer 300S includes a silicon substrate. A circuit is provided in a portion on the front surface side of the semiconductor layer 300S. Specifically, the portion on the front surface side of the semiconductor layer 300S is provided with, for example, at least a part of the input section 510A, the row drive section 520, the timing control section 530, the column signal processing section 550, the image signal processing section 560, and the output section 510B. The wiring layer 300T provided between the semiconductor layer 300S and the second substrate 200 includes, for example, an interlayer insulating film, a plurality of wiring layers separated from each other by the interlayer insulating film, and the contact portions 301 and 302. The contact portions 301 and 302 are exposed on the front surface (surface of the second substrate 200 side) of the wiring layer 300T, the contact portion 301 is in contact with the contact portion 201 of the second substrate 200, and the contact portion 302 is in contact with the contact portion 202 of the second substrate 200. The contact portions 301 and 302 are electrically connected to a circuit (for example, at least one of the input section 510A, the row drive section 520, the timing control section 530, the column signal processing section 550, the image signal processing section 560, or the output section 510B) formed in the semiconductor layer 300S. The contact portions 301 and 302 include metal such as copper (Cu) and aluminum (Al), for example. For example, an external terminal TA is connected to the input section 510A via the connection hole H1, and an external terminal TB is connected to the output section 510B via the connection hole H2.

Here, features of the imaging device 1 will be described.

In general, an imaging device mainly includes a photodiode and a pixel circuit. Here, when an area of the photodiode is increased, charges generated as a result of photoelectric conversion increases, and as a result, a signal/noise ratio (S/N ratio) of a pixel signal is improved, and the imaging device can output better image data (image information). On the other hand, when a size of a transistor (particularly, a size of an amplification transistor) included in the pixel circuit is increased, noise generated in the pixel circuit is reduced, and as a result, the S/N ratio of an imaging signal is improved, and the imaging device can output better image data (image information).

However, it is conceivable that, in an imaging device in which the photodiode and the pixel circuit are provided in the same semiconductor substrate, if the area of the photodiode is increased in a limited area of the semiconductor substrate, the size of the transistor included in the pixel circuit is reduced. Furthermore, it is conceivable that, if the size of the transistor included in the pixel circuit is increased, the area of the photodiode is reduced.

In order to solve these problems, for example, the imaging device 1 of the present embodiment uses a structure in which the plurality of pixels 541 shares one pixel circuit 210, and the shared pixel circuit 210 is arranged to overlap the photodiode PD. As a result, it is possible to achieve making an area of the photodiode PD as large as possible and making the size of the transistor included in the pixel circuit 210 as large as possible within the limited area of the semiconductor substrate. As a result, the S/N ratio of the pixel signal can be improved, and the imaging device 1 can output better image data (image information).

When a structure is implemented in which the plurality of pixels 541 shares one pixel circuit 210 and the pixel circuit is arranged to overlap the photodiode PD, a plurality of wiring lines extends that is connected to one pixel circuit 210 from the floating diffusions FD of the respective plurality of pixels 541. In order to secure a large area of the semiconductor substrate 200 in which the pixel circuit 210 is to be formed, for example, a connection wiring line can be formed in which the plurality of extending wiring lines is connected to each other and integrated into one. Similarly, for a plurality of wiring lines extending from the VSS contact regions 118, it is possible to form a connection wiring line in which the plurality of extending wiring lines is connected to each other and integrated into one.

It is conceivable that, for example, when a connection wiring line in which the plurality of wiring lines extending from the floating diffusions FD of the respective plurality of pixels 541 is connected to each other is formed in the semiconductor substrate 200 in which the pixel circuit 210 is to be formed, an area for forming the transistors included in the pixel circuit 210 is reduced. Similarly, it is conceivable that, when a connection wiring line in which the plurality of wiring lines extending from the VSS contact regions 118 of the respective plurality of pixels 541 is connected to each other and integrated into one is formed in the semiconductor substrate 200 in which the pixel circuit 210 is to be formed, the area for forming the transistors included in the pixel circuit 210 is reduced.

In order to solve these problems, for example, the imaging device 1 of the present embodiment can have a structure in which the plurality of pixels 541 shares one pixel circuit 210, and the shared pixel circuit 210 is arranged to overlap the photodiode PD, and a connection wiring line in which the floating diffusions FD of the respective plurality of pixels 541 are connected to each other and integrated into one, and a connection wiring line in which the VSS contact regions 118 included in the respective plurality of pixels 541 are connected to each other and integrated into one are provided in the first substrate 100.

Here, when the second manufacturing method described above is used as a manufacturing method for providing, on the first substrate 100, the connection wiring line in which the floating diffusions FD of the respective plurality of pixels 541 are connected to each other and integrated into one and the connection wiring line in which the VSS contact regions 118 of the respective plurality of pixels 541 are connected to each other and integrated into one, for example, it is possible to perform manufacturing using an appropriate process according to the configuration of each of the first substrate 100 and the second substrate 200, and manufacture a high-quality and high-performance imaging device. Furthermore, the connection wiring lines of the first substrate 100 and the second substrate 200 can be formed by an easy process. Specifically, in the case of using the second manufacturing method described above, an electrode connected to the floating diffusion FD and an electrode connected to the VSS contact region 118 are provided respectively on the surface of the first substrate 100 and the surface of the second substrate 200, which are bonding boundary surfaces of the first substrate 100 and the second substrate 200. Moreover, it is preferable to enlarge the electrodes formed on the two substrate surfaces so that the electrodes formed on the two substrate surfaces come into contact with each other even if positional deviation occurs between the electrodes provided on the two substrate surfaces when the first substrate 100 and the second substrate 200 are bonded to each other. In this case, it is conceivable that it becomes difficult to arrange the electrodes described above in a limited area of each pixel included in the imaging device 1.

In order to solve the problem that large electrodes are required at the bonding boundary surfaces of the first substrate 100 and the second substrate 200, for example, the imaging device 1 of the present embodiment can use the first manufacturing method described above as a manufacturing method in which the plurality of pixels 541 shares one pixel circuit 210, and the shared pixel circuit 210 is arranged to overlap the photodiode PD. As a result, it is easy to align the elements formed on the first substrate 100 and the second substrate 200, and a high-quality and high-performance imaging device can be manufactured. Moreover, it is possible to have a unique structure generated by using this manufacturing method. That is, the imaging device has a structure in which the semiconductor layer 100S and the wiring layer 100T of the first substrate 100 and the semiconductor layer 200S and the wiring layer 200T of the second substrate 200 are stacked in this order, in other words, a structure in which the first substrate 100 and the second substrate 200 are stacked in a face-to-back manner, and the through electrodes 120E and 121E are included that extend from the front surface side of the semiconductor layer 200S of the second substrate 200 through the semiconductor layer 200S and the wiring layer 100T of the first substrate 100 to the front surface of the semiconductor layer 100S of the first substrate 100.

In a structure in which the connection wiring line in which the floating diffusions FD of the respective plurality of pixels 541 are connected to each other and integrated into one and the connection wiring line in which the VSS contact regions 118 of the respective plurality of pixels 541 are connected to each other and integrated into one are provided in the first substrate 100, when this structure and the second substrate 200 are stacked by using the first manufacturing method to form the pixel circuit 210 on the second substrate 200, there is a possibility that the heating treatment necessary in forming the active element included in the pixel circuit 210 may affect the connection wiring line formed on the first substrate 100.

Thus, in order to solve the problem that the connection wiring line is affected by the heating treatment in forming the active element, it is desirable that the imaging device 1 of the present embodiment uses a conductive material having high heat resistance for the connection wiring line in which the floating diffusions FD of the respective plurality of pixels 541 are connected to each other and integrated into one and the connection wiring line in which the VSS contact regions 118 of the respective plurality of pixels 541 are connected to each other and integrated into one. Specifically, as the conductive material having high heat resistance, it is possible to use a material having a melting point higher than that of at least a part of the wiring material included in the wiring layer 200T of the second substrate 200.

As described above, for example, the imaging device 1 of the present embodiment includes: (1) a structure in which the first substrate 100 and the second substrate 200 are stacked in a face-to-back manner (specifically, a structure in which the semiconductor layer 100S and the wiring layer 100T of the first substrate 100 and the semiconductor layer 200S and the wiring layer 200T of the second substrate 200 are stacked in this order); (2) a structure in which the through electrodes 120E and 121E are provided that extend from the front surface side of the semiconductor layer 200S of the second substrate 200 through the semiconductor layer 200S and the wiring layer 100T of the first substrate 100 to the front surface of the semiconductor layer 100S of the first substrate 100; and (3) a structure in which the connection wiring line in which the floating diffusions FD included in the respective plurality of pixels 541 are connected to each other and integrated into one and the connection wiring line in which the VSS contact regions 118 included in the respective plurality of pixels 541 are connected to each other and integrated into one include a conductive material having high heat resistance, thereby enabling provision of the connection wiring line in which the floating diffusions FD included in the respective plurality of pixels 541 are connected to each other and integrated into one and the connection wiring line in which the VSS contact regions 118 included in the respective plurality of pixels 541 are connected to each other and integrated into one in the first substrate 100 without including a large electrode at an interface between the first substrate 100 and the second substrate 200.

### Operation of Imaging Device 1

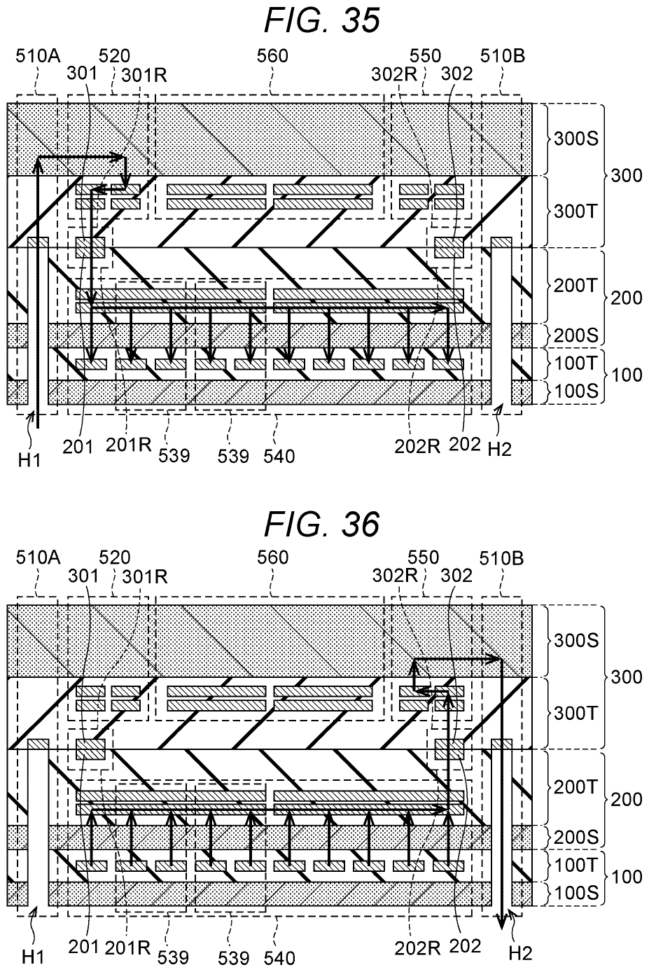

Next, operation of the imaging device 1 will be described with reference to FIGS. 35 and 36. FIGS. 35 and 36 are diagrams in which an arrow representing a path of each signal is added to FIG. 25. In FIG. 35, a path of an input signal input to the imaging device 1 from the outside, a power supply potential, and a reference potential is indicated by an arrow. In FIG. 36, a signal path of a pixel signal output from the imaging device 1 to the outside is indicated by an arrow. For example, an input signal (for example, a pixel clock and a synchronization signal) input to the imaging device 1 via the input section 510A is transmitted to the row drive section 520 of the third substrate 300, and the row drive section 520 creates a row drive signal. The row drive signal is sent to the second substrate 200 via the contact portions 301 and 201. Moreover, the row drive signal reaches each of the pixel sharing units 539 of the pixel array section 540 via the row drive signal line 542 in the wiring layer 200T. Among row drive signals reaching the pixel sharing units 539 of the second substrate 200, drive signals other than for the transfer gate TG are input to the pixel circuit 210, and the transistors included in the pixel circuit 210 are driven. The drive signals for the transfer gates TG are input to the transfer gates TG1, TG2, TG3, and TG4 of the first substrate 100 via the through electrode TGV, and the pixels 541A, 541B, 541C, and 541D are driven (FIG. 35). Furthermore, the power supply potential and the reference potential supplied from the outside of the imaging device 1 to the input section 510A (input terminal 511) of the third substrate 300 are sent to the second substrate 200 via the contact portions 301 and 201, and supplied to the pixel circuit 210 of each of the pixel sharing units 539 via the wiring lines in the wiring layer 200T. The reference potential is further supplied to the pixels 541A, 541B, 541C, and 541D of the first substrate 100 via the through electrode 121E. On the other hand, the pixel signals photoelectrically converted by the pixels 541A, 541B, 541C, and 541D of the first substrate 100 are sent to the pixel circuit 210 of the second substrate 200 for each pixel sharing unit 539 via the through electrode 120E. Pixel signals based on the pixel signals are sent from the pixel circuit 210 to the third substrate 300 via the vertical signal line 543 and the contact portions 202 and 302. The pixel signal is processed by the column signal processing section 550 and the image signal processing section 560 of the third substrate 300, and then output to the outside via the output section 510B.

### Effects

In the present embodiment, the pixels 541A, 541B, 541C, and 541D (pixel sharing unit 539) and the pixel circuit 210 are provided in different substrates (the first substrate 100 and the second substrate 200). Thus, areas of the pixels 541A, 541B, 541C, and 541D and the pixel circuit 210 can be enlarged as compared with a case where the pixels 541A, 541B, 541C, and 541D and the pixel circuit 210 are formed on the same substrate. As a result, an amount of the pixel signal obtained by photoelectric conversion can be increased, and transistor noise of the pixel circuit 210 can be reduced. Thus, the signal/noise ratio of the pixel signal is improved, and the imaging device 1 can output better pixel data (image information). Furthermore, the imaging device 1 can be miniaturized (in other words, the pixel size is reduced and the imaging device 1 is downsized). The imaging device 1 can increase the number of pixels per unit area due to reduction in pixel size, and can output a high-quality image.

Furthermore, in the imaging device 1, the first substrate 100 and the second substrate 200 are electrically connected to each other by the through electrodes 120E and 121E provided in the insulating region 212. For example, a method may be considered of connecting the first substrate 100 and the second substrate 200 by bonding pad electrodes to each other, or connecting the first substrate 100 and the second substrate 200 by a through wiring line (for example, through Si via (TSV)) penetrating the semiconductor layer. As compared with such a method, by providing the through electrodes 120E and 121E in the insulating region 212, it is possible to reduce an area required for connecting the first substrate 100 and the second substrate 200 to each other. As a result, the pixel size can be reduced, and the imaging device 1 can be further downsized. Furthermore, it is possible to further increase the resolution by further miniaturizing an area per pixel. When it is not necessary to reduce a chip size, formation regions can be enlarged for the pixels 541A, 541B, 541C, and 541D and the pixel circuit 210. As a result, the amount of the pixel signal obtained by photoelectric conversion can be increased, and noise of the transistor included in the pixel circuit 210 can be reduced. Thus, the signal/noise ratio of the pixel signal is improved, and the imaging device 1 can output better pixel data (image information).

Furthermore, in the imaging device 1, the pixel circuit 210 and the column signal processing section 550 and the image signal processing section 560 are provided in different substrates (the second substrate 200 and the third substrate 300). As a result, the area of the pixel circuit 210 and areas of the column signal processing section 550 and the image signal processing section 560 can be enlarged as compared with a case where the pixel circuit 210 and the column signal processing section 550 and the image signal processing section 560 are formed on the same substrate. As a result, noise generated in the column signal processing section 550 can be reduced, and a more advanced image processing circuit can be mounted on the image signal processing section 560. Thus, the signal/noise ratio of the pixel signal is improved, and the imaging device 1 can output better pixel data (image information).

Furthermore, in the imaging device 1, the pixel array section 540 is provided in the first substrate 100 and the second substrate 200, and the column signal processing section 550 and the image signal processing section 560 are provided in the third substrate 300. Furthermore, the contact portions 201, 202, 301, and 302 connecting the second substrate 200 and the third substrate 300 to each other is formed above the pixel array section 540. For this reason, the contact portions 201, 202, 301, and 302 can be freely laid out without receiving layout interference from various wiring lines included in the pixel array. As a result, the contact portions 201, 202, 301, and 302 can be used for electrical connection between the second substrate 200 and the third substrate 300. By using the contact portions 201, 202, 301, and 302, for example, the column signal processing section 550 and the image signal processing section 560 have a higher degree of freedom in layout. As a result, noise generated in the column signal processing section 550 can be reduced, and a more advanced image processing circuit can be mounted on the image signal processing section 560. Thus, the signal/noise ratio of the pixel signal is improved, and the imaging device 1 can output better pixel data (image information).

Furthermore, in the imaging device 1, the pixel isolation portion 117 penetrates the semiconductor layer 100S. As a result, color mixing among the pixels 541A, 541B, 541C, and 541D can be suppressed even in a case where a distance between adjacent pixels (pixels 541A, 541B, 541C, and 541D) is shortened due to miniaturization of the area per pixel. Thus, the signal/noise ratio of the pixel signal is improved, and the imaging device 1 can output better pixel data (image information).

Furthermore, in the imaging device 1, the pixel circuit 210 is provided for each pixel sharing unit 539. As a result, as compared with a case where the pixel circuit 210 is provided in each of the pixels 541A, 541B, 541C, and 541D, a formation region can be enlarged for the transistors (amplification transistor AMP, reset transistor RST, selection transistor SEL, and FD conversion gain switching transistor FDG) constituting the pixel circuit 210. For example, it is possible to suppress noise by enlarging the formation region for the amplification transistor AMP. Thus, the signal/noise ratio of the pixel signal is improved, and the imaging device 1 can output better pixel data (image information).

Furthermore, in the imaging device 1, the pad portion 120 is provided on the first substrate 100, the pad portion 120 electrically connecting the floating diffusions FD (floating diffusions FD1, FD2, FD3, and FD4) of the four pixels (pixels 541A, 541B, 541C, and 541D) to each other. As a result, as compared with a case where such a pad portion 120 is provided on the second substrate 200, it is possible to reduce the number of through electrodes (through electrodes 120E) connecting the first substrate 100 and the second substrate 200 to each other. Thus, the insulating region 212 can be reduced, and it is possible to secure the formation region (semiconductor layer 200S) for the transistors constituting the pixel circuit 210 with a sufficient size. As a result, noise of the transistor included in the pixel circuit 210 can be reduced, the signal/noise ratio of the pixel signal is improved, and the imaging device 1 can output better pixel data (image information).

Hereinafter, a description will be given of modifications of the imaging device 1 according to the above embodiments. In the following modifications, components common to the above embodiment will be denoted by the same reference signs.

### 2. Modification 1

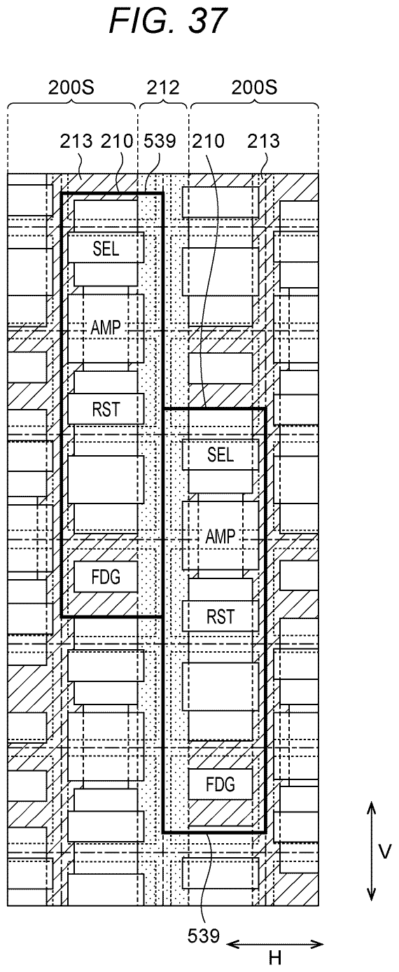

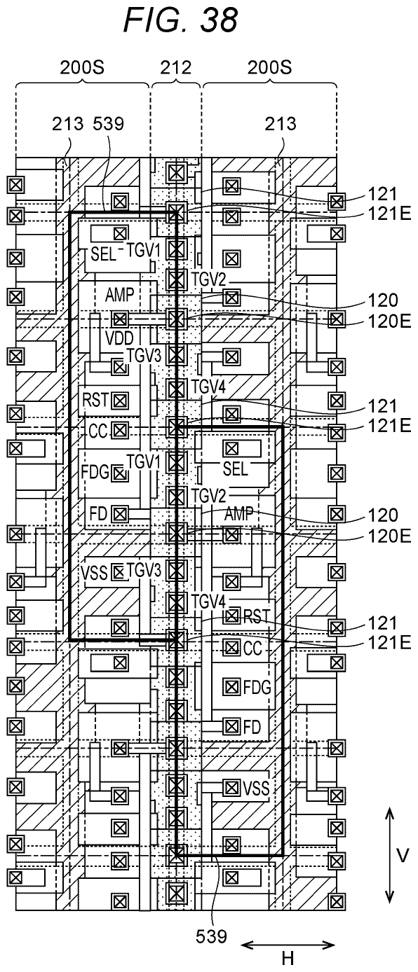

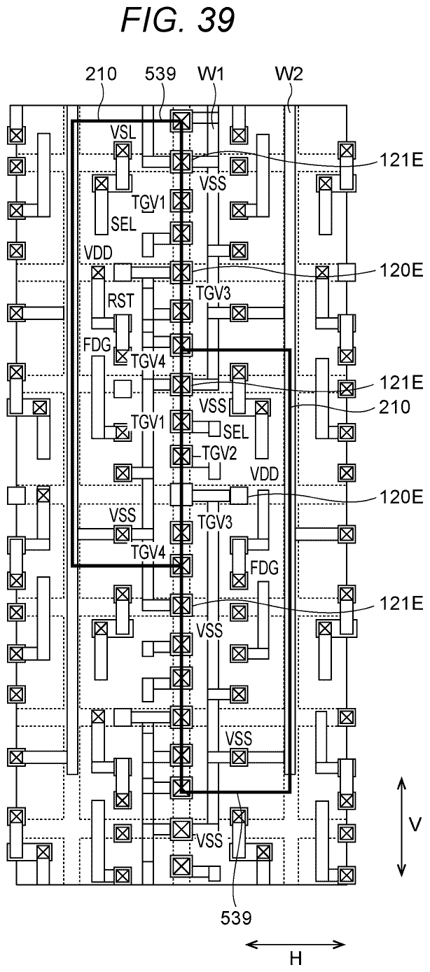

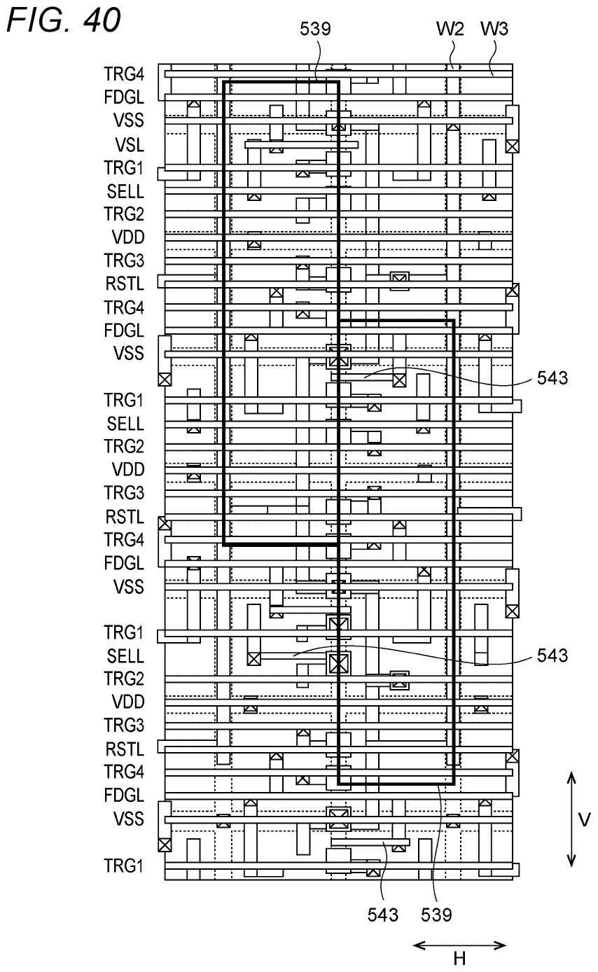

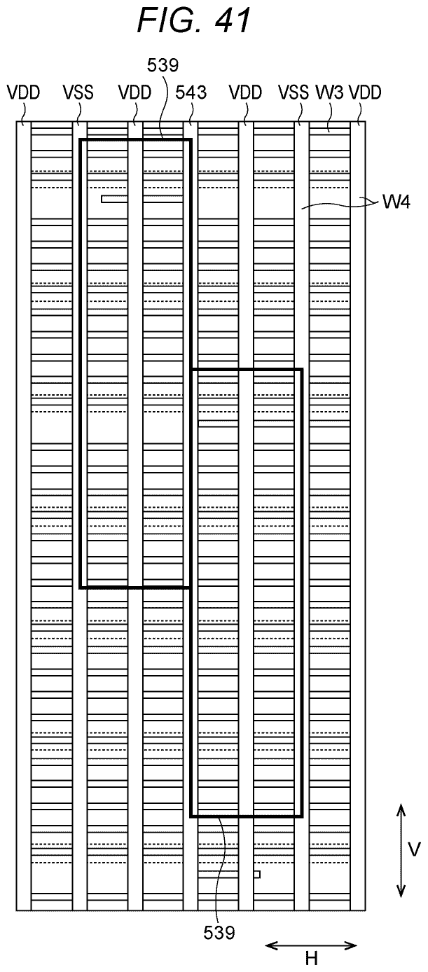

FIGS. 37 to 41 illustrate a modification of a planar configuration of the imaging device 1 according to the above embodiments. FIG. 37 schematically illustrates a planar configuration in the vicinity of the front surface of the semiconductor layer 200S of the second substrate 200, and corresponds to FIG. 30 described in the above embodiments. FIG. 38 schematically illustrates a configuration of each part of the first wiring layer W1, the semiconductor layer 200S connected to the first wiring layer W1, and the first substrate 100, and corresponds to FIG. 31 described in the above embodiments. FIG. 39 illustrates an example of the planar configuration of the first wiring layer W1 and the second wiring layer W2, and corresponds to FIG. 32 described in the above embodiments. FIG. 40 illustrates an example of the planar configuration of the second wiring layer W2 and the third wiring layer W3, and corresponds to FIG. 33 described in the above embodiments. FIG. 41 illustrates an example of the planar configuration of the third wiring layer W3 and the fourth wiring layer W4, and corresponds to FIG. 34 described in the above embodiments.

In the present modification, as illustrated in FIG. 38, among the two pixel sharing units 539 arranged in the H direction of the second substrate 200, the internal layout of one pixel sharing unit 539 (for example, the right side of the figure) has a configuration in which the internal layout of the other pixel sharing unit 539 (for example, the left side of the figure) is inverted only in the H direction. Furthermore, a deviation in the V direction between the outline of one pixel sharing unit 539 and the outline of the other pixel sharing unit 539 is larger than a deviation (FIG. 31) described in the above embodiments. As described above, by increasing the deviation in the V direction, it is possible to reduce the distance between the amplification transistor AMP of the other pixel sharing unit 539 and the pad portion 120 (the pad portion 120 of the other (lower side of the figure) of the two pixel sharing units 539 arranged in the V direction illustrated in FIG. 29) connected to the amplification transistor AMP. With such a layout, Modification 1 of the imaging device 1 illustrated in FIGS. 37 to 41 can make an area of the planar layout of the two pixel sharing units 539 arranged in the H direction the same as an area of the pixel sharing units 539 of the second substrate 200 described in the above embodiments without inverting the planar layout of the two pixel sharing units 539 in the V direction. Note that the planar layout of the pixel sharing unit 539 of the first substrate 100 is the same as the planar layout (FIG. 29A, FIG. 29B) described in the above embodiments. Thus, the imaging device 1 of the present modification can obtain effects similar to those of the imaging device 1 described in the above embodiments. The arrangement of the pixel sharing unit 539 of the second substrate 200 is not limited to the arrangement described in the above embodiments and the present modification.

### 3. Modification 2

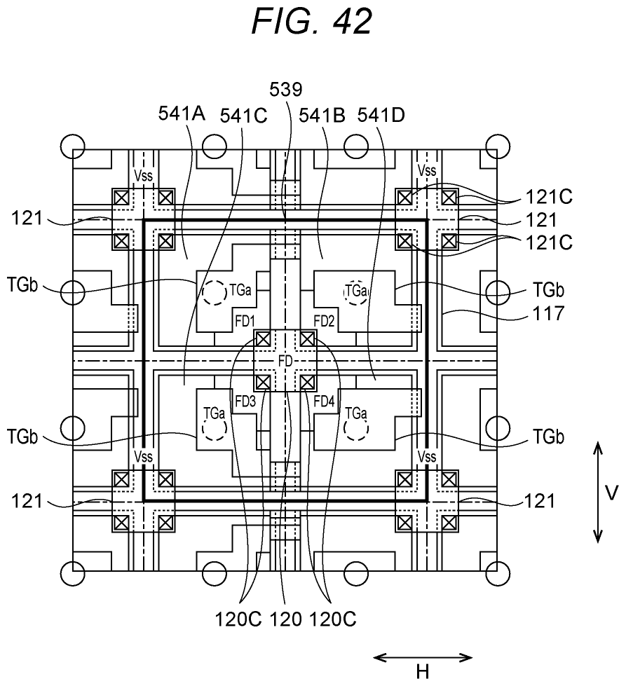

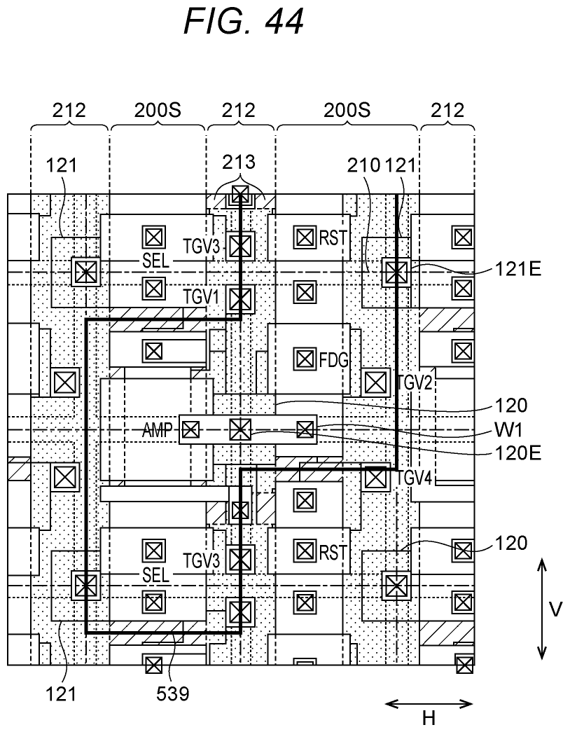

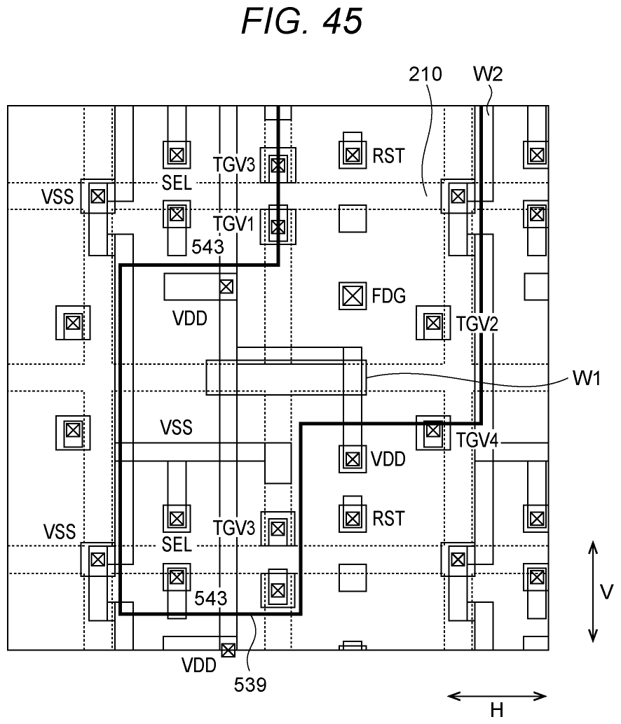

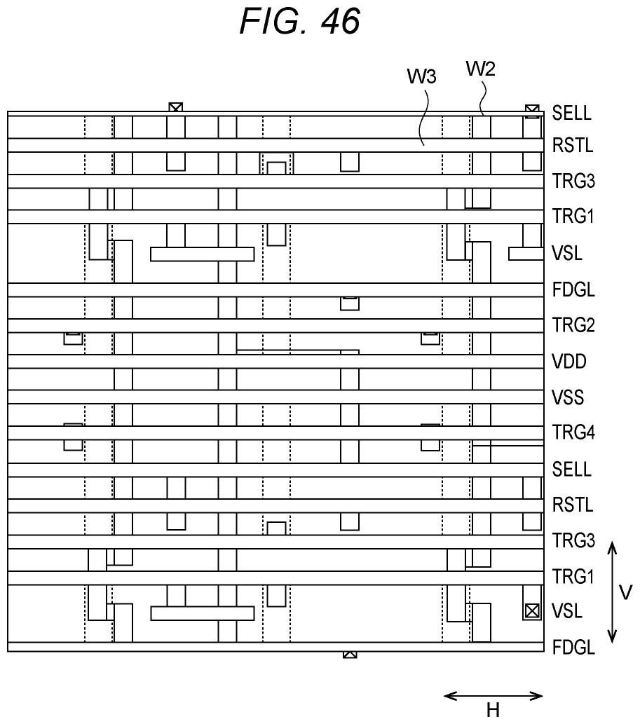

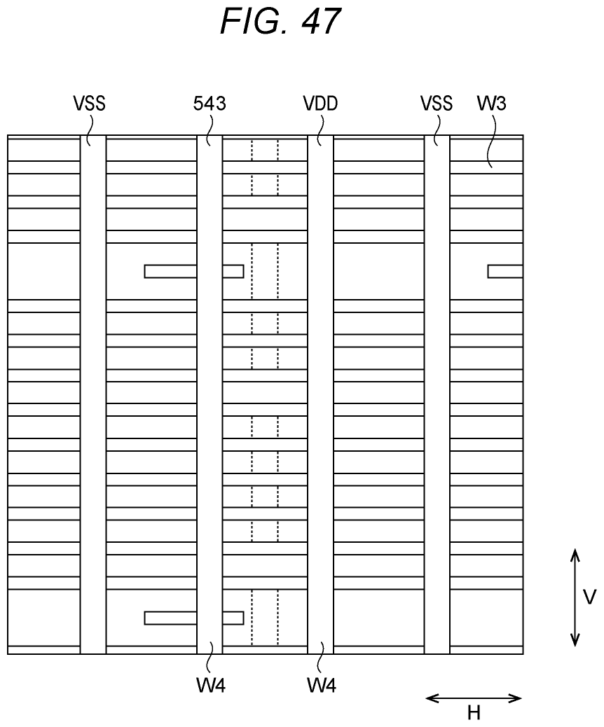

FIGS. 42 to 47 illustrate a modification of the planar configuration of the imaging device 1 according to the above embodiments. FIG. 42 schematically illustrates the planar configuration of the first substrate 100, and corresponds to FIG. 29A described in the above embodiments. FIG. 43 schematically illustrates the planar configuration in the vicinity of the front surface of the semiconductor layer 200S of the second substrate 200, and corresponds to FIG. 30 described in the above embodiments. FIG. 44 schematically illustrates a configuration of each part of the first wiring layer W1, the semiconductor layer 200S connected to the first wiring layer W1, and the first substrate 100, and corresponds to FIG. 31 described in the above embodiments. FIG. 45 illustrates an example of the planar configuration of the first wiring layer W1 and the second wiring layer W2, and corresponds to FIG. 32 described in the above embodiments. FIG. 46 illustrates an example of the planar configuration of the second wiring layer W2 and the third wiring layer W3, and corresponds to FIG. 33 described in the above embodiments. FIG. 47 illustrates an example of the planar configuration of the third wiring layer W3 and the fourth wiring layer W4, and corresponds to FIG. 34 described in the above embodiments.

In the present modification, the outer shape of each pixel circuit 210 has a substantially square planar shape (FIG. 43 and the like). In this respect, the planar configuration of the imaging device 1 of the present modification is different from the planar configuration of the imaging device 1 described in the above embodiments.

For example, the pixel sharing unit 539 of the first substrate 100 is formed over a region of pixels of two rows×two columns, and has a substantially square planar shape (FIG. 42), as described in the above embodiments. For example, in each pixel sharing unit 539, the horizontal portions TGb of the transfer gates TG1 and TG3 of the pixel 541A and the pixel 541C of one pixel column extend in a direction from a position overlapping the vertical portion TGa toward the central portion of the pixel sharing unit 539 in the H direction (more specifically, a direction toward outer edges of the pixels 541A and 541C and a direction toward the central portion of the pixel sharing unit 539), and the horizontal portions TGb of the transfer gates TG2 and TG4 of the pixel 541B and the pixel 541D of the other pixel column extend in a direction from a position overlapping the vertical portion TGa toward the outside of the pixel sharing unit 539 in the H direction (more specifically, a direction toward outer edges of the pixels 541B and 541D and a direction toward the outside of the pixel sharing unit 539). The pad portion 120 connected to the floating diffusion FD is provided at the central portion of the pixel sharing unit 539 (the central portion of the pixel sharing unit 539 in the H direction and the V direction), and the pad portion 121 connected to the VSS contact region 118 is provided at an end portion of the pixel sharing unit 539 at least in the H direction (in the H direction and the V direction in FIG. 42).

As another arrangement example, it is also conceivable to provide the horizontal portions TGb of the transfer gates TG1, TG2, TG3, and TG4 only in a region facing the vertical portion TGa. At this time, the semiconductor layer 200S is likely to be finely divided as described in the above embodiments. Thus, it is difficult to form a large transistor of the pixel circuit 210. On the other hand, when the horizontal portions TGb of the transfer gates TG1, TG2, TG3, and TG4 are extended in the H direction from the position overlapping the vertical portions TGa as in the above modification, a width of the semiconductor layer 200S can be increased as described in the above embodiments. Specifically, the positions in the H direction of the through electrodes TGV1 and TGV3 connected to the transfer gates TG1 and TG3 can be arranged close to the position in the H direction of the through electrode 120E, and the positions in the H direction of the through electrodes TGV2 and TGV4 connected to the transfer gates TG2 and TG4 can be arranged close to the position in the H direction of the through electrode 121E (FIG. 44). As a result, the width (size in the H direction) of the semiconductor layer 200S extending in the V direction can be increased as described in the above embodiments. Thus, it is possible to increase the sizes of the transistors of the pixel circuit 210, particularly, the size of the amplification transistor AMP. As a result, the signal/noise ratio of the pixel signal is improved, and the imaging device 1 can output better pixel data (image information).

The pixel sharing unit 539 of the second substrate 200 has, for example, substantially the same size in the H direction and the V direction as that of the pixel sharing unit 539 of the first substrate 100, and is provided over, for example, a region corresponding to a region of pixels of approximately two rows×two columns. For example, in each pixel circuit 210, the selection transistor SEL and the amplification transistor AMP are arranged side by side in the V direction in one semiconductor layer 200S extending in the V direction, and the FD conversion gain switching transistor FDG and the reset transistor RST are arranged side by side in the V direction in one semiconductor layer 200S extending in the V direction. One semiconductor layer 200S provided with the selection transistor SEL and the amplification transistor AMP and one semiconductor layer 200S provided with the FD conversion gain switching transistor FDG and the reset transistor RST are arranged in the H direction with the insulating region 212 interposed therebetween. The insulating region 212 extends in the V direction (FIG. 43).

Here, the outer shape of the pixel sharing unit 539 of the second substrate 200 will be described with reference to FIGS. 43 and 44. For example, the pixel sharing unit 539 of the first substrate 100 illustrated in FIG. 42 is connected to the amplification transistor AMP and the selection transistor SEL provided on one side (the left side of FIG. 44) of the pad portion 120 in the H direction, and the FD conversion gain switching transistor FDG and the reset transistor RST provided on the other side (the right side of FIG. 44) of the pad portion 120 in the H direction. The outer shape of the sharing unit 541 of the second substrate 200 including the amplification transistor AMP, the selection transistor SEL, the FD conversion gain switching transistor FDG, and the reset transistor RST is determined by the following four outer edges.

A first outer edge is an outer edge of one end (end on the upper side of FIG. 44) in the V direction of the semiconductor layer 200S including the selection transistor SEL and the amplification transistor AMP. The first outer edge is provided between the amplification transistor AMP included in the pixel sharing unit 539 and the selection transistor SEL included in another pixel sharing unit 539 adjacent to one side (the upper side of FIG. 44) of the pixel sharing unit 539 in the V direction. More specifically, the first outer edge is provided at the central portion in the V direction of the element isolation region 213 between the amplification transistor AMP and the selection transistor SEL. A second outer edge is an outer edge of the other end (end on the lower side of FIG. 44) in the V direction of the semiconductor layer 200S including the selection transistor SEL and the amplification transistor AMP. The second outer edge is provided between the selection transistor SEL included in the pixel sharing unit 539 and the amplification transistor AMP included in another pixel sharing unit 539 adjacent to the other side (the lower side of FIG. 44) of the pixel sharing unit 539 in the V direction. More specifically, the second outer edge is provided at the central portion in the V direction of the element isolation region 213 between the selection transistor SEL and the amplification transistor AMP. A third outer edge is an outer edge of the other end (end on the lower side of FIG. 44) in the V direction of the semiconductor layer 200S including the reset transistor RST and the FD conversion gain switching transistor FDG. The third outer edge is provided between the FD conversion gain switching transistor FDG included in the pixel sharing unit 539 and the reset transistor RST included in another pixel sharing unit 539 adjacent to the other side (the lower side of FIG. 44) of the pixel sharing unit 539 in the V direction. More specifically, the third outer edge is provided at the central portion in the V direction of the element isolation region 213 between the FD conversion gain switching transistor FDG and the reset transistor RST. A fourth outer edge is an outer edge of one end (end on the upper side of FIG. 44) in the V direction of the semiconductor layer 200S including the reset transistor RST and the FD conversion gain switching transistor FDG. The fourth outer edge is provided between the reset transistor RST included in the pixel sharing unit 539 and the FD conversion gain switching transistor FDG (not illustrated) included in another pixel sharing unit 539 adjacent to one side (the upper side of FIG. 44) of the pixel sharing unit 539 in the V direction. More specifically, the fourth outer edge is provided at the central portion in the V direction of the element isolation region 213 (not illustrated) between the reset transistor RST and the FD conversion gain switching transistor FDG.

In the outer shape of the pixel sharing unit 539 of the second substrate 200 including such first, second, third, and fourth outer edges, the third and fourth outer edges are arranged to be shifted to one side in the V direction (in other words, offset to one side in the V direction) with respect to the first and second outer edges. By using such a layout, it is possible to arrange both the gate of the amplification transistor AMP and the source of the FD conversion gain switching transistor FDG as close as possible to the pad portion 120. Thus, an area of wiring lines connecting them to each other is reduced, and the imaging device 1 can be easily miniaturized. Note that the VSS contact region 218 is provided between the semiconductor layer 200S including the selection transistor SEL and the amplification transistor AMP and the semiconductor layer 200S including the reset transistor RST and the FD conversion gain switching transistor FDG. For example, the plurality of pixel circuits 210 has the same arrangement.

The imaging device 1 including such a second substrate 200 can also obtain effects similar to those described in the above embodiments. The arrangement of the pixel sharing unit 539 of the second substrate 200 is not limited to the arrangement described in the above embodiments and the present modification.

### 4. Modification 3

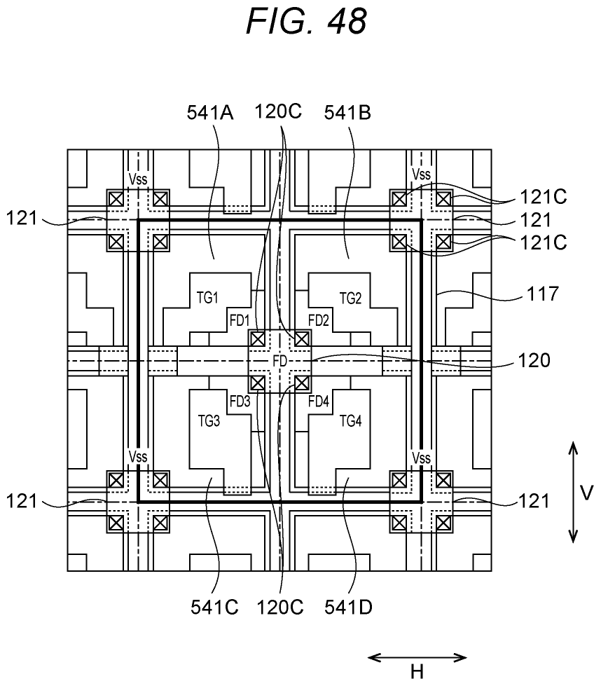

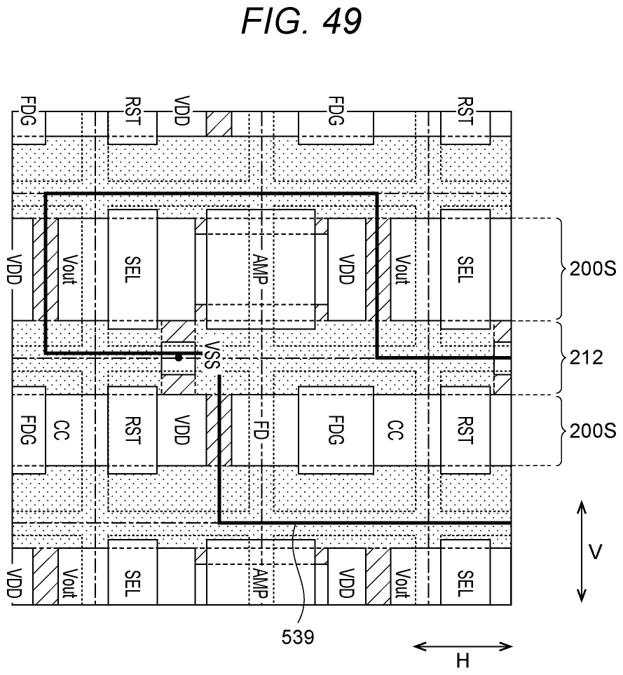

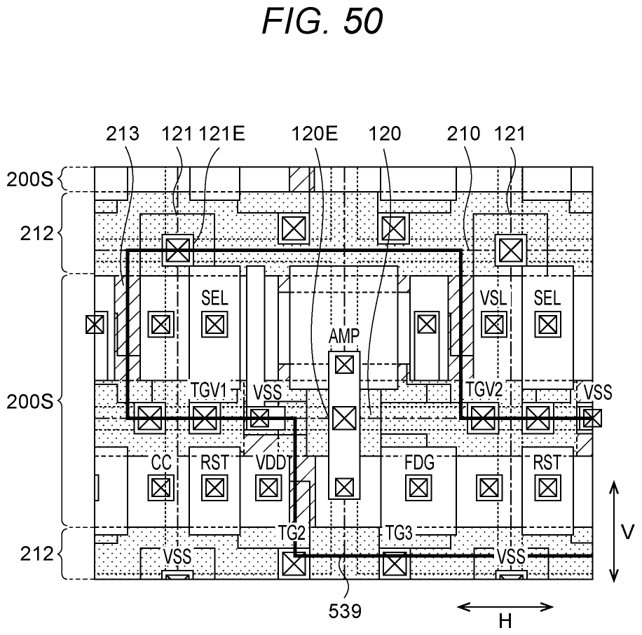

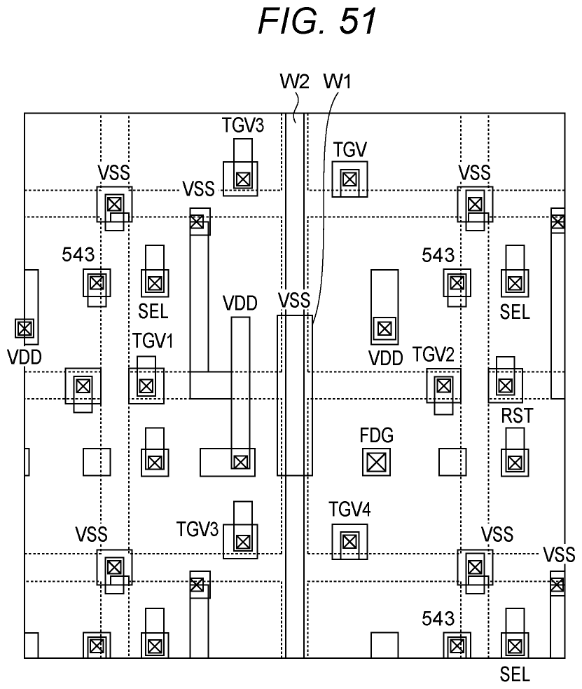

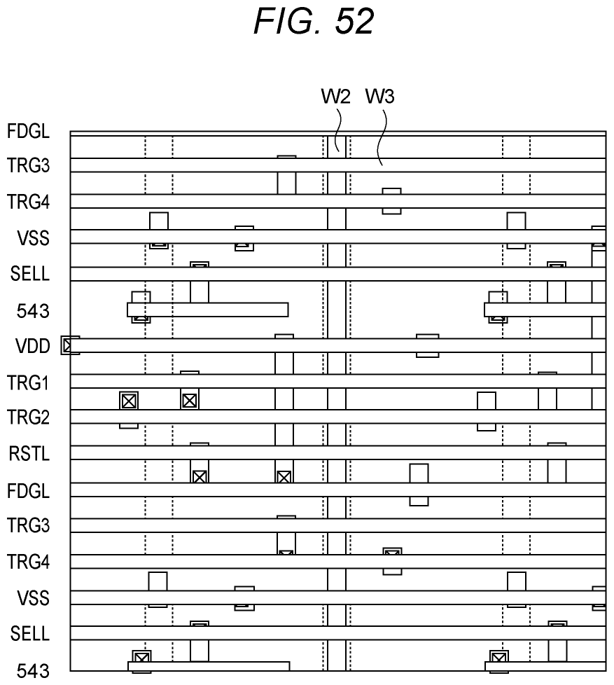

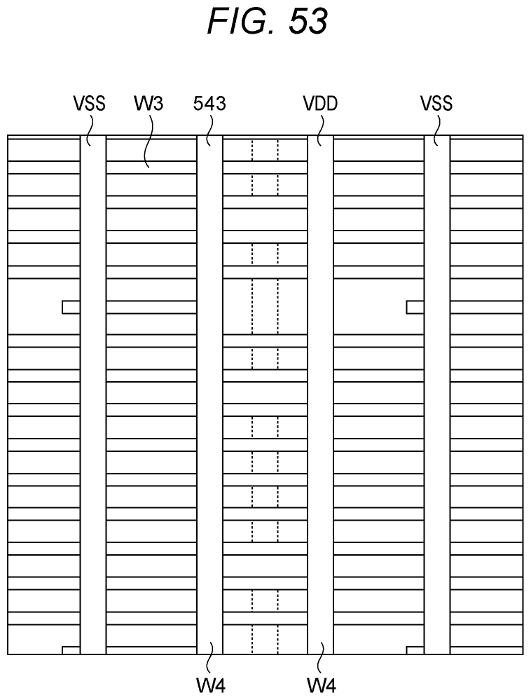

FIGS. 48 to 53 illustrate a modification of the planar configuration of the imaging device 1 according to the above embodiments. FIG. 48 schematically illustrates the planar configuration of the first substrate 100, and corresponds to FIG. 29B described in the above embodiments. FIG. 49 schematically illustrates the planar configuration in the vicinity of the front surface of the semiconductor layer 200S of the second substrate 200, and corresponds to FIG. 30 described in the above embodiments. FIG. 50 schematically illustrates a configuration of each part of the first wiring layer W1, the semiconductor layer 200S connected to the first wiring layer W1, and the first substrate 100, and corresponds to FIG. 31 described in the above embodiments. FIG. 51 illustrates an example of the planar configuration of the first wiring layer W1 and the second wiring layer W2, and corresponds to FIG. 32 described in the above embodiments. FIG. 52 illustrates an example of the planar configuration of the second wiring layer W2 and the third wiring layer W3, and corresponds to FIG. 33 described in the above embodiments. FIG. 53 illustrates an example of the planar configuration of the third wiring layer W3 and the fourth wiring layer W4, and corresponds to FIG. 34 described in the above embodiments.

In the present modification, the semiconductor layer 200S of the second substrate 200 extends in the H direction (FIG. 50). That is, it substantially corresponds to a configuration in which the planar configuration of the imaging device 1 illustrated in FIG. 43 described above and the like is rotated by 90 degrees.

For example, the pixel sharing unit 539 of the first substrate 100 is formed over a region of pixels of two rows×two columns, and has a substantially square planar shape (FIG. 48), as described in the above embodiments. For example, in each pixel sharing unit 539, the transfer gates TG1 and TG2 of the pixel 541A and the pixel 541B of one pixel row extend toward the central portion of the pixel sharing unit 539 in the V direction, and the transfer gates TG3 and TG4 of the pixel 541C and the pixel 541D of the other pixel row extend in the outward direction of the pixel sharing unit 539 in the V direction. The pad portion 120 connected to the floating diffusion FD is provided at the central portion of the pixel sharing unit 539, and the pad portion 121 connected to the VSS contact region 118 is provided at the end portion of the pixel sharing unit 539 at least in the V direction (in the V direction and the H direction in FIG. 48). At this time, the positions in the V direction of the through electrodes TGV1 and TGV2 of the transfer gates TG1 and TG2 are close to the positions in the V direction of the through electrode 120E, and the positions in the V direction of the through electrodes TGV3 and TGV4 of the transfer gates TG3 and TG4 are close to the positions in the V direction of the through electrode 121E (FIG. 50). Thus, the width (the size in the V direction) of the semiconductor layer 200S extending in the H direction can be increased for reasons similar to those described in the above embodiments. Thus, it is possible to increase the size of the amplification transistor AMP and suppress noise.

In each pixel circuit 210, the selection transistor SEL and the amplification transistor AMP are arranged side by side in the H direction, and the reset transistor RST is arranged at a position adjacent to the selection transistor SEL in the V direction with the insulating region 212 interposed therebetween (FIG. 49). The FD conversion gain switching transistor FDG is arranged side by side with the reset transistor RST in the H direction. The VSS contact region 218 is provided like an island in the insulating region 212. For example, the third wiring layer W3 extends in the H direction (FIG. 52), and the fourth wiring layer W4 extends in the V direction (FIG. 53).

The imaging device 1 including such a second substrate 200 can also obtain effects similar to those described in the above embodiments. The arrangement of the pixel sharing unit 539 of the second substrate 200 is not limited to the arrangement described in the above embodiments and the present modification. For example, the semiconductor layer 200S described in the above embodiments and Modification 1 may extend in the H direction.

### 5. Modification 4

FIG. 54 schematically illustrates a modification of the cross-sectional configuration of the imaging device 1 according to the above embodiments. FIG. 54 corresponds to FIG. 25 described in the above embodiments. In the present modification, the imaging device 1 includes contact portions 203, 204, 303, and 304 at positions facing each other in the central portion of the pixel array section 540 in addition to the contact portions 201, 202, 301, and 302. In this respect, the imaging device 1 of the present modification is different from the imaging device 1 described in the above embodiments.

The contact portions 203 and 204 are provided on the second substrate 200, and are exposed on a bonding surface with the third substrate 300. The contact portions 303 and 304 are provided on the third substrate 300, and are exposed on a bonding surface with the second substrate 200. The contact portion 203 is in contact with the contact portion 303, and the contact portion 204 is in contact with the contact portion 304. That is, in the imaging device 1, the second substrate 200 and the third substrate 300 are connected to each other by the contact portions 203, 204, 303, and 304 in addition to the contact portions 201, 202, 301, and 302.

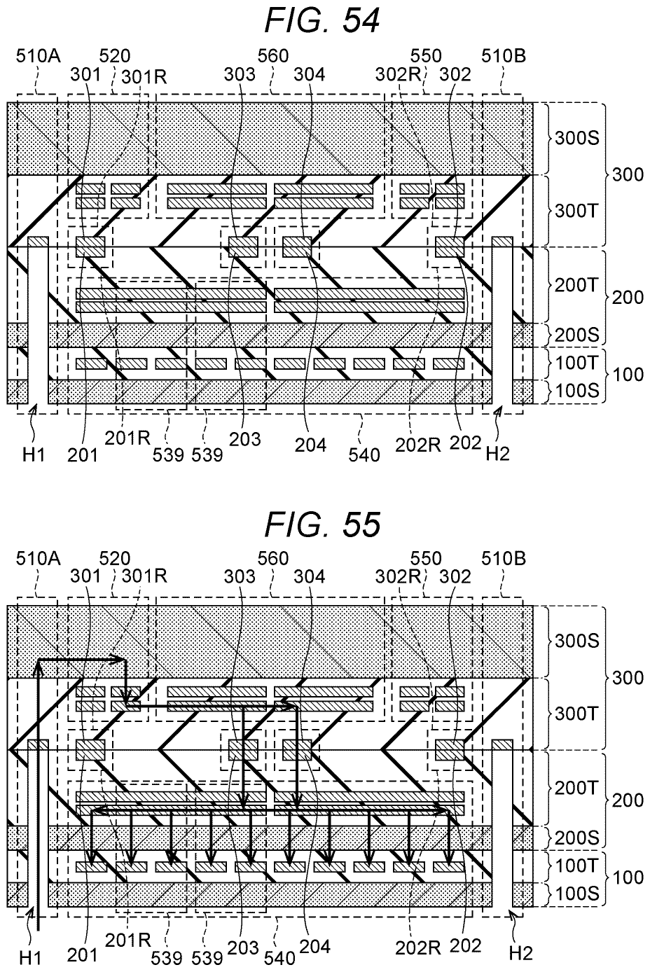

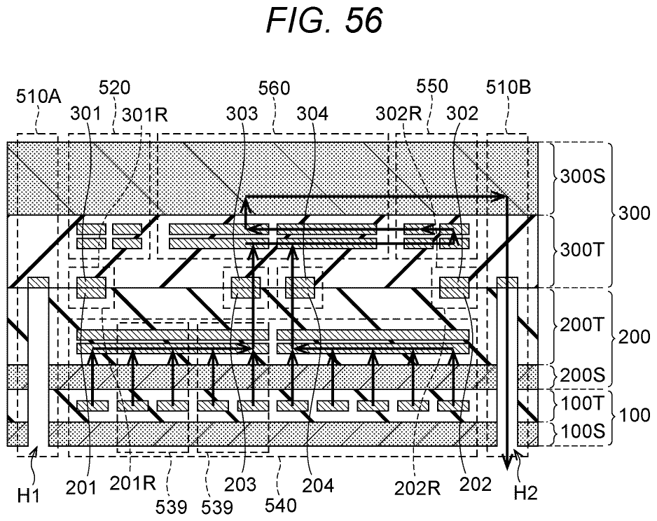

Next, operation of the imaging device 1 will be described with reference to FIGS. 55 and 56. In FIG. 55, a path of an input signal input to the imaging device 1 from the outside, a power supply potential, and a reference potential is indicated by an arrow. In FIG. 56, a signal path of a pixel signal output from the imaging device 1 to the outside is indicated by an arrow. For example, an input signal input to the imaging device 1 via the input section 510A is transmitted to the row drive section 520 of the third substrate 300, and the row drive section 520 creates a row drive signal. The row drive signal is sent to the second substrate 200 via the contact portions 303 and 203. Moreover, the row drive signal reaches each of the pixel sharing units 539 of the pixel array section 540 via the row drive signal line 542 in the wiring layer 200T. Among row drive signals reaching the pixel sharing units 539 of the second substrate 200, drive signals other than for the transfer gate TG are input to the pixel circuit 210, and the transistors included in the pixel circuit 210 are driven. The drive signals for the transfer gates TG are input to the transfer gates TG1, TG2, TG3, and TG4 of the first substrate 100 via the through electrode TGV, and the pixels 541A, 541B, 541C, and 541D are driven. Furthermore, the power supply potential and the reference potential supplied from the outside of the imaging device 1 to the input section 510A (input terminal 511) of the third substrate 300 are sent to the second substrate 200 via the contact portions 303 and 203, and supplied to the pixel circuit 210 of each of the pixel sharing units 539 via the wiring lines in the wiring layer 200T. The reference potential is further supplied to the pixels 541A, 541B, 541C, and 541D of the first substrate 100 via the through electrode 121E. On the other hand, the pixel signals photoelectrically converted by the pixels 541A, 541B, 541C, and 541D of the first substrate 100 are sent to the pixel circuit 210 of the second substrate 200 for each pixel sharing unit 539. Pixel signals based on the pixel signals are sent from the pixel circuit 210 to the third substrate 300 via the vertical signal line 543 and the contact portions 204 and 304. The pixel signal is processed by the column signal processing section 550 and the image signal processing section 560 of the third substrate 300, and then output to the outside via the output section 510B.

The imaging device 1 including such contact portions 203, 204, 303, and 304 can also obtain effects similar to those described in the above embodiments. The positions, the number, and the like of the contact portions can be changed according to design of the circuit and the like of the third substrate 300 to which the wiring lines are connected via the contact portions 303 and 304.

### 6. Modification 5

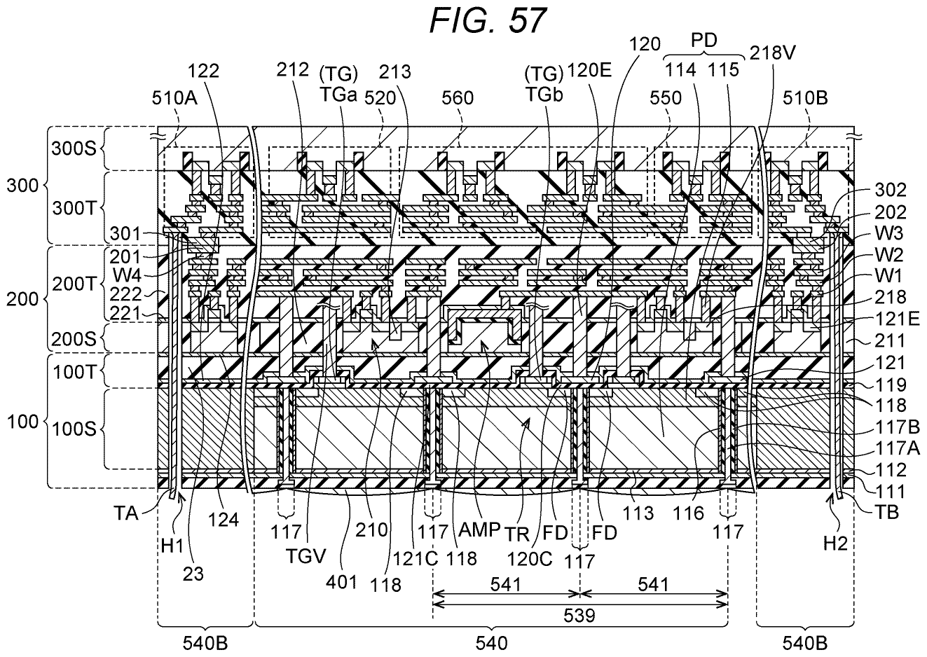

FIG. 57 illustrates a modification of the cross-sectional configuration of the imaging device 1 according to the above embodiments. FIG. 57 corresponds to FIG. 6 described in the above embodiments. In the present modification, the transfer transistor TR having a planar structure is provided in the first substrate 100. In this respect, the imaging device 1 of the present modification is different from the imaging device 1 described in the above embodiments.

In the transfer transistor TR, the transfer gate TG only includes the horizontal portion TGb. In other words, the transfer gate TG does not include the vertical portion TGa, and is provided to face the semiconductor layer 100S.

The imaging device 1 including the transfer transistor TR having such a planar structure can also obtain effects similar to those described in the above embodiments. Moreover, it is also conceivable to form the photodiode PD closer to the front surface of the semiconductor layer 100S by providing the planar transfer gate TG in the first substrate 100 as compared with a case where the vertical transfer gate TG is provided in the first substrate 100, thereby increasing a saturation signal amount (Qs). Furthermore, it can be considered that a method of forming the planar transfer gate TG in the first substrate 100 has a smaller number of manufacturing processes than a method of forming the vertical transfer gate TG in the first substrate 100, and the photodiode PD is less likely to be adversely affected due to the manufacturing processes.

### 7. Modification 6

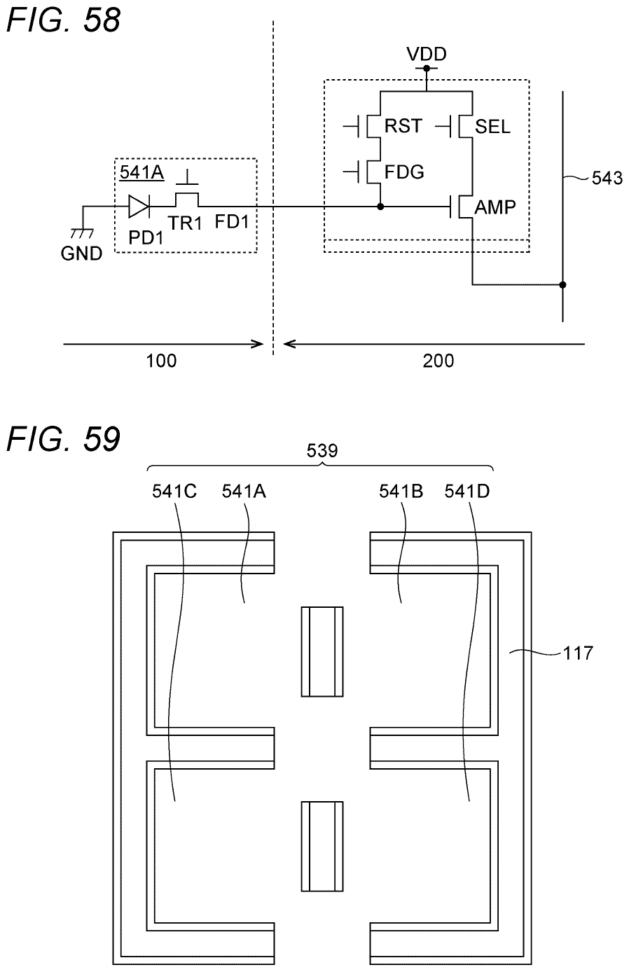

FIG. 58 illustrates a modification of the pixel circuit of the imaging device 1 according to the above embodiments. FIG. 58 corresponds to FIG. 26 described in the above embodiments. In the present modification, the pixel circuit 210 is provided for each pixel (pixel 541A). That is, the pixel circuit 210 is not shared by a plurality of pixels. In this respect, the imaging device 1 of the present modification is different from the imaging device 1 described in the above embodiments.

The imaging device 1 of the present modification is the same as the imaging device 1 described in the above embodiments in that the pixel 541A and the pixel circuit 210 are provided in different substrates (the first substrate 100 and the second substrate 200). For this reason, the imaging device 1 according to the present modification can also obtain effects similar to those described in the above embodiments.

### 8. Modification 7

FIG. 59 illustrates a modification of the planar configuration of the pixel isolation portion 117 described in the above embodiments. A gap may be provided in the pixel isolation portion 117 surrounding the pixels 541A, 541B, 541C, and 541D. That is, the entire circumference of the pixels 541A, 541B, 541C, and 541D may not be surrounded by the pixel isolation portion 117. For example, the gap of the pixel isolation portion 117 is provided in the vicinity of the pad portions 120 and 121 (see FIG. 29B).

In the above embodiments, an example has been described in which the pixel isolation portion 117 has the FTI structure penetrating the semiconductor layer 100S (see FIG. 28), but the pixel isolation portion 117 may have a configuration other than the FTI structure. For example, the pixel isolation portion 117 may not be provided so as to completely penetrate the semiconductor layer 100S, and may have a so-called deep trench isolation (DTI) structure.

### 9. Applied Example

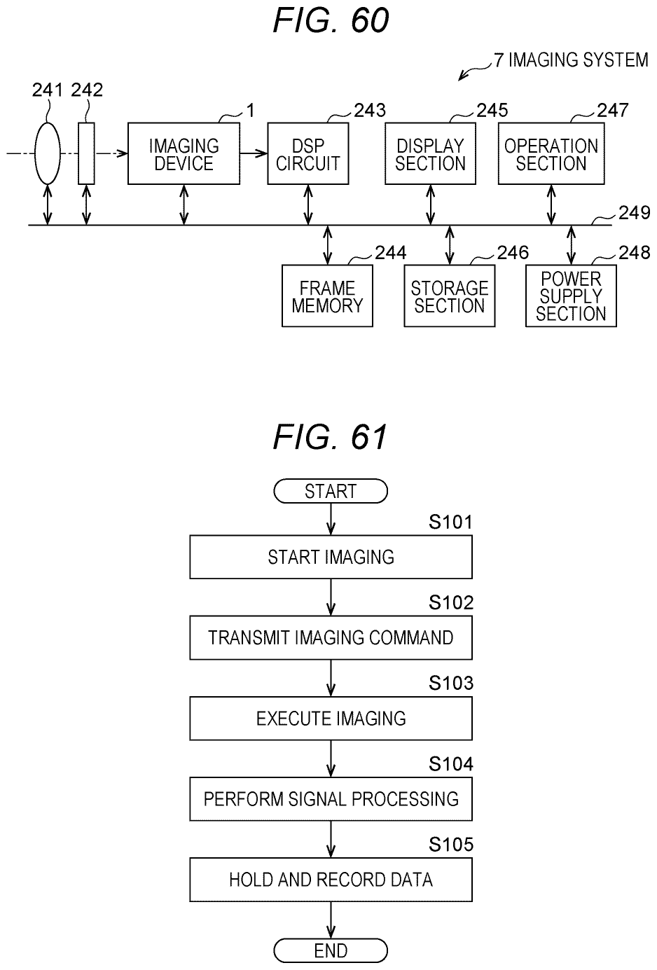

FIG. 60 illustrates an example of a schematic configuration of an imaging system 7 including the imaging device 1 according to the above-described embodiments and the modifications thereof.

The imaging system 7 is, for example, an electronic apparatus such as an imaging device such as a digital still camera or a video camera, or a portable terminal device such as a smartphone or a tablet terminal. The imaging system 7 includes, for example, the imaging device 1 according to the above-described embodiments and the modifications thereof, a DSP circuit 243, a frame memory 244, a display section 245, a storage section 246, an operation section 247, and a power supply section 248. In the imaging system 7, the imaging device 1 according to the above-described embodiments and the modifications thereof, the DSP circuit 243, the frame memory 244, the display section 245, the storage section 246, the operation section 247, and the power supply section 248 are connected to each other via a bus line 249.

The imaging device 1 according to the above-described embodiments and the modifications thereof outputs image data according to incident light. The DSP circuit 243 is a signal processing circuit that processes a signal (image data) output from the imaging device 1 according to the above-described embodiments and the modifications thereof. The frame memory 244 temporarily holds the image data processed by the DSP circuit 243 in units of frames. The display section 245 includes, for example, a panel-type display device such as a liquid crystal panel or an organic electro luminescence (EL) panel, and displays a moving image or a still image captured by the imaging device 1 according to the above-described embodiments and the modifications thereof. The storage section 246 records image data of a moving image or a still image captured by the imaging device 1 according to the above-described embodiments and the modifications thereof in a recording medium such as a semiconductor memory or a hard disk. The operation section 247 issues operation commands for various functions of the imaging system 7 in accordance with operation by a user. The power supply section 248 appropriately supplies various power supplies serving as operation power supplies of the imaging device 1 according to the above-described embodiments and the modifications thereof, the DSP circuit 243, the frame memory 244, the display section 245, the storage section 246, and the operation section 247 to these supply targets.

Next, an imaging procedure in the imaging system 7 will be described.

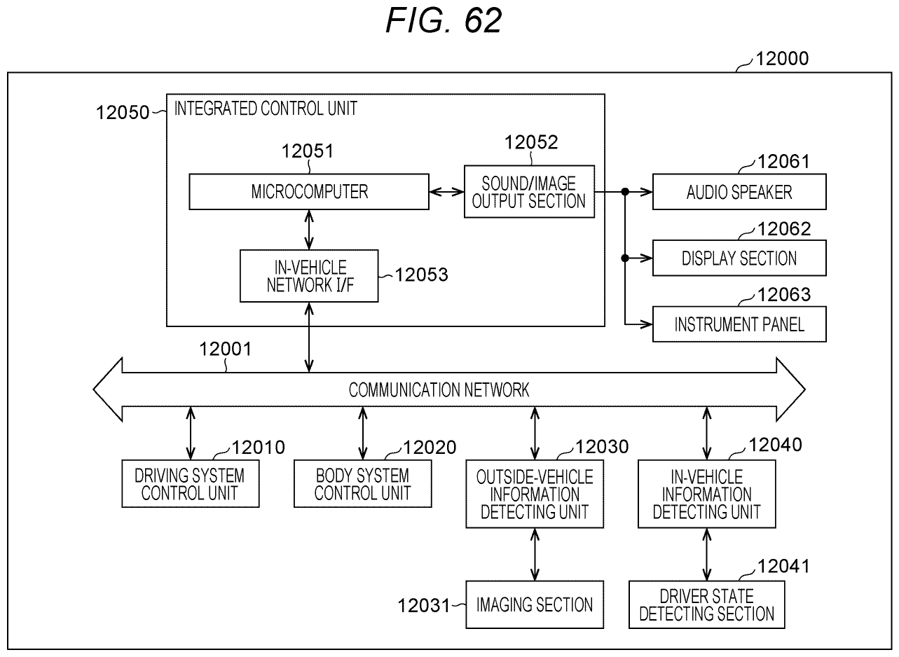

FIG. 61 illustrates an example of a flowchart of imaging operation in the imaging system 7. The user gives an instruction to start imaging by operating the operation section 247 (step S101). Then, the operation section 247 transmits an imaging command to the imaging device 1 (step S102). When receiving the imaging command, the imaging device 1 (specifically, a system control circuit 36) executes imaging by a predetermined imaging method (step S103).

The imaging device 1 outputs image data obtained by imaging to the DSP circuit 243. Here, the image data is data for all the pixels of the pixel signal generated on the basis of the charge temporarily held in the floating diffusion FD. The DSP circuit 243 performs predetermined signal processing (for example, noise reduction processing or the like) on the basis of the image data input from the imaging device 1 (step S104). The DSP circuit 243 causes the frame memory 244 to hold the image data subjected to the predetermined signal processing, and the frame memory 244 causes the storage section 246 to store the image data (step S105). In this manner, imaging in the imaging system 7 is performed.

In the present applied example, the imaging device 1 according to the above-described embodiments and the modifications thereof is applied to the imaging system 7. As a result, since the imaging device 1 can be downsized or made high definition, it is possible to provide the small or high definition imaging system 7.

### SECOND APPLICATION EXAMPLE

The technology according to the present disclosure (present technology) can be applied to various products. For example, the technology according to the present disclosure may be implemented in the form of a device to be mounted on a mobile body of any type, such as an automobile, an electric vehicle, a hybrid electric vehicle, a motorcycle, a bicycle, a personal mobility, an airplane, a drone, a vessel, or a robot.

FIG. 62 is a block diagram illustrating a schematic configuration example of a vehicle control system that is an example of a mobile body control system to which the technology of the present disclosure can be applied.

A vehicle control system 12000 includes a plurality of electronic control units connected to each other via a communication network 12001. In the example illustrated in FIG. 62, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and an in-vehicle network interface (I/F) 12053 are illustrated as functional components of the integrated control unit 12050.

The driving system control unit 12010 controls operation of devices related to a driving system of a vehicle in accordance with various programs. For example, the driving system control unit 12010 functions as a control device for a driving force generating device for generating driving force of the vehicle, such as an internal combustion engine or a driving motor, a driving force transmitting mechanism for transmitting the driving force to wheels, a steering mechanism for adjusting a steering angle of the vehicle, a braking device for generating braking force of the vehicle, and the like.

The body system control unit 12020 controls operation of various devices provided to a vehicle body in accordance with various programs. For example, the body system control unit 12020 functions as a control device for a keyless entry system, a smart key system, a power window device, or various lamps such as a headlamp, a back-up lamp, a brake lamp, a turn indicator, or a fog lamp. In this case, radio waves transmitted from a mobile device that substitutes for a key or signals of various switches may be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected to an imaging section 12031. The outside-vehicle information detecting unit 12030 causes the imaging section 12031 to capture an image of the outside of the vehicle, and receives the captured image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light and outputs an electric signal corresponding to an amount of the light received. The imaging section 12031 can output the electric signal as an image, or can output the electric signal as distance measurement information. Furthermore, the light received by the imaging section 12031 may be visible light, or may be invisible light such as infrared rays or the like.

The in-vehicle information detecting unit 12040 detects information about the inside of the vehicle. The in-vehicle information detecting unit 12040 is connected to a driver state detecting section 12041 that detects a state of a driver, for example. The driver state detecting section 12041 includes a camera that images the driver, for example, and the in-vehicle information detecting unit 12040 may calculate a degree of fatigue of the driver or a degree of concentration of the driver, or may determine whether or not the driver is dozing, on the basis of detection information input from the driver state detecting section 12041.

The microcomputer 12051 can calculate a control target value for the driving force generating device, the steering mechanism, or the braking device on the basis of the information about the inside or outside of the vehicle, the information being acquired by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS), the functions including vehicle collision avoidance or shock mitigation, following driving based on a following distance, vehicle speed maintaining driving, vehicle collision warning, vehicle lane departure warning, and the like.

Furthermore, the microcomputer 12051 can perform cooperative control intended for automated driving in which the vehicle travels autonomously without depending on the driver's operation, or the like, by controlling the driving force generating device, the steering mechanism, the braking device, or the like on the basis of the information about surroundings of the vehicle, the information being acquired by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent glare such as switching from high beam to low beam, by controlling the headlamp in accordance with a position of a preceding vehicle or an oncoming vehicle detected by the outside-vehicle information detecting unit 12030.

The sound/image output section 12052 transmits an output signal of at least one of a sound or an image to an output device capable of visually or auditorily notifying an occupant of the vehicle or the outside of the vehicle of information. In the example illustrated in FIG. 53, an audio speaker 12061, a display section 12062, and an instrument panel 12063 are illustrated as the output device. The display section 12062 may, for example, include at least one of an on-board display or a head-up display.

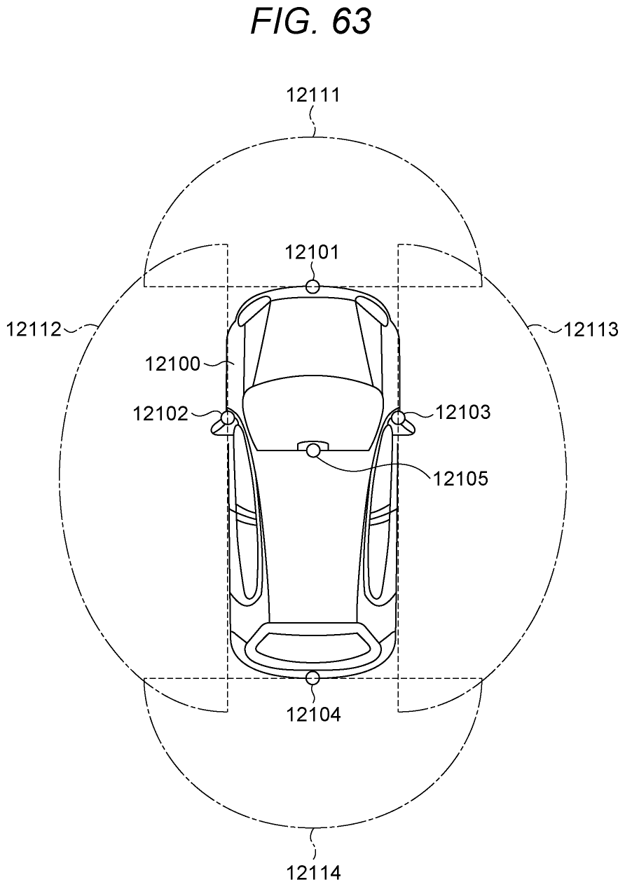

FIG. 63 is a diagram illustrating an example of installation positions of the imaging section 12031.

In FIG. 63, a vehicle 12100 includes imaging sections 12101, 12102, 12103, 12104, and 12105, as the imaging section 12031.

The imaging sections 12101, 12102, 12103, 12104, and 12105 are provided at positions on a vehicle 12100, for example, the front nose, the sideview mirrors, the rear bumper, the back door, an upper portion of the windshield in the interior of the vehicle, and the like. The imaging section 12101 provided to the front nose and the imaging section 12105 provided to the upper portion of the windshield in the interior of the vehicle acquire mainly images of areas in front of the vehicle 12100. The imaging sections 12102 and 12103 provided to the sideview mirrors acquire mainly images of areas on the lateral sides from the vehicle 12100. The imaging section 12104 provided to the rear bumper or the back door acquires mainly an image of an area behind the vehicle 12100. The images of areas in front to be acquired by the imaging sections 12101 and 12105 are used mainly to detect a preceding vehicle, a pedestrian, an obstacle, a traffic signal, a traffic sign, a lane, or the like.

Note that FIG. 63 illustrates an example of imaging ranges of the imaging sections 12101 to 12104. An imaging range 12111 represents the imaging range of the imaging section 12101 provided to the front nose, imaging ranges 12112 and 12113 respectively represent the imaging ranges of the imaging sections 12102 and 12103 provided to the sideview mirrors, and an imaging range 12114 represents the imaging range of the imaging section 12104 provided to the rear bumper or the back door. For example, image data captured by the imaging sections 12101 to 12104 are superimposed, whereby a bird's-eye image of the vehicle 12100 as viewed from above is obtained.

At least one of the imaging sections 12101 to 12104 may have a function of acquiring distance information. For example, at least one of the imaging sections 12101 to 12104 may be a stereo camera including a plurality of imaging elements, or may be an imaging element having pixels for phase difference detection.

For example, the microcomputer 12051 obtains a distance to each of three-dimensional objects within the imaging ranges 12111 to 12114 and a temporal change in the distance (relative speed with respect to the vehicle 12100) on the basis of the distance information obtained from the imaging sections 12101 to 12104, thereby being able to extract, as a preceding vehicle, a nearest three-dimensional object in particular that is present on a traveling path of the vehicle 12100 and travels in substantially the same direction as the vehicle 12100 at a predetermined speed (for example, greater than or equal to 0 km/hour). Moreover, the microcomputer 12051 can set a following distance to be secured in front of a preceding vehicle in advance, and perform automatic brake control (including following stop control), automatic acceleration control (including following start control), or the like. It is thus possible to perform cooperative control intended for automated driving in which the vehicle travels autonomously without depending on the driver's operation, or the like.

For example, the microcomputer 12051 can classify three-dimensional object data regarding three-dimensional objects into three-dimensional object data of a two-wheeled vehicle, a standard-sized vehicle, a large-sized vehicle, a pedestrian, and other three-dimensional objects such as a utility pole, on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle, and in a situation in which the collision risk is greater than or equal to a set value and there is a possibility of collision, can perform driving assistance to avoid collision by outputting a warning to the driver via the audio speaker 12061 or the display section 12062, and performing forced deceleration or avoidance steering via the driving system control unit 12010.

At least one of the imaging sections 12101 to 12104 may be an infrared camera that detects infrared rays. The microcomputer 12051 can, for example, recognize a pedestrian by determining whether or not there is a pedestrian in captured images by the imaging sections 12101 to 12104. Such pedestrian recognition is performed, for example, by a procedure of extracting feature points in the captured images by the imaging sections 12101 to 12104 as infrared cameras and a procedure of performing pattern matching processing on a series of feature points representing a contour of an object to determine whether or not the feature points represent a pedestrian. When the microcomputer 12051 determines that there is a pedestrian in the captured images by the imaging sections 12101 to 12104 and recognizes the pedestrian, the sound/image output section 12052 controls the display section 12062 so that a rectangular contour for emphasis is displayed in a Superimposed manner on the recognized pedestrian. Furthermore, the sound/image output section 12052 may also control the display section 12062 so that an icon or the like representing the pedestrian is displayed at a desired position.

In the above, an example has been described of the mobile body control system to which the technology according to the present disclosure can be applied. The technology according to the present disclosure can be applied to the imaging section 12031, in the configuration described above. Specifically, the imaging device 1 according to the above-described embodiments and the modifications thereof can be applied to the imaging section 12031. By applying the technology according to the present disclosure to the imaging section 12031, it is possible to obtain a high-definition captured image with little noise, and thus, it is possible to perform highly accurate control using the captured image in the mobile body control system.

### THIRD APPLICATION EXAMPLE

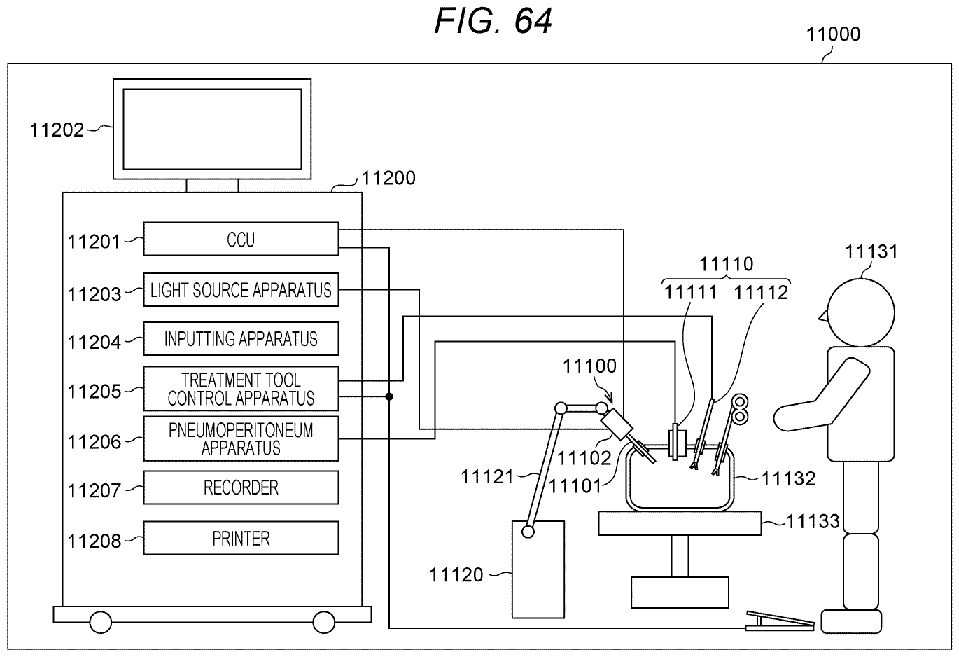

FIG. 64 is a diagram illustrating an example of a schematic configuration of an endoscopic surgery system to which the technology according to the present disclosure (the present technology) can be applied.

FIG. 64 illustrates a state where a surgeon (doctor) 11131 performs surgery on a patient 11132 on a patient bed 11133, by using an endoscopic surgery system 11000. As illustrated, the endoscopic surgery system 11000 includes an endoscope 11100, other surgical tools 11110 such as a pneumoperitoneum tube 11111 and an energy treatment tool 11112, a supporting arm apparatus 11120 that supports the endoscope 11100, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the illustrated example, the endoscope 11100 is illustrated that is formed as a so-called rigid endoscope including the lens barrel 11101 of a rigid type; however, the endoscope 11100 may be formed as a flexible endoscope including the lens barrel 11101 of a flexible type.

The lens barrel 11101 is provided with an opening in which an objective lens is fitted, at the distal end thereof. A light source apparatus 11203 is connected to the endoscope 11100 and light generated by the light source apparatus 11203 is guided by a light guide extending inside the lens barrel 11101 to the distal end of the lens barrel, and applied to an observation target in the body cavity of the patient 11132 via the objective lens. Note that the endoscope 11100 may be a forward-viewing endoscope or may be an oblique-viewing endoscope or a side-viewing endoscope.

An optical system and an imaging element are provided inside the camera head 11102, and reflected light (observation light) from the observation target is condensed on the imaging element by the optical system. The observation light is photoelectrically converted by the imaging element to generate an electric signal corresponding to the observation light, that is, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Moreover, the CCU 11201 receives the image signal from the camera head 11102 and performs, on the image signal, various types of image processing for displaying an image based on the image signal, for example, development processing (demosaic processing) and the like.

The display apparatus 11202 displays the image based on the image signal, on which the image processing has been performed by the CCU 11201, under the control of the CCU 11201.

The light source apparatus 11203 includes a light source, for example, a light emitting diode (LED) or the like, and supplies irradiation light for imaging a surgical region or the like to the endoscope 11100.

An input apparatus 11204 is an input interface for the endoscopic surgery system 11000. A user can input various types of information and instructions to the endoscopic surgery system 11000 via the input apparatus 11204. For example, the user inputs an instruction to change an imaging condition (type of irradiation light, magnification, focal length, or the like) by the endoscope 11100, or the like.

A treatment tool control apparatus 11205 controls driving of the energy treatment tool 11112 for cautery or incision of tissue, sealing of a blood vessel, or the like. A pneumoperitoneum apparatus 11206 feeds gas into a body cavity of the patient 11132 through the pneumoperitoneum tube 11111 to inflate the body cavity in order to secure a field of view by the endoscope 11100 and secure a working space for the surgeon. A recorder 11207 is an apparatus capable of recording various types of information regarding surgery. A printer 11208 is an apparatus capable of printing various types of information regarding surgery in various forms such as a text, an image, or a graph.

Note that the light source apparatus 11203 that supplies irradiation light when a surgical region is to be imaged to the endoscope 11100 can include a white light source including, for example, an LED, a laser light source, or a combination thereof. In a case where the white light source includes a combination of R, G, and B laser light sources, since an output intensity and an output timing can be controlled with high accuracy for each color (each wavelength), adjustment of white balance of a captured image can be performed in the light source apparatus 11203. Furthermore, in this case, it is also possible to capture an image corresponding to each of R, G, and B in a time division manner by irradiating the observation target with laser light from each of the R, G, and B laser light sources in a time-division manner, and controlling driving of the imaging element of the camera head 11102 in synchronization with a timing of the irradiation. According to this method, a color image can be obtained even if color filters are not provided for the imaging element.

Furthermore, driving of the light source apparatus 11203 may be controlled such that the intensity of light to be output is changed for each predetermined time. Driving of the imaging element of the camera head 11102 is controlled in synchronization with a timing of the change of the intensity of light to acquire images in a time division manner and combining the images, whereby it is possible to create an image with a high dynamic range free from so-called blocked up shadows and blown out highlights.

Furthermore, the light source apparatus 11203 may be configured to supply light of a predetermined wavelength band applicable to special light observation. In special light observation, for example, by utilizing wavelength dependency of absorption of light in body tissue to irradiate light of a narrow band in comparison with irradiation light upon ordinary observation (that is, white light), so-called narrow band observation (narrow band imaging) is performed of imaging predetermined tissue such as a blood vessel of a superficial portion of the mucous membrane or the like in a high contrast. Alternatively, in special light observation, fluorescent observation may be performed for obtaining an image from fluorescent light generated by irradiation of excitation light. In fluorescent observation, it is possible to perform observation of fluorescent light from body tissue by irradiating the body tissue with excitation light (autofluorescence observation) or to obtain a fluorescent light image by locally injecting a reagent such as indocyanine green (ICG) into body tissue and irradiating the body tissue with excitation light corresponding to a fluorescent light wavelength of the reagent. The light source apparatus 11203 can be configured to supply such narrowband light and/or excitation light applicable to special light observation as described above.

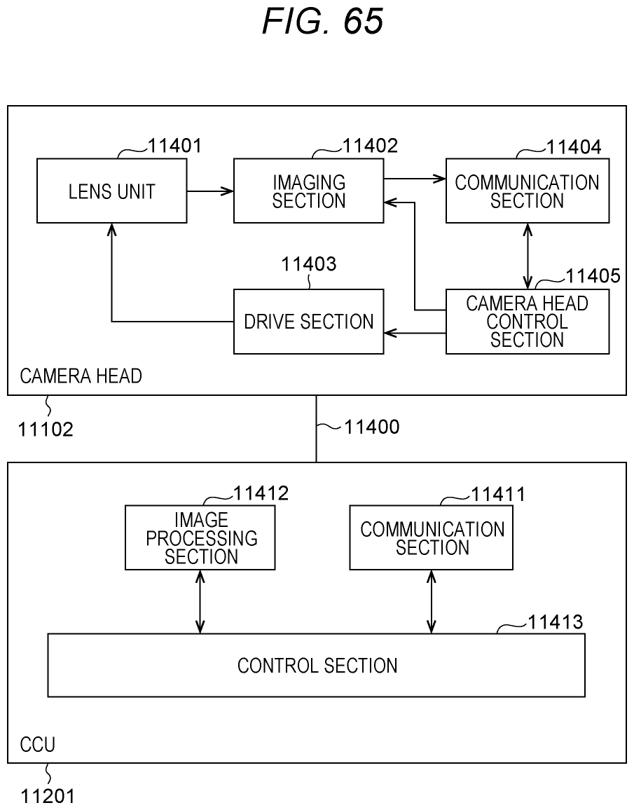

FIG. 65 is a block diagram illustrating an example of a functional configuration of the camera head 11102 and the CCU 11201 illustrated in FIG. 64.

The camera head 11102 includes a lens unit 11401, an imaging section 11402, a drive section 11403, a communication section 11404 and a camera head control section 11405. The CCU 11201 includes a communication section 11411, an image processing section 11412, and a control section 11413. The camera head 11102 and the CCU 11201 are communicatively connected to each other by a transmission cable 11400.

The lens unit 11401 is an optical system provided at a connection portion to the lens barrel 11101. The observation light taken in from the distal end of the lens barrel 11101 is guided to the camera head 11102 and is incident on the lens unit 11401. The lens unit 11401 includes a combination of a plurality of lenses including a zoom lens and a focus lens.

The imaging section 11402 includes an imaging element. The number of imaging elements included in the imaging section 11402 may be one (so-called single-plate type) or a plural number (so-called multi-plate type). In a case where the imaging section 11402 is configured as the multi-plate type, for example, image signals respectively corresponding to R, G and B are generated by the imaging elements, and the image signals may be combined to obtain a color image. Alternatively, the imaging section 11402 may include a pair of imaging elements for acquiring right-eye and left-eye image signals compatible with three-dimensional (3D) display. The 3D display is performed, whereby depth of living body tissue in a surgical region can be grasped more accurately by the surgeon 11131. Note that, in a case where the imaging section 11402 is configured as the multi-plate type, a plurality of systems of lens units 11401 is provided corresponding to the individual imaging elements.

Furthermore, the imaging section 11402 may not necessarily be provided in the camera head 11102. For example, the imaging section 11402 may be provided immediately behind the objective lens, inside the lens barrel 11101.

The drive section 11403 includes an actuator and moves the zoom lens and the focus lens of the lens unit 11401 by a predetermined distance along the optical axis under the control of the camera head control section 11405. As a result, a magnification and a focus of a captured image by the imaging section 11402 can be appropriately adjusted.

The communication section 11404 includes a communication device for transmitting and receiving various types of information to and from the CCU 11201. The communication section 11404 transmits an image signal acquired from the imaging section 11402 as RAW data to the CCU 11201 through the transmission cable 11400.

Furthermore, the communication section 11404 receives a control signal for controlling driving of the camera head 11102 from the CCU 11201 and supplies the control signal to the camera head control section 11405. The control signal includes information regarding imaging conditions, for example, information to the effect that a frame rate of the captured image is designated, information to the effect that an exposure value at the time of imaging is designated, and/or information to the effect that the magnification and the focus of the captured image are designated.

Note that the imaging conditions such as the frame rate, exposure value, magnification, and focus described above may be appropriately designated by the user, or may be set automatically by the control section 11413 of the CCU 11201 on the basis of the acquired image signal. In the latter case, so-called auto exposure (AE) function, auto focus (AF) function, and auto white balance (AWB) function are incorporated in the endoscope 11100.

The camera head control section 11405 controls driving of the camera head 11102 on the basis of a control signal from the CCU 11201 received through the communication section 11404.

The communication section 11411 includes a communication device for transmitting and receiving various types of information to and from the camera head 11102. The communication section 11411 receives the image signal transmitted from the camera head 11102 through the transmission cable 11400.

Furthermore, the communication section 11411 transmits the control signal for controlling driving of the camera head 11102 to the camera head 11102. The image signal and the control signal can be transmitted by electrical communication, optical communication, or the like.

The image processing section 11412 performs various types of image processing on an image signal that is RAW data transmitted from the camera head 11102.

The control section 11413 performs various types of control regarding imaging of a surgical region or the like by the endoscope 11100 and display of a captured image obtained by imaging of the surgical region or the like. For example, the control section 11413 creates the control signal for controlling driving of the camera head 11102.

Furthermore, the control section 11413 causes the display apparatus 11202 to display a captured image in which the surgical region or the like is imaged, on the basis of the image signal subjected to the image processing by the image processing section 11412. At this time, the control section 11413 may recognize various objects in the captured image by using various image recognition technologies. For example, the control section 11413 can recognize a surgical tool such as forceps, a particular living body region, bleeding, mist when the energy treatment tool 11112 is used, and the like by detecting edge shapes, colors, and the like of the objects included in the captured image. At the time of causing the display apparatus 11202 to display the captured image, the control section 11413 may display various types of surgery assistance information on the image of the surgical region in a superimposed manner by using a result of the recognition. The surgery assistance information is displayed in a superimposed manner and presented to the surgeon 11131, whereby a burden on the surgeon 11131 can be reduced and the surgeon 11131 can reliably proceed with the surgery.

The transmission cable 11400 that connects the camera head 11102 and the CCU 11201 to each other is an electric signal cable applicable to communication of an electric signal, an optical fiber applicable to optical communication, or a composite cable thereof.

Here, in the illustrated example, communication is performed by wired communication using the transmission cable 11400; however, the communication between the camera head 11102 and the CCU 11201 may be performed by wireless communication.

In the above, an example has been described of the endoscopic surgery system to which the technology according to the present disclosure can be applied. The technology according to the present disclosure can be suitably applied to the imaging section 11402 provided in the camera head 11102 of the endoscope 11100, in the configuration described above. By application of the technology according to the present disclosure to the imaging section 11402, the imaging section 11402 can be downsized or made high definition, so that the endoscope 11100 having a small size or high definition can be provided.

Although the present disclosure has been described with the embodiments and the modifications thereof, the applied example, and the application examples above, the present disclosure is not limited to the above-described embodiments and the like, and various modifications can be made. Note that the effects described in the present specification are merely examples. The effects of the present disclosure are not limited to the effects described in the present specification. The present disclosure may have effects other than those described in the present specification.

Note that the present technology may have the following configurations.
(1) A photodetection device including:
a pixel array section including a plurality of pixels arranged in a first direction and a second direction and divided into a plurality of pixel groups including some pixels different from each other on the basis of a plurality of pixel control signals;
a control signal generation circuit that is arranged in a layer different from the pixel array section and generates the plurality of pixel control signals;
a thinned image generation section that generates a plurality of thinned images by exposing the plurality of pixel groups within a predetermined frame period while shifting at least one of exposure start times or exposure end times from each other; and
an image composition section that generates a composite image obtained by combining the plurality of thinned images.
(2) The photodetection device according to (1), further including:
a first substrate on which the pixel array section is arranged;
a second substrate on which at least a part of a pixel circuit that generates a pixel signal according to charges photoelectrically converted by the plurality of pixels and the control signal generation circuit are arranged and that is stacked on the first substrate; and
a third substrate on which the thinned image generation section and the image composition section are arranged and that is stacked on the first substrate and the second substrate.
(3) The photodetection device according to (1) or (2), in which
the image composition section generates the plurality of thinned images at a frame rate identical to a frame rate in a case where image data based on all of the plurality of pixels is generated.
(4) The photodetection device according to any one of (1) to (3), in which
each of the plurality of pixel groups includes two or more pixels that are not adjacent to each other in the first direction and the second direction.
(5) The photodetection device according to any one of (1) to (4), in which
each of the plurality of pixels includes:
a photoelectric conversion element that accumulates a charge according to an amount of incident light;
a charge holding portion that holds the charge accumulated in the photoelectric conversion element ;
a charge-voltage conversion portion that converts the charge held in the charge holding portion into a voltage signal; and
a transfer transistor that transfers the charge held in the charge holding portion to the charge-voltage conversion portion, and
the charge holding portion holds the charge photoelectrically converted in each of the plurality of pixel groups at an aligned timing for each pixel group.
(6) The photodetection device according to (5), in which
the plurality of thinned images is generated on the basis of the charge photoelectrically converted by the plurality of pixel groups for which at least one of the exposure start times or the exposure end times are different from each other and exposure times are identical to each other.
(7) The photodetection device according to (6), in which
each of the plurality of pixel groups starts exposure of a next frame after reading out the charge from the charge holding portion while another pixel group performs exposure.
(8) The photodetection device according to any one of (1) to (7), further including
a motion vector detection section that detects a motion vector on the basis of the composite image.
(9) The photodetection device according to (5), in which
the plurality of thinned images is generated on the basis of the charge photoelectrically converted by the plurality of pixel groups for which at least one of the exposure start times or the exposure end times are different from each other and exposure times are different from each other.
(10) The photodetection device according to (9), in which
the plurality of pixel groups reads out the charge from the charge holding portion at an identical timing, and then starts exposure of a next frame at a timing shifted for each pixel group.
(11) The photodetection device according to (9) or (10), in which
the image composition section generates the composite image having a wider dynamic range than a dynamic range of each of the plurality of thinned images.
(12) The photodetection device according to (5), in which
the plurality of thinned images includes two or more thinned image groups,
each of the two or more thinned image groups includes two or more thinned images for which exposure times are different from each other, and
the image composition section generates, for each of the two or more thinned image groups, the composite image obtained by combining the two or more thinned images included in a corresponding one of the thinned image groups.
(13) The photodetection device according to (12), in which
the plurality of pixel groups includes two or more pixel group units for which at least one of the exposure start times or the exposure end times are different from each other,
each of the two or more pixel group units includes two or more pixel groups for which at least one of the exposure start times or the exposure end times are different from each other and exposure times are different from each other within the predetermined frame period, and
the two or more pixel group units generate the two or more thinned image groups.
(14) The photodetection device according to (12) or (13), in which
the two or more pixel groups included in each of the two or more pixel group units end exposure at an identical timing, and
an exposure end timing is different for each of the two or more pixel group units.
(15) The photodetection device according to any one of (12) to (14), further including
a motion vector detection section that detects a motion vector on the basis of the composite image, in which
the image composition section generates the composite image having a wider dynamic range than a dynamic range of each of the plurality of thinned images.
(16) A photodetection device including:
a pixel array section including a plurality of pixels arranged in a first direction and a second direction and divided into a plurality of macropixels each including two or more of the pixels adjacent to each other in at least one of the first direction or the second direction on the basis of a plurality of pixel control signals;
a control signal generation circuit that is arranged in a layer different from the pixel array section and generates the plurality of pixel control signals; and
an image generation section that generates a phase difference detection image on the basis of pixel signals generated by the plurality of macropixels in a state where charge reading from some pixels is stopped, the some pixels being included in each of the plurality of macropixels and arranged in the first direction or the second direction.
(17) The photodetection device according to (16), in which
in two of the macropixels adjacent to each other in the first direction or the second direction, pixels for which charge reading is stopped are arranged symmetrically with each other.
(18) An electronic apparatus including:
a photodetection device that generates a composite image; and
a processing section that performs processing on the composite image, in which
the photodetection device includes:
a pixel array section including a plurality of pixels arranged in a first direction and a second direction and divided into a plurality of pixel groups including some pixels different from each other on the basis of a plurality of pixel control signals;
a control signal generation circuit that is arranged in a layer different from the pixel array section and generates the plurality of pixel control signals;
a thinned image generation section that generates a plurality of thinned images by performing exposure while shifting at least one of exposure start times or exposure end times from each other within a predetermined frame period in the plurality of pixel groups; and
an image composition section that generates the composite image obtained by combining the plurality of thinned images.

Aspects of the present disclosure are not limited to the above-described individual embodiments, but include various modifications that can be conceived by those skilled in the art, and the effects of the present disclosure are not limited to the above-described contents. In other words, various additions, modifications, and partial deletions may be made without departing from the conceptual idea and spirit of the present disclosure derived from the matters defined in the claims and equivalents thereof.

### REFERENCE SIGNS LIST

1 Imaging device
2 Imaging lens
3 Photodetection device
4 Processing section
5 Control section
6 Transmission line
8 Control line
9 Recording section
10 Pixel
11 Pixel array section
12 Row drive section
13 Column signal processing section
14 Image signal processing section
15 Timing control section
16 Image generation section
17 Image composition section
18 Vector detection section
19 Control signal generation section
20 Pixel circuit
21 GS memory
25 First substrate
26 Second substrate
27 Third substrate
28 Logic circuit
30 Macropixel
31 Electronic apparatus

1. A photodetection device comprising:
a pixel array section including a plurality of pixels arranged in a first direction and a second direction and divided into a plurality of pixel groups including some pixels different from each other on a basis of a plurality of pixel control signals;
a control signal generation circuit that is arranged in a layer different from the pixel array section and generates the plurality of pixel control signals;
a thinned image generation section that generates a plurality of thinned images by exposing the plurality of pixel groups within a predetermined frame period while shifting at least one of exposure start times or exposure end times from each other; and
an image composition section that generates a composite image obtained by combining the plurality of thinned images.

2. The photodetection device according to claim 1, further comprising:
a first substrate on which the pixel array section is arranged;
a second substrate on which at least a part of a pixel circuit that generates a pixel signal according to charges photoelectrically converted by the plurality of pixels and the control signal generation circuit are arranged and that is stacked on the first substrate; and
a third substrate on which the thinned image generation section and the image composition section are arranged and that is stacked on the first substrate and the second substrate.

3. The photodetection device according to claim 1, wherein
the image composition section generates the plurality of thinned images at a frame rate identical to a frame rate in a case where image data based on all of the plurality of pixels is generated.

4. The photodetection device according to claim 1, wherein
each of the plurality of pixel groups includes two or more pixels that are not adjacent to each other in the first direction and the second direction.

5. The photodetection device according to claim 1, wherein
each of the plurality of pixels includes:
a photoelectric conversion element that accumulates a charge according to an amount of incident light;
a charge holding portion that holds the charge accumulated in the photoelectric conversion element ;
a charge-voltage conversion portion that converts the charge held in the charge holding portion into a voltage signal; and
a transfer transistor that transfers the charge held in the charge holding portion to the charge-voltage conversion portion, and
the charge holding portion holds the charge photoelectrically converted in each of the plurality of pixel groups at an aligned timing for each pixel group.

6. The photodetection device according to claim 5, wherein
the plurality of thinned images is generated on a basis of the charge photoelectrically converted by the plurality of pixel groups for which at least one of the exposure start times or the exposure end times are different from each other and exposure times are identical to each other.

7. The photodetection device according to claim 6, wherein
each of the plurality of pixel groups starts exposure of a next frame after reading out the charge from the charge holding portion while another pixel group performs exposure.

8. The photodetection device according to claim 1, further comprising
a motion vector detection section that detects a motion vector on a basis of the composite image.

9. The photodetection device according to claim 5, wherein
the plurality of thinned images is generated on a basis of the charge photoelectrically converted by the plurality of pixel groups for which at least one of the exposure start times or the exposure end times are different from each other and exposure times are different from each other.

10. The photodetection device according to claim 9, wherein
the plurality of pixel groups reads out the charge from the charge holding portion at an identical timing, and then starts exposure of a next frame at a timing shifted for each pixel group.

11. The photodetection device according to claim 9, wherein
the image composition section generates the composite image having a wider dynamic range than a dynamic range of each of the plurality of thinned images.

12. The photodetection device according to claim 5, wherein
the plurality of thinned images includes two or more thinned image groups,
each of the two or more thinned image groups includes two or more thinned images for which exposure times are different from each other, and
the image composition section generates, for each of the two or more thinned image groups, the composite image obtained by combining the two or more thinned images included in a corresponding one of the thinned image groups.

13. The photodetection device according to claim 12, wherein
the plurality of pixel groups includes two or more pixel group units for which at least one of the exposure start times or the exposure end times are different from each other,
each of the two or more pixel group units includes two or more pixel groups for which at least one of the exposure start times or the exposure end times are different from each other and exposure times are different from each other within the predetermined frame period, and
the two or more pixel group units generate the two or more thinned image groups.

14. The photodetection device according to claim 12, wherein
the two or more pixel groups included in each of the two or more pixel group units end exposure at an identical timing, and
an exposure end timing is different for each of the two or more pixel group units.

15. The photodetection device according to claim 12, further comprising
a motion vector detection section that detects a motion vector on a basis of the composite image, wherein
the image composition section generates the composite image having a wider dynamic range than a dynamic range of each of the plurality of thinned images.

16. A photodetection device comprising:
a pixel array section including a plurality of pixels arranged in a first direction and a second direction and divided into a plurality of macropixels each including two or more of the pixels adjacent to each other in at least one of the first direction or the second direction on a basis of a plurality of pixel control signals;
a control signal generation circuit that is arranged in a layer different from the pixel array section and generates the plurality of pixel control signals; and
an image generation section that generates a phase difference detection image on a basis of pixel signals generated by the plurality of macropixels in a state where charge reading from some pixels is stopped, the some pixels being included in each of the plurality of macropixels and arranged in the first direction or the second direction.

17. The photodetection device according to claim 16, wherein
in two of the macropixels adjacent to each other in the first direction or the second direction, pixels for which charge reading is stopped are arranged symmetrically with each other.

18. An electronic apparatus comprising:
a photodetection device that generates a composite image; and
a processing section that performs processing on the composite image, wherein
the photodetection device includes:
a pixel array section including a plurality of pixels arranged in a first direction and a second direction and divided into a plurality of pixel groups including some pixels different from each other on a basis of a plurality of pixel control signals;
a control signal generation circuit that is arranged in a layer different from the pixel array section and generates the plurality of pixel control signals;
a thinned image generation section that generates a plurality of thinned images by performing exposure while shifting at least one of exposure start times or exposure end times from each other within a predetermined frame period in the plurality of pixel groups; and
an image composition section that generates the composite image obtained by combining the plurality of thinned images.
